(19) United States
(12) Patent Application Publication
(10) Pub. No.: US 2026/0258300 A1
(43) Pub. Date: Sep. 3, 2026

(54) PROCESS FOR SYNTHESIZING EUROPIUM-DOPED STRONTIUM MAGNESIUM GERMANATE PHOSPHORS

(71) Applicant: PRINCESS NOURAH BINT ABDULRAHMAN UNIVERSITY, Riyadh (SA)

(72) Inventors: Mohd. SHKIR, Abha (SA); Thamraa ALSHAHRANI, Riyadh (SA); S. ALFAIFY, Abha (SA); H. NAGABHUSHANA, Tumkur (IN); K. MANJUNATHA, Hualien (TW); B. R. Radha KRUSHNA, Tumkur (IN); S. C. SHARMA, Bangalore (IN); Sambasivam SANGARAJU, Al Ain (AE)

(73) Assignee: PRINCESS NOURAH BINT ABDULRAHMAN UNIVERSITY, Riyadh (SA)

(21) Appl. No.: 19/675,597

(22) Filed: May 13, 2026

(51) Int. Cl. C09K 11/77; C01G 17/00; C09D 1/00; C09D 5/22; C09D 7/61; C09D 7/80; C09K 11/02; H10H 20/01

(52) U.S. Cl. CPC C09K 11/7735; C01G 17/006; C09D 1/00; C09D 5/22; C09D 7/61; C09D 7/80; C09K 11/02; C09K 11/7734; C09K 11/77342; H10H 20/034; C01P 2002/54; C01P 2002/72; C01P 2002/77; C01P 2002/82; C01P 2002/84; C01P 2002/85; C01P 2004/03; C01P 2004/04; C01P 2006/60

(57) ABSTRACT

The present invention relates to the synthesis of europium-doped strontium magnesium germanate phosphors and, in more particular manner, to a process for the synthesis of Sr₂MgGe₂O₇:xEu³⁺ (SMGO:xEu³⁺) phosphors (where x=0.5-6 mol %) for white LEDs, latent fingerprint detection, and anti-counterfeiting applications. The synthesis is carried out by mixing Stoichiometric molar amounts of strontium nitrate (Sr(NO₃)₂), magnesium nitrate (Mg(NO₃)₂·6H₂O), germanium dioxide (GeO₂), and europium nitrate (Eu(NO₃)₃·6H₂O) were dissolved in deionized water, and further adding Aloe vera gel extract as a natural fuel, wherein the resultant solution is stirred to obtain a homogeneous redox mixture, which then boiled, ignited to form a gel, and combusted into a fine powder, wherein the fine powder is then annealed for improve crystallinity. These results substantiate the efficacy of SMGO:Eu³⁺ phosphor as a viable forensic material for high-resolution LFP detection, offering a compelling alternative to existing commercial powders, especially under UV-assisted visualization scenarios

### FIELD OF THE INVENTION

The present disclosure relates to the field of multifunctional rare earth doped phosphor materials, particularly Eu³⁺ activated alkaline earth germanate compounds, and their applications in lighting, forensic science and security technologies. In more particular manner, the present invention relates to a process for synthesizing Europium-doped strontium magnesium germanate (Sr₂MgGe₂O₇) phosphors for white LEDs, latent fingerprint detection, and anti-counterfeiting applications.

### BACKGROUND OF THE INVENTION

Beyond lighting applications, rare-earth-doped phosphors are also playing a vital role in the field of anti-counterfeiting. Counterfeiting has become a pervasive global issue, affecting sectors such as pharmaceuticals, electronics, and financial transactions. Traditional security methods, including barcodes, holograms, and watermarks, are increasingly susceptible to replication due to the evolving sophistication of counterfeit techniques. As a result, the demand for advanced luminescent materials with distinct and complex optical signatures has risen sharply. Rare-earth-doped phosphors are particularly advantageous in this regard, offering persistent luminescence, robust emission characteristics, and the ability to operate under various excitation wavelengths, which collectively make them difficult to replicate. Among them, europium-activated phosphors are especially appealing due to their strong red luminescence under UV or n-UV excitation, rendering them suitable for incorporation into security labels, invisible inks, and digital authentication systems. Despite these benefits, ongoing research is required to enhance their optical stability, emission strength, and compatibility with various substrates to expand their scope in anti-counterfeiting applications.

Another promising area for the application of rare-earth-doped phosphors lies in LFP detection. Fingerprints (FPs) are a critical tool in forensic investigations due to their uniqueness and permanence. However, LFPs, which are typically invisible without treatment, present challenges in detection. Traditional methods such as powder dusting, chemical reagents, and cyanoacrylate fuming often produce inconsistent results, especially on complex or multi-textured surfaces, and may involve cumbersome procedures or time-dependent degradation. Luminescent phosphors, particularly those doped with rare-earth ions, offer a compelling solution by providing high-contrast visualization of ridge patterns under UV illumination. These materials selectively bind to FP residues, enabling clear imaging with enhanced detail and sensitivity. Moreover, the integration of artificial intelligence (AI) and deep learning technologies, such as the YOLOv8x model, has introduced new capabilities in automating FP recognition. This model significantly improves the speed and precision of detecting FP minutiae across various surfaces, thereby increasing the reliability of forensic evidence. Nonetheless, further refinement is needed in terms of improving phosphor adherence, reducing background interference, and boosting detection accuracy for practical forensic applications. Among rare-earth ions, Eu³⁺ has attracted particular attention for its vivid red emission via the ⁵D₀→⁷F_{J} (J=0-4) transitions, which are known for their narrow bandwidths and superior CP. These emissions stem from intra-4f transitions that are shielded by the outer 5s and 5p orbitals, resulting in high spectral resolution and excellent photostability. In recent years, green synthesis methods employing plant extracts have gained prominence as sustainable alternatives to traditional chemical routes for nanoparticle synthesis. Aloe vera, in particular, has proven to be an effective natural fuel and complexing agent due to its rich phytochemical composition, which includes polysaccharides, phenolics, flavonoids, amino acids, and carbohydrates. These bioactive compounds function as natural reducing, stabilizing, and chelating agents, facilitating the controlled nucleation and growth of nanostructures with tailored morphology and size. Unlike conventional polymer- or surfactant-assisted hydrothermal routes, the use of A.V. extract enables eco-friendly combustion at lower temperatures, minimizes toxic by-products, and enhances particle homogeneity. The carbohydrate-rich gel supports exothermic redox reactions essential for combustion synthesis, while the presence of enzymes, organic acids, and minerals aids in better cation distribution during crystallization. Such characteristics not only improve the phase purity and crystallinity of the synthesized materials but also introduce surface functionalities beneficial for applications in biomedicine, catalysis, and optoelectronics. In the view of the foregoing discussion, the present invention aims to use A.V. mediated combustion synthesis to synthesize Eu³⁺-activated SMGO phosphors, offering a green, energy-efficient route with potential advantages over conventional synthesis techniques.

### SUMMARY OF THE INVENTION

The present disclosure relates to a process for synthesizing Europium-doped strontium magnesium germanate (Sr₂MgGe₂O₇) phosphors for white LEDs, latent fingerprint detection, and anti-counterfeiting applications. The present invention aims to provide synthesis, characterization, and multifunctional applications of SMGO:Eu³⁺ phosphors prepared via a solution combustion technique. Three critical applications of the synthesized phosphors are evaluated, including: as a red phosphor to enhance color quality and thermal stability in w-LEDs; for AC purposes owing to their distinct and durable luminescence, and; in LFP detection, utilizing the YOLOv8x deep learning framework for improved detection accuracy. The present invention aims to provide in-depth insights into the structure-property relationships of SMGO:Eu³⁺ phosphors and establishes their potential for versatile applications across optoelectronic, forensic, and security sectors.

An object of the present disclosure is to provide a process for synthesizing Europium-doped strontium magnesium germanate (Sr₂MgGe₂O₇) phosphors for white LEDs, latent fingerprint detection, and anti-counterfeiting applications. Another object of the present disclosure is to synthesize the Europium-doped strontium magnesium germinate phosphors via a solution combustion technique with A.V. gel functioning as both a fuel and a natural templating agent.

Another object of the present disclosure is to synthesize phosphors that enable the fabrication of white light-emitting diodes (w-LEDs).

Another object of the present disclosure is to provide phosphors that enable the preparation of security ink. Another object of the present disclosure is to provide phosphors that enable the detection of latent fingerprints. Yet, another object of the present disclosure is to comparative analysis of SMGO:Eu³⁺ phosphors with reported Eu³⁺-activated systems.

To further clarify advantages and features of the present disclosure, a more particular description of the invention will be rendered by reference to specific embodiments thereof, which is illustrated in the appended drawings. It is appreciated that these drawings depict only typical embodiments of the invention and are therefore not to be considered limiting of its scope. The invention will be described and explained with additional specificity and detail with the accompanying drawings.

### BRIEF DESCRIPTION OF FIGURES

These and other features, aspects, and advantages of the present disclosure will become better understood when the following detailed description is read with reference to the accompanying drawings in which like characters represent like parts throughout the drawings, wherein:

FIG. 1(a) illustrates Schematic representation of (a) extraction of A.V. gel, in accordance with an embodiment of the present disclosure;

FIG. 1(b) illustrates a schematic representation of synthesis of un-doped and 1-6 mol % Eu³⁺ doped SMGO phosphors via solution combustion route, in accordance with an embodiment of the present disclosure;

FIG. 1(c) illustrates a schematic representation of Development of AC labels via simple pen mode using SMGO:2% Eu³⁺ phosphors ink, in accordance with an embodiment of the present disclosure;

FIG. 1(d) illustrates LFPs development using optimized SMGO:2% Eu³⁺ phosphors via powder dusting method and visualized under UV 365 nm light, in accordance with an embodiment of the present disclosure;

FIG. 2(a) illustrates XRD pattens of SMGO:x % Eu³⁺ (0-6 mol %) phosphors, in accordance with an embodiment of the present disclosure;

FIG. 2(b) illustrates enlarged view of (211) plane, in accordance with an embodiment of the present disclosure;

FIG. 3(a) illustrates Rietveld refinement patterns of undoped SMGO:x % Eu³⁺ phosphors, in accordance with an embodiment of the present disclosure;

FIG. 3(b) illustrates Rietveld refinement patterns of SMGO:x % Eu³⁺ phosphors at 1 mol %, in accordance with an embodiment of the present disclosure;

FIG. 3(c) illustrates Rietveld refinement patterns of SMGO:x % Eu³⁺ phosphors, at 2 mol %, in accordance with an embodiment of the present disclosure;

FIG. 3(d) illustrates Rietveld refinement patterns of SMGO:x % Eu³⁺ phosphors, at 3 mol %, in accordance with an embodiment of the present disclosure;

FIG. 3(e) illustrates Rietveld refinement patterns of SMGO:x % Eu³⁺ phosphors at 4 mol %, in accordance with an embodiment of the present disclosure;

FIG. 3(f) illustrates Rietveld refinement patterns of SMGO:x % Eu³⁺ phosphors at 5 mol %, in accordance with an embodiment of the present disclosure;

FIG. 3(g) illustrates Rietveld refinement patterns of SMGO:x % Eu³⁺ phosphors at 6 mol %, in accordance with an embodiment of the present disclosure;

FIG. 4(a) illustrates Crystal structure visualization of undoped SMGO phosphors, showing three-dimensional unit cells in ball-and-stick and polyhedral, before doping, in accordance with an embodiment of the present disclosure;

FIG. 4(b) illustrates Crystal structure visualization of undoped SMGO phosphors, showing formats for undoped structures, in accordance with an embodiment of the present disclosure;

FIG. 4(c) illustrates Crystal structure visualization of undoped SMGO phosphors, showing magnified local coordination of Sr²⁺, in accordance with an embodiment of the present disclosure;

FIG. 4(d) illustrates Crystal structure visualization of undoped SMGO phosphors, showing local geometry of the [MgO₄] tetrahedra before Eu³⁺ doping, in accordance with an embodiment of the present disclosure;

FIG. 4(e) illustrates Crystal structure visualization of undoped SMGO phosphors, showing the [GeO₄] tetrahedral before Eu³⁺ doping, in accordance with an embodiment of the present disclosure;

FIG. 4(f) illustrates Crystal structure visualization of undoped SMGO phosphors, showing the atomic legend and compass of undoped structure, in accordance with an embodiment of the present disclosure;

FIG. 4(g) illustrates Crystal structure visualization of 2 mol % Eu³⁺-doped SMGO phosphors, showing three-dimensional unit cells in ball-and-stick and polyhedral, after doping, in accordance with an embodiment of the present disclosure;

FIG. 4(h) illustrates Crystal structure visualization of 2 mol % Eu³⁺-doped SMGO phosphors, showing formats for Eu³⁺ doped structures, in accordance with an embodiment of the present disclosure;

FIG. 4(i) illustrates Crystal structure visualization of 2 mol % Eu³⁺-doped SMGO phosphors, showing magnified local coordination of Sr²⁺/Eu³⁺ sites, in accordance with an embodiment of the present disclosure;

FIG. 4(j) illustrates Crystal structure visualization of 2 mol % Eu³⁺-doped SMGO phosphors, showing [MgO₄] tetrahedral after doping, in accordance with an embodiment of the present disclosure;

FIG. 4(k) illustrates Crystal structure visualization of 2 mol % Eu³⁺-doped SMGO phosphors, showing [GeO₄] tetrahedral after doping, in accordance with an embodiment of the present disclosure;

FIG. 4(l) illustrates Crystal structure visualization of 2 mol % Eu³⁺-doped SMGO phosphors, showing the atomic legend and compass of Eu³⁺ doped structure, in accordance with an embodiment of the present disclosure;

FIG. 5(a) crystallite size calculations using W—H plots for un-doped and SMGO:x % Eu³⁺ (1-6 mol %) phosphors, in accordance with an embodiment of the present disclosure;

FIG. 5(b) illustrates variation of lattice parameter a, with Eu³⁺ concentrations, in accordance with an embodiment of the present disclosure;

FIG. 5(c) illustrates variation of lattice parameter c, with Eu³⁺ concentrations, in accordance with an embodiment of the present disclosure;

FIG. 5(d) illustrates the variation of volume with Eu³⁺ concentrations, in accordance with an embodiment of the present disclosure;

FIG. 5(e) illustrates the 2D Electron density mapping of Sr/Eu, in SMGO:2% Eu³⁺ phosphor, in accordance with an embodiment of the present disclosure;

FIG. 5(f) illustrates 2D Electron density mapping of Mg, in SMGO:2% Eu³⁺ phosphor, in accordance with an embodiment of the present disclosure;

FIG. 5(g) illustrates 2D Electron density mapping of Ge, in SMGO:2% Eu³⁺ phosphor, in accordance with an embodiment of the present disclosure;

FIG. 5(h) illustrates 2D Electron density mapping of O, in SMGO:2% Eu³⁺ phosphor, in accordance with an embodiment of the present disclosure;

FIG. 5(i) illustrates 3D Electron density mapping of Sr/Eu, in SMGO:2% Eu³⁺ phosphor, in accordance with an embodiment of the present disclosure;

FIG. 5(j) illustrates 3D Electron density mapping of Mg, in SMGO:2% Eu³⁺ phosphor, in accordance with an embodiment of the present disclosure;

FIG. 5(k) illustrates 3D Electron density mapping of Ge, in SMGO:2% Eu³⁺ phosphor, in accordance with an embodiment of the present disclosure;

FIG. 5(l) illustrates 3D Electron density mapping of O, in SMGO:2% Eu³⁺ phosphor, in accordance with an embodiment of the present disclosure;

FIG. 6(a) illustrates FE-SEM images of un-doped phosphors, in accordance with an embodiment of the present disclosure;

FIG. 6(b) illustrates FE-SEM images of 1 mol % SMGO:x % Eu³⁺ phosphors, in accordance with an embodiment of the present disclosure;

FIG. 6(c) illustrates FE-SEM images of 2 mol % SMGO:x % Eu³⁺ phosphors, in accordance with an embodiment of the present disclosure;

FIG. 6(d) illustrates FE-SEM images of 3 mol % SMGO:x % Eu³⁺ phosphors, in accordance with an embodiment of the present disclosure;

FIG. 6(e) illustrates FE-SEM images of 4 mol % SMGO:x % Eu³⁺ phosphors, in accordance with an embodiment of the present disclosure;

FIG. 6(f) illustrates FE-SEM images of 5 mol % SMGO:x % Eu³⁺ phosphors, in accordance with an embodiment of the present disclosure;

FIG. 6(g) illustrates FE-SEM images of 6 mol % SMGO:x % Eu³⁺ phosphors, in accordance with an embodiment of the present disclosure;

FIG. 6(h) illustrates FE-SEM image of the SMGO:2% Eu³⁺ phosphor indicating the region selected for EDS spectra and elemental mapping, in accordance with an embodiment of the present disclosure;

FIG. 6(i) illustrates EDS spectra of the SMGO:2% Eu³⁺ phosphor, in accordance with an embodiment of the present disclosure;

FIG. 6(j) illustrates Table showing the atomic % and weight %; of SMGO:2% Eu³⁺ phosphors, in accordance with an embodiment of the present disclosure;

FIG. 6(k) illustrates atomic % pie chart of SMGO:2% Eu³⁺ phosphors, in accordance with an embodiment of the present disclosure;

FIG. 6(l) illustrates TEM image of SMGO:2% Eu³⁺ phosphors, in accordance with an embodiment of the present disclosure;

FIG. 6(m) illustrates Particle size distribution of SMGO:2% Eu³⁺ phosphors, in accordance with an embodiment of the present disclosure;

FIG. 6(n) illustrates HR-TEM image of SMGO:2% Eu³⁺ phosphors, in accordance with an embodiment of the present disclosure;

FIG. 6(o) illustrates FFT and IFFT images of SMGO:2% Eu³⁺ phosphors, in accordance with an embodiment of the present disclosure;

FIG. 6(p) illustrates Pixel intensity profiles showing interplanar spacings of 0.301 nm, for the (211) plane of SMGO:2% Eu³⁺ phosphor, in accordance with an embodiment of the present disclosure;

FIG. 7(a) illustrates UV-Vis diffuse reflectance spectra and corresponding inset Tauc's plots of un-doped phosphors, in accordance with an embodiment of the present disclosure;

FIG. 7(b) illustrates UV-Vis diffuse reflectance spectra and corresponding inset Tauc's plots of 1 mol % SMGO:x % Eu³⁺ phosphors, in accordance with an embodiment of the present disclosure;

FIG. 7(c) illustrates UV-Vis diffuse reflectance spectra and corresponding inset Tauc's plots of 2 mol % SMGO:x % Eu³⁺ phosphors, in accordance with an embodiment of the present disclosure;

FIG. 7(d) illustrates UV-Vis diffuse reflectance spectra and corresponding inset Tauc's plots of 3 mol % SMGO:x % Eu³⁺ phosphors, in accordance with an embodiment of the present disclosure;

FIG. 7(e) illustrates UV-Vis diffuse reflectance spectra and corresponding inset Tauc's plots of 4 mol % SMGO:x % Eu³⁺ phosphors, in accordance with an embodiment of the present disclosure;

FIG. 7(f) illustrates UV-Vis diffuse reflectance spectra and corresponding inset Tauc's plots of 5 mol % SMGO:x % Eu³⁺ phosphors, in accordance with an embodiment of the present disclosure;

FIG. 7(g) illustrates UV-Vis diffuse reflectance spectra and corresponding inset Tauc's plots of 6 mol % SMGO:x % Eu³⁺ phosphors, in accordance with an embodiment of the present disclosure;

FIG. 7(h) illustrates Raman spectra of SMGO:x % Eu³⁺ (0-6 mol %) phosphors, in accordance with an embodiment of the present disclosure;

FIG. 7(i) illustrates FTIR spectra of SMGO:x % Eu³⁺ (0-6 mol %) phosphors, in accordance with an embodiment of the present disclosure;

FIG. 8(a) illustrates XPS survey scan spectrum of SMGO and SMGO:2% Eu³⁺ phosphor, in accordance with an embodiment of the present disclosure;

FIG. 8(b) illustrates HR-XPS spectrum of Sr 3d core level, in accordance with an embodiment of the present disclosure, in accordance with an embodiment of the present disclosure;

FIG. 8(c) illustrates HR-XPS spectrum of Mg 2p core level, in accordance with an embodiment of the present disclosure, in accordance with an embodiment of the present disclosure;

FIG. 8(d) illustrates HR-XPS spectrum of Ge 3d core level, in accordance with an embodiment of the present disclosure, in accordance with an embodiment of the present disclosure;

FIG. 8(e) illustrates HR-XPS spectrum of O is core level, in accordance with an embodiment of the present disclosure, in accordance with an embodiment of the present disclosure;

FIG. 8(f) illustrates HR-XPS spectrum of Eu 3d core level, in accordance with an embodiment of the present disclosure, in accordance with an embodiment of the present disclosure;

FIG. 9(a) illustrates PLE of SMGO:2% Eu³⁺ phosphor, in accordance with an embodiment of the present disclosure;

FIG. 9(b) illustrates PL spectrum of SMGO:x % Eu³⁺ (1-6 mol %) phosphors, in accordance with an embodiment of the present disclosure;

FIG. 9(c) illustrates normalized luminous intensity variation with concentration, in accordance with an embodiment of the present disclosure;

FIG. 9(d) illustrates Relation between log (I/x) and log (x) of SMGO:x % Eu³⁺ phosphors, in accordance with an embodiment of the present disclosure;

FIG. 9(e) illustrates Energy level diagram of Eu³⁺ in SMGO matrix, in accordance with an embodiment of the present disclosure;

FIG. 9(f) illustrates CIE and diagrams of SMGO:x % Eu³⁺ phosphors, in accordance with an embodiment of the present disclosure;

FIG. 9(g) illustrates phosphors photos of SMGO:x % Eu³⁺ phosphors, in accordance with an embodiment of the present disclosure;

FIG. 9(h) illustrates CCT diagram of SMGO:x % Eu³⁺ (1-6 mol %) phosphors, in accordance with an embodiment of the present disclosure;

FIG. 10 illustrates UI of JOES software for SMSO:2% Eu³⁺ phosphor excited at λ_{exci}=394 nm, in accordance with an embodiment of the present disclosure;

FIG. 11(a) illustrates PL emission spectra of SMGO:2% Eu³⁺ phosphors recorded at different time intervals under relative humidity of 30%, in accordance with an embodiment of the present disclosure;

FIG. 11(b) illustrates normalized PL intensity variations corresponding to PL emission spectra of SMGO:2% Eu³⁺ phosphors recorded at different time intervals under relative humidity of 30%, in accordance with an embodiment of the present disclosure;

FIG. 11(c) illustrates UV-excited digital photographs showing macroscopic luminescence variations over time for RH~30%, in accordance with an embodiment of the present disclosure;

FIG. 11(d) illustrates PL emission spectra of SMGO:2% Eu³⁺ phosphors recorded at different time intervals under relative humidity of 60%, in accordance with an embodiment of the present disclosure;

FIG. 11(e) illustrates normalized PL intensity variations normalized PL intensity variations corresponding to PL emission spectra of SMGO:2% Eu³⁺ phosphors recorded at different time intervals under relative humidity of 60%, in accordance with an embodiment of the present disclosure;

FIG. 11(f) illustrates UV-excited digital photographs showing macroscopic luminescence variations over time for RH~60%, in accordance with an embodiment of the present disclosure;

FIG. 11(g) illustrates PL emission spectra of SMGO:2% Eu³⁺ phosphors recorded at different time intervals under relative humidity of 90%, in accordance with an embodiment of the present disclosure;

FIG. 11(h) illustrates normalized PL intensity variations normalized PL intensity variations corresponding to PL emission spectra of SMGO:2% Eu³⁺ phosphors recorded at different time intervals under relative humidity of 90%, in accordance with an embodiment of the present disclosure;

FIG. 11(i) illustrates UV-excited digital photographs showing macroscopic luminescence variations over time for RH~90%, in accordance with an embodiment of the present disclosure;

FIG. 11(j) illustrates PL emission spectra of SMGO:2% Eu³⁺ phosphors recorded at different time intervals under acidic (HCl, pH~3) conditions, in accordance with an embodiment of the present disclosure;

FIG. 11(k) illustrates monitored chemical stability, showing normalized PL intensity retention corresponding to PL emission spectra of SMGO:2% Eu³⁺ phosphors recorded at different time intervals under acidic (HCl, pH~3) conditions, in accordance with an embodiment of the present disclosure;

FIG. 11(l) illustrates UV-excited digital photographs showing macroscopic luminescence variations over time for pH 3, in accordance with an embodiment of the present disclosure;

FIG. 11(m) illustrates PL emission spectra of SMGO:2% Eu³⁺ phosphors recorded at different time intervals under basic (NaOH, pH~13) conditions, in accordance with an embodiment of the present disclosure;

FIG. 11(n) illustrates monitoring chemical stability, showing normalized PL intensity retention corresponding to PL emission spectra of SMGO:2% Eu³⁺ phosphors recorded at different time intervals under basic (NaOH, pH~13) conditions, in accordance with an embodiment of the present disclosure;

FIG. 11(o) illustrates UV-excited digital photographs showing macroscopic luminescence variations over time for pH 7, in accordance with an embodiment of the present disclosure;

FIG. 11(p) illustrates PL emission spectra of SMGO:2% Eu³⁺ phosphors recorded at different time intervals under neutral (H₂O, pH~7) conditions, in accordance with an embodiment of the present disclosure;

FIG. 11(q) illustrates monitored chemical stability, showing normalized PL intensity retention corresponding to PL emission spectra of SMGO:2% Eu³⁺ phosphors recorded at different time intervals under neutral (H₂O, pH~7) conditions, in accordance with an embodiment of the present disclosure;

FIG. 11(r) illustrates UV-excited digital photographs showing macroscopic luminescence variations over time for pH 13, in accordance with an embodiment of the present disclosure;

FIG. 12(a) illustrates I_{QE} spectra of SMGO:2% Eu³⁺ phosphor, in accordance with an embodiment of the present disclosure;

FIG. 12(b) illustrates Decay lifetimes of SMGO:x % Eu³⁺ at 1 mol %, in accordance with an embodiment of the present disclosure;

FIG. 12(c) illustrates Decay lifetimes of SMGO:x % Eu³⁺ at 2 mol %, in accordance with an embodiment of the present disclosure;

FIG. 12(d) illustrates Decay lifetimes of SMGO:x % Eu³⁺ at 3 mol %, in accordance with an embodiment of the present disclosure;

FIG. 12(e) illustrates Decay lifetimes of SMGO:x % Eu³⁺ at 4 mol %, in accordance with an embodiment of the present disclosure;

FIG. 12(f) illustrates Decay lifetimes of SMGO:x % Eu³⁺ at 5 mol %, in accordance with an embodiment of the present disclosure;

FIG. 12(g) illustrates Decay lifetimes of SMGO:x % Eu³⁺ at 6 mol %, in accordance with an embodiment of the present disclosure;

FIG. 12(h) illustrates variation of decay lite time with Eu³⁺ concentrations, in accordance with an embodiment of the present disclosure;

FIG. 13(a) illustrates TDPL spectra of SMGO:2% Eu³⁺ phosphor, in accordance with an embodiment of the present disclosure;

FIG. 13(b) illustrates contour plot of SMGO:2% Eu³⁺ phosphor, in accordance with an embodiment of the present disclosure;

FIG. 13(c) illustrates luminescence intensity variation of SMGO:2% Eu³⁺ phosphor, in accordance with an embodiment of the present disclosure;

FIG. 13(d) illustrates ln((I₀/I_{T})−1) v/s 1/T plot for determination of activation energy of SMGO:2% Eu³⁺ phosphor, in accordance with an embodiment of the present disclosure;

FIG. 13(e) illustrates coordination diagram of Eu³⁺ in SMGO matrix, in accordance with an embodiment of the present disclosure;

FIG. 13(f) illustrates CIE diagram of SMGO:2% Eu³⁺ phosphor at different temperatures (300-480 K), in accordance with an embodiment of the present disclosure;

FIG. 13(g) illustrates FIR (⁵D₀→⁷F₁/⁵D₀→⁷F₂) with temperature for SMGO:2% Eu³⁺ phosphors, in accordance with an embodiment of the present disclosure;

FIG. 13(h) illustrates Ln[FIR (⁵D₀→⁷F₁/⁵D₀→⁷F₂)] with temperature for SMGO:2% Eu³⁺ phosphors, in accordance with an embodiment of the present disclosure;

FIG. 13(i) illustrates Sᵣ and Sₐ parameters for SMGO:2% Eu³⁺ phosphors, in accordance with an embodiment of the present disclosure;

FIG. 13(j) illustrates Fifty measurements of FIR, (k) δT variation for SMGO:2% Eu³⁺ phosphors, in accordance with an embodiment of the present disclosure;

FIG. 13(k) illustrates δT variation for SMGO:2% Eu³⁺ phosphors, in accordance with an embodiment of the present disclosure;

FIG. 13(l) illustrates thermal repeatability for SMGO:2% Eu³⁺ phosphors for SMGO:2% Eu³⁺ phosphors, in accordance with an embodiment of the present disclosure;

FIG. 14(a) illustrates I_{QE} of SMGO:2% Eu³⁺ phosphors at 420 K temperature, in accordance with an embodiment of the present disclosure;

FIG. 14(b) illustrates I_{QE} of SMGO:2% Eu³⁺ phosphors at 480 K temperature, in accordance with an embodiment of the present disclosure;

FIG. 15(a) illustrates the EL spectrum of the fabricated w-LED, in accordance with an embodiment of the present disclosure;

FIG. 15(b) illustrates CIE diagram of the fabricated w-LED, in accordance with an embodiment of the present disclosure;

FIG. 15(c) illustrates EL spectra of the fabricated w-LED at different currents (30-300 mA), in accordance with an embodiment of the present disclosure;

FIG. 15(d) illustrates CIE diagram of fabricated w-LED at different currents (30-300 mA), in accordance with an embodiment of the present disclosure;

FIG. 15(e) illustrates column graph showing a comparison of CRI between the fabricated w-LED and commercially available w-LED, in accordance with an embodiment of the present disclosure;

FIG. 15(f) illustrates Variation of luminous intensity with time for fabricated w-LED, in accordance with an embodiment of the present disclosure;

FIG. 15(g) illustrates contour plot of the fabricated w-LED, in accordance with an embodiment of the present disclosure;

FIG. 15(h) illustrates camera images of w-LEDs with time, in accordance with an embodiment of the present disclosure;

FIG. 15(i) illustrates temperature of w-LEDs with various temperature, in accordance with an embodiment of the present disclosure;

FIG. 15(j) illustrates CIE diagram of w-LEDs with various temperature, in accordance with an embodiment of the present disclosure;

FIG. 16(a) illustrates surfaces of paper, aluminum foil, and glass substrates, in accordance with an embodiment of the present disclosure;

FIG. 16(b) illustrates the AC patterns developed on paper, aluminum foil, and glass substrates under 365 nm illumination developed using SMGO:2% Eu³⁺ ink, in accordance with an embodiment of the present disclosure;

FIG. 16(c) illustrates aging of the AC patterns developed on paper using SMGO:2% Eu³⁺ ink, in accordance with an embodiment of the present disclosure;

FIG. 16(d) illustrates photostability tests of the AC patterns developed on aluminum foil using SMGO:2% Eu³⁺ ink, in accordance with an embodiment of the present disclosure;

FIG. 16(e) illustrates thermal robustness of the AC patterns developed on glass substrates using SMGO:2% Eu³⁺ ink, in accordance with an embodiment of the present disclosure;

FIG. 17(a) illustrates surfaces of the Developed FPs on various substrates, in accordance with an embodiment of the present disclosure;

FIG. 17(b) illustrates developed FPs on various substrates (paper, aluminium foil and ceramic plate) using optimized SMGO:2% Eu³⁺ phosphor via powder dusting approach, in accordance with an embodiment of the present disclosure;

FIG. 17(c) illustrates 3D interactive plots of corresponding developed FPs, in accordance with an embodiment of the present disclosure;

FIG. 17(d) illustrates Pixel profiles of selected region, in accordance with an embodiment of the present disclosure;

FIG. 18(a) illustrates FP image and Magnified views of different minutiae features, in accordance with an embodiment of the present disclosure;

FIG. 18(b) illustrates Poroscopy of sweat pores showing position, shape and area of sweat pores, in accordance with an embodiment of the present disclosure;

FIG. 18(c) illustrates Poroscopy of sweat pores showing ridge and furrow width, in accordance with an embodiment of the present disclosure;

FIG. 18(d) illustrates Pixel profile extracted from the FP image, in accordance with an embodiment of the present disclosure;

FIG. 18(e) illustrates 3D profile of selected sweat pore, in accordance with an embodiment of the present disclosure;

FIG. 18(f) illustrates Developed FP image, in accordance with an embodiment of the present disclosure;

FIG. 18(g) illustrates Pixel profile extracted from the FP image, in accordance with an embodiment of the present disclosure;

FIG. 19(a) illustrates the level 2 features including bifurcation, ridge-end, and loop identified using YOLOv8x software, in accordance with an embodiment of the present disclosure;

FIG. 19(b) illustrates a pre-processing involved in the analysis process using YOLOv8x for object detection, in accordance with an embodiment of the present disclosure;

FIG. 19(c) illustrates a training model involved in the analysis process using YOLOv8x for object detection, in accordance with an embodiment of the present disclosure;

FIG. 19(d) illustrates a prediction process involved in the analysis process using YOLOv8x for object detection, in accordance with an embodiment of the present disclosure;

FIG. 19(e) illustrates a plot of visual representation of a confusion matrix, in accordance with an embodiment of the present disclosure;

FIG. 19(f) illustrates a definition of an intersection over union (IoU) metric, in accordance with an embodiment of the present disclosure;

FIG. 19(g) illustrates a calculation of the intersection over union (IoU) metric, in accordance with an embodiment of the present disclosure;

FIG. 20(a) illustrates a conceptual representation of a bifurcation feature detected by the YOLOv8x model during training, in accordance with an embodiment of the present disclosure;

FIG. 20(b) illustrates a confusion matrix representing classification results for bifurcation features obtained using the YOLOv8x model, in accordance with an embodiment of the present disclosure;

FIG. 20(c) illustrates a precision plot for bifurcation feature detection over training epochs, in accordance with an embodiment of the present disclosure;

FIG. 20(d) illustrates a recall plot for bifurcation feature detection over training epochs, in accordance with an embodiment of the present disclosure;

FIG. 20(e) illustrates mean Average Precision at 50% IoU (mAP@50) scores for bifurcation feature detection over training epochs, in accordance with an embodiment of the present disclosure;

FIG. 20(f) illustrates mean Average Precision at 50-95% IoU (mAP@50-95) scores for bifurcation feature detection over training epochs, in accordance with an embodiment of the present disclosure;

FIG. 20(g) illustrates a training loss function variation with respect to training epochs for bifurcation feature detection using the YOLOv8x model, in accordance with an embodiment of the present disclosure;

FIG. 20(h) illustrates a validation loss function variation with respect to training epochs for bifurcation feature detection using the YOLOv8x model, in accordance with an embodiment of the present disclosure;

FIG. 20(i) illustrates a conceptual representation of a ridge-end feature detected by the YOLOv8x model during training, in accordance with an embodiment of the present disclosure;

FIG. 20(j) illustrates a confusion matrix representing classification results for ridge-end features obtained using the YOLOv8x model, in accordance with an embodiment of the present disclosure;

FIG. 20(k) illustrates a precision plot for ridge-end feature detection over training epochs, in accordance with an embodiment of the present disclosure;

FIG. 20(l) illustrates a recall plot for ridge-end feature detection over training epochs, in accordance with an embodiment of the present disclosure;

FIG. 20(m) illustrates mean Average Precision at 50% IoU (mAP@50) scores for ridge-end feature detection over training epochs, in accordance with an embodiment of the present disclosure;

FIG. 20(n) illustrates mean Average Precision at 50-95% IoU (mAP@50-95) scores for ridge-end feature detection over training epochs, in accordance with an embodiment of the present disclosure;

FIG. 20(o) illustrates a training loss function variation with respect to training epochs for ridge-end feature detection using the YOLOv8x model, in accordance with an embodiment of the present disclosure;

FIG. 20(p) illustrates a validation loss function variation with respect to training epochs for ridge-end feature detection using the YOLOv8x model, in accordance with an embodiment of the present disclosure;

FIG. 21(a) illustrates a conceptual representation of a loop feature detected by the YOLOv8x model during training, in accordance with an embodiment of the present disclosure;

FIG. 21(b) illustrates a confusion matrix representing classification results for loop feature detection obtained using the YOLOv8x model, in accordance with an embodiment of the present disclosure;

FIG. 21(c) illustrates a precision plot for loop feature detection over training epochs, in accordance with an embodiment of the present disclosure;

FIG. 21(d) illustrates a recall plot for loop feature detection over training epochs, in accordance with an embodiment of the present disclosure;

FIG. 21(e) illustrates mean Average Precision at 50% IoU (mAP@50) scores for loop feature detection over training epochs, in accordance with an embodiment of the present disclosure;

FIG. 21(f) illustrates mean Average Precision at 50-95% IoU (mAP@50-95) scores for loop feature detection over training epochs, in accordance with an embodiment of the present disclosure;

FIG. 21(g) illustrates a training loss function variation with respect to training epochs for loop feature detection using the YOLOv8x model, in accordance with an embodiment of the present disclosure;

FIG. 21(h) illustrates a validation loss function variation with respect to training epochs for loop feature detection using the YOLOv8x model, in accordance with an embodiment of the present disclosure;

FIG. 22(a) illustrates a precision versus confidence curve for bifurcation feature detection using the YOLOv8x model, in accordance with an embodiment of the present disclosure;

FIG. 22(b) illustrates a precision versus confidence curve for ridge-end feature detection using the YOLOv8x model, in accordance with an embodiment of the present disclosure;

FIG. 22(c) illustrates a precision versus confidence curve for loop feature detection using the YOLOv8x model, in accordance with an embodiment of the present disclosure;

FIG. 22(d) illustrates a recall versus confidence curve for bifurcation feature detection using the YOLOv8x model, in accordance with an embodiment of the present disclosure;

FIG. 22(e) illustrates a recall versus confidence curve for ridge-end feature detection using the YOLOv8x model, in accordance with an embodiment of the present disclosure;

FIG. 22(f) illustrates a recall versus confidence curve for loop feature detection using the YOLOv8x model, in accordance with an embodiment of the present disclosure;

FIG. 22(g) illustrates a precision versus recall curve for bifurcation feature detection using the YOLOv8x model, in accordance with an embodiment of the present disclosure;

FIG. 22(h) illustrates a precision versus recall curve for ridge-end feature detection using the YOLOv8x model, in accordance with an embodiment of the present disclosure;

FIG. 22(i) illustrates a precision versus recall curve for loop feature detection using the YOLOv8x model, in accordance with an embodiment of the present disclosure;

FIG. 22(j) illustrates an F1-score versus confidence curve for bifurcation feature detection using the YOLOv8x model, in accordance with an embodiment of the present disclosure;

FIG. 22(k) illustrates an F1-score versus confidence curve for ridge-end feature detection using the YOLOv8x model, in accordance with an embodiment of the present disclosure;

FIG. 22(l) illustrates an F1-score versus confidence curve for loop feature detection using the YOLOv8x model, in accordance with an embodiment of the present disclosure;

FIG. 23(a) illustrates cross-point labels for detected bifurcation features in fingerprint images, in accordance with an embodiment of the present disclosure;

FIG. 23(b) illustrates cross-point labels for detected ridge-end features in fingerprint images, in accordance with an embodiment of the present disclosure;

FIG. 23(c) illustrates cross-point labels for detected loop features in fingerprint images, in accordance with an embodiment of the present disclosure;

FIG. 23(d) illustrates a labels correlogram representing correlations among detected bifurcation features, in accordance with an embodiment of the present disclosure;

FIG. 23(e) illustrates a labels correlogram representing correlations among detected ridge-end features, in accordance with an embodiment of the present disclosure;

FIG. 23(f) illustrates a labels correlogram representing correlations among detected loop features, in accordance with an embodiment of the present disclosure;

FIG. 24(a) illustrates latent fingerprint patterns (LFPs) developed using commercial white, black, green, orange, and red phosphors and SMGO:2% Eu³⁺ phosphor on a substrate, in accordance with an embodiment of the present disclosure;

FIG. 24(b) illustrates a three-dimensional surface plot corresponding to the latent fingerprint patterns developed using commercial phosphors and SMGO:2% Eu³⁺ phosphor, in accordance with an embodiment of the present disclosure;

FIG. 24(c) pixel intensity profiles of the LFPs developed using commercial white, black, green, orange, red phosphors and SMGO:2% Eu³⁺ phosphor, in accordance with an embodiment of the present disclosure;

FIG. 25 illustrates a table showing Comparative analysis of SMGO:Eu³⁺ phosphors with reported Eu³⁺ doped phosphors, in accordance with an embodiment of the present disclosure;

FIG. 26 illustrates a table showing Obtained Rietveld refinement parameters of SMGO:x % Eu³⁺ (0-6 mol %) phosphors, in accordance with an embodiment of the present disclosure;

FIG. 27 illustrates a table showing Estimated values of crystallite size (D), micro strain (ε), dislocation density (δ) and stacking fault of SMGO:x % Eu³⁺ (0-6 mol %) phosphors, in accordance with an embodiment of the present disclosure;

FIG. 28 illustrates a table showing Estimated CIE coordinates, CCT and CP values of SMGO:x % Eu³⁺ (0-6 mol %) phosphors, in accordance with an embodiment of the present disclosure;

FIG. 29 illustrates a table showing Judd-Ofelt intensity parameters (Ω₂, Ω₄), radiative transition probabilities (A_{0-J}), total radiative rates (Aᵣ), luminescence lifetime (τ_{rad}), branching ratio (β), and asymmetric ratio (R) for SMGO:Eu³⁺ phosphors with varying Eu³⁺ (1-6 mol %) concentrations, in accordance with an embodiment of the present disclosure;

FIG. 30 illustrates a table showing Comparison of I_{QE} of SMGO:2% Eu³⁺ with other Eu³⁺ doped phosphors, in accordance with an embodiment of the present disclosure;

FIG. 31 illustrate a table showing Comparison of activation energy (Eₐ) of SMGO:2% Eu³⁺ phosphors with other reported phosphors, in accordance with an embodiment of the present disclosure;

FIG. 32 illustrates a table showing Obtained color parameters including CP, CIE, CCT chroma-coordinates for SMGO:2% Eu³⁺ phosphors at different temperatures (300-480 K), in accordance with an embodiment of the present disclosure;

FIG. 33 illustrates a table showing Comparison of relative sensitivity (Sr) of SMGO:2% Eu³⁺ Phosphors with other reported phosphors, in accordance with an embodiment of the present disclosure;

FIG. 34 illustrates a table showing values of CIE chromaticity coordinates, CCT, Rₐ, R₁₂, R₉ and LE of the Fabricated w-LED using SMGO:2% Eu³⁺ phosphors device driven by different currents, in accordance with an embodiment of the present disclosure; and

FIG. 35 illustrates a flow chart of a process for synthesizing europium-doped Europium-doped strontium magnesium germinate (Sr₂MgGe₂O₇) phosphors for white LEDs, latent fingerprint detection, and anti-counterfeiting applications, in accordance with an embodiment of the present disclosure.

Further, skilled artisans will appreciate that elements in the drawings are illustrated for simplicity and may not have been necessarily been drawn to scale. For example, the flow charts illustrate the method in terms of the most prominent steps involved to help to improve understanding of aspects of the present disclosure. Furthermore, in terms of the construction of the device, one or more components of the device may have been represented in the drawings by conventional symbols, and the drawings may show only those specific details that are pertinent to understanding the embodiments of the present disclosure so as not to obscure the drawings with details that will be readily apparent to those of ordinary skill in the art having benefit of the description herein.

### DETAILED DESCRIPTION

It will be understood by those skilled in the art that the foregoing general description and the following detailed description are exemplary and explanatory of the invention and are not intended to be restrictive thereof. Reference throughout this specification to “an aspect”, “another aspect” or similar language means that a particular feature, structure, or characteristic described in connection with the embodiment is included in at least one embodiment of the present disclosure. Thus, appearances of the phrase “in an embodiment”, “in another embodiment” and similar language throughout this specification may, but do not necessarily, all refer to the same embodiment. The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components. Unless otherwise defined, all technical and scientific terms used herein have the same meaning as commonly understood by one of ordinary skill in the art to which this invention belongs. The system, methods, and examples provided herein are illustrative only and not intended to be limiting.

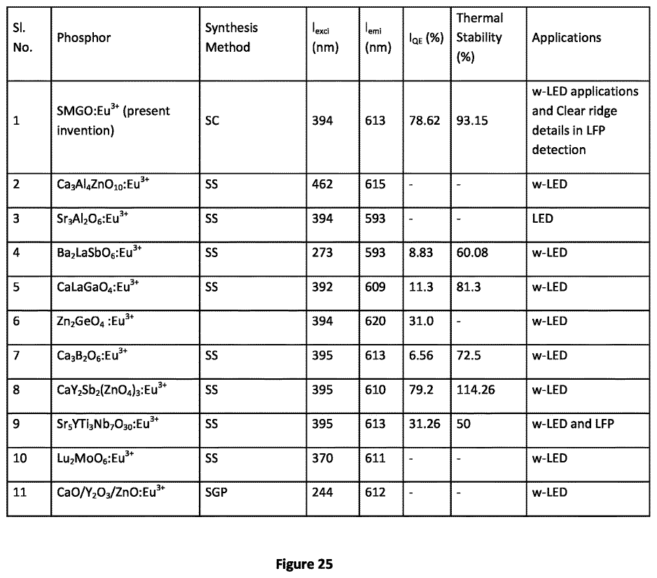

The present invention relates to the synthesis, characterization, and multifunctional applications of SMGO:Eu³⁺ phosphors prepared via a solution combustion technique. Their suitability is evaluated for three critical applications, including: (1) as a red phosphor to enhance color quality and thermal stability in w-LEDs, (2) for AC purposes owing to their distinct and durable luminescence, and (3) in LFP detection, utilizing the YOLOv8x deep learning framework for improved detection accuracy. This disclosure provides in-depth insights into the structure-property relationships of SMGO:Eu³⁺ phosphors and establishes their potential for versatile applications across optoelectronic, forensic, and security sectors. The present invention relates to the synthesis of Europium-doped strontium magnesium germanate (Sr₂MgGe₂O₇) phosphors for white LEDs, latent fingerprint detection, and anti-counterfeiting applications. A comparative analysis of SMGO:Eu³⁺ phosphors with reported Eu³⁺-activated systems was performed (Table shown in FIG. 25), emphasizing their unique advantages. While prior materials have shown promising red emissions for w-LED applications, many suffer from relatively low quantum efficiency, poor thermal stability, or lack of application versatility. In contrast, the SMGO:Eu³⁺ phosphors synthesized via a green, scalable solution combustion method not only exhibit strong red emission with a high internal quantum efficiency of 78.62% and excellent thermal retention (93.15% at 420 K), but also demonstrate clear and detailed LFP visualization under UV light. Furthermore, their compatibility with modern AI-based biometric systems (YOLOv8x) underscores their potential for cross-disciplinary innovation. Existing literature largely focuses on isolated applications such as w-LEDs or anti-counterfeiting, without assessing their combined utility. This multifunctionality spanning optoelectronics, forensic science, and AI-driven biometrics positions SMGO:Eu³⁺ as a next-generation phosphor system with broader technological relevance than existing single-purpose counterparts.

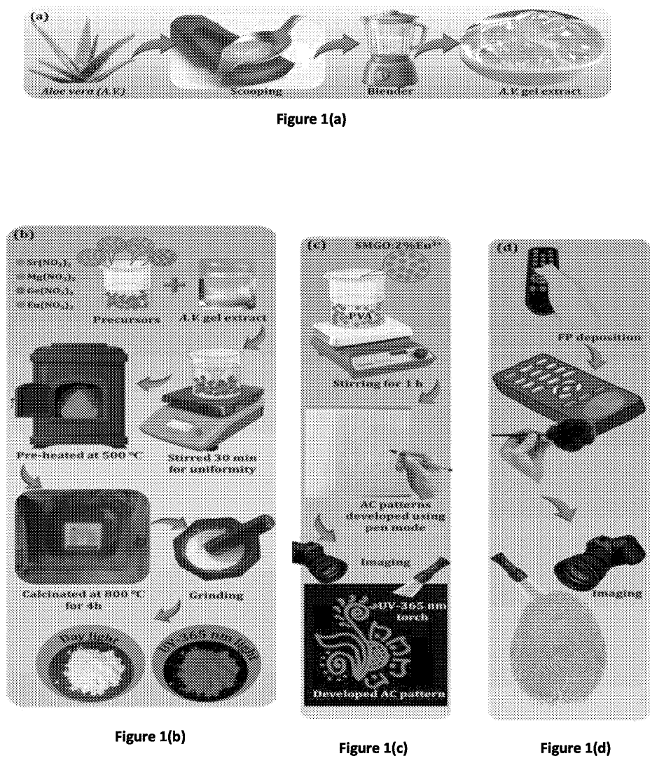

The synthesis process employed high-purity starting materials, including strontium nitrate [Sr(NO₃)₂; 99.99%], magnesium nitrate [Mg(NO₃)₂; 99.99%], germanium dioxide [GeO₂; 99.99%], and europium nitrate [Eu(NO₃)₃; 99.99%], all sourced from Sigma Aldrich, India. These nitrates were used without any additional purification. In the case of oxide precursors, they were transformed into nitrates by dissolving them in nitric acid (HNO₃) solution. A. v. gel extract, utilized as a fuel and complexing agent, A.V. is procured from a local market in Tumakuru, Karnataka, India. Fresh A.V. stems were acquired locally from the Tumkur market in Karnataka, India. The leaves were cleaned thoroughly using distilled water to eliminate surface impurities. The outer green skin was carefully removed using a sterilized knife, and the inner transparent gel was extracted. The gel was then blended into a smooth and uniform consistency using a household blender. The extracted A.V. gel serves dual roles as a green fuel and chelating medium in the phosphor fabrication process. The prepared gel was stored in a sanitized container for subsequent use (FIG. 1(a)).

The SMGO:x % Eu³⁺ (x=0-6 mol %) phosphors were synthesized via a solution combustion technique, with A.V. gel functioning as both a fuel and a natural templating agent. Stoichiometric quantities of Sr(NO₃)₂, Mg(NO₃)₂, Ge(NO₃)₄, and Eu(NO₃)₃, corresponding to varying Eu³⁺ doping levels (0-6 mol %), were accurately weighed and dissolved in a minimal volume of distilled water to form a homogenous solution. A.V. gel was subsequently added in a predetermined amount and thoroughly mixed into the precursor solution. This mixture was stirred continuously at room temperature for 30 min on a magnetic stirrer to achieve a viscous gel-like solution. The mixture was then transferred to a borosilicate beaker and placed inside a muffle furnace preheated to 500° C. The exothermic combustion reaction resulted in the formation of a porous, spongy mass due to the rapid evolution of gases. Post-combustion, the obtained product was subjected to calcination at 800° C. for 4 h to enhance crystallinity and eliminate residual organic content. After natural cooling to room temperature, the resulting material was collected and finely ground using an agate mortar and pestle to obtain the final SMGO:x % Eu³⁺ phosphor powders. This procedure was repeated for all specified Eu³⁺ concentrations. A schematic representation of the synthesis process is shown in FIG. 1(b). To construct w-LED devices, an EL Spectrum HP9000 instrument was employed. The synthesized SMGO:2% Eu³⁺ red-emitting phosphor was mixed with commercially available blue-emitting BAM:Eu²⁺ and green-emitting (Ba,Sr)₂SiO₄:Eu²⁺ phosphors. This phosphor blend was combined with a 398 nm (1 W) blue LED chip. ZWL8820 organic silica gel served as the encapsulating medium, with the phosphors and gel combined in a mass ratio of 1:1:2, respectively. The phosphor-silica mixture was thoroughly stirred to ensure even dispersion and then uniformly applied over the blue chip surface. The composite was cured at 100° C. for 10 h to solidify the encapsulation and secure the phosphors in place. These fabricated LED devices were subsequently subjected to performance testing to analyze their photometric and electrical properties.

To prepare a security ink formulation, 10 mL of distilled water was mixed with polyvinyl alcohol (PVA) to act as a binder. The solution was heated to 85° C. with continuous stirring until a clear, uniform solution was achieved. The synthesized SMGO:2% Eu³⁺ phosphor powder was then incorporated into the solution, followed by ultrasonic treatment to ensure homogeneous dispersion and avoid particle agglomeration. The resulting ink was applied to various substrates such as paper, plastic sheets, aluminium foil, glass, wood with painted surfaces, currency notes, and metal plates using a sketch pen. This method enabled the creation of fine and detailed patterns. As shown in FIG. 1(c), the ink's luminescent patterns were observed under daylight, ultraviolet light (365 nm), and complete darkness. Under ambient light, patterns appeared faint due to residual PVA markings. Upon UV exposure, a bright red emission was observed, facilitating clear visualization and authentication. The ink demonstrated good adhesion across different substrates and maintained consistent luminescence under UV irradiation, indicating its suitability for long-term security applications.

LFP samples were obtained from a 24-year-old male volunteer, ensuring no prior treatment on the fingertip to retain natural skin oils. The volunteer pressed his thumb onto different substrates including paper, aluminium foil, and ceramic tiles. The SMGO:2% Eu³⁺ phosphor powder was gently dusted over the FP impressions using a soft brush to allow the powder to adhere to the FP ridges. Excess powder was carefully removed, enhancing the ridge pattern visibility. The developed prints were captured using a Canon EOS 4000D DSLR camera equipped with an EF-S 18-55 mm f/3.5-5.6 III lens under 365 nm UV illumination. This method provided high-contrast, detailed FP images suitable for forensic documentation (illustrated in FIG. 1(d)).

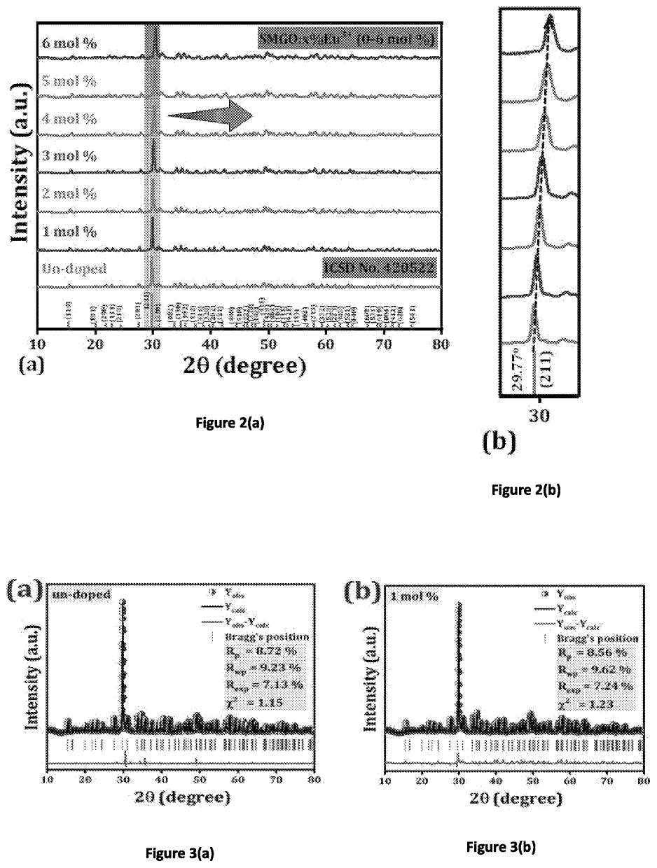

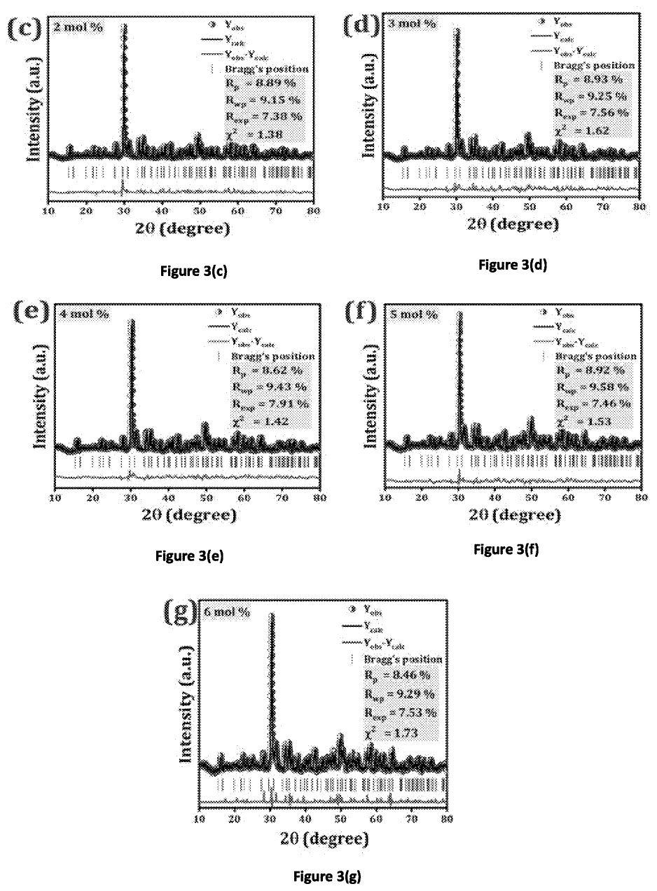

The phase composition and crystalline structure of SMGO:x % Eu³⁺ (0-6 mol %) phosphors with varying concentrations of Eu³⁺ ions (0-6 mol %) were investigated using PXRD. The corresponding diffraction patterns are presented in FIG. 2(a). The characteristic diffraction peaks of both undoped and Eu³⁺-doped samples exhibit excellent alignment with the reference ICSD no. 420522, confirming the formation of a tetragonal melilite-type structure without the presence of secondary phases. The presence of sharp and well-defined peaks in the XRD spectra indicates the high crystallinity of the synthesized materials. With increasing Eu³⁺ concentration, a progressive shift in peak positions toward higher angles is observed (FIG. 2(b)), signifying successful substitution of Eu³⁺ ions into the Sr²⁺ lattice sites of the SMGO structure. This shift is attributed to the difference in ionic radii between Sr²⁺ (1.18 Å) and Eu³⁺ (0.947 Å), leading to a slight contraction in the crystal lattice. To assess the substitutional effect, the ionic radius mismatch between the host cation and the dopant ion is quantified using the following equation.

$${D}_{r} = \frac{\vert {R}_{h} ( CN ) - {R}_{d} ( CN ) \vert}{{R}_{h} ( CN )} \times 100 \% \qquad ( 1 )$$

Here, R_{d}, Rₕ and Dᵣ represent the ionic radius of the host cation, dopant ion, and their percentage difference, respectively, while CN denotes the coordination number. In this system, initially, considering coordination number CN=6, Eu³⁺ (0.947 Å) substituting for Sr²⁺ (1.18 Å) results in a calculated Dᵣ of 19.7%. For comparison, the Dᵣ values for Mg²⁺ (0.72 Å) and Ge⁴⁺ (0.53 Å), both also with CN=6, are 32% and 72%, respectively. These values suggest that Eu³⁺ is more likely to substitute Sr²⁺ than either Mg²⁺ or Ge⁴⁺ in this coordination environment. However, it is important to note that in the SMGO structure, Sr²⁺ ions actually occupies eight-coordinated sites (CN=8, 1.26 Å). Under this coordination environment, Eu³⁺ (1.066 Å) yields a Dᵣ of 15.4% when substituting for Sr²⁺. For Mg²⁺ (CN=8, 0.89 Å), the Dᵣ is 20%, which also falls within the acceptable substitutional range (generally below 30%). Nonetheless, considering factors such as ionic size compatibility, valence state matching, and coordination preference, Eu³⁺ ions are still more favorably incorporated at the Sr²⁺ site. Ge⁴⁺ does not exhibit CN=8 coordination, further ruling it out as a plausible substitution site. Since substitutional tolerance is generally acceptable when Dᵣ is below 30%, these findings consistently indicate that Eu³⁺ ions preferentially substitute Sr²⁺ sites in the SMGO lattice.

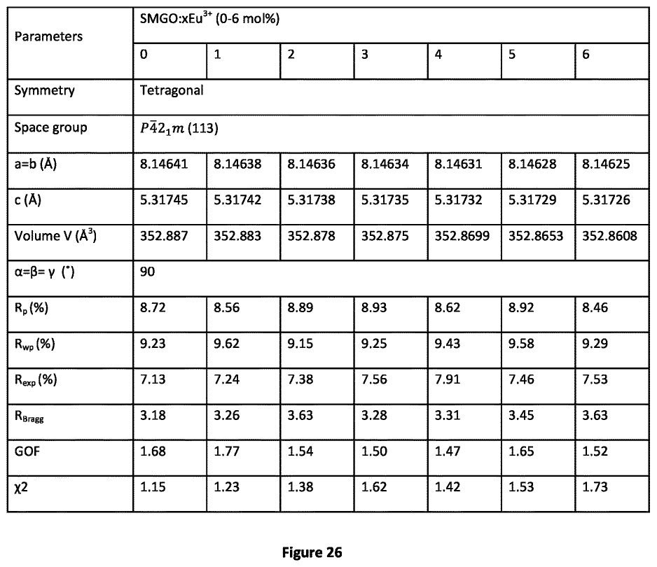

Rietveld refinement was carried out for SMGO doped with Eu³⁺ (0-6 mol %) using FullProf Suite software, as depicted in FIGS. (3(a)-3(g)). The refined pattern showed excellent agreement with the experimental data, as evidenced by low residual error factors (R_{wp}<9.5%) and a chi-square values close to 1 (χ^{z}≈1), indicating a reliable structural model. The refinement results suggest that the incorporation of Eu³⁺ ions does not significantly disrupt the host lattice structure. The corresponding refinement data, provided in Table as shown in FIG. 26, offer insights into how structural parameters evolve with dopant concentration, further confirming the successful substitution of Eu³⁺ ions in Sr²⁺ sites across all compositions.

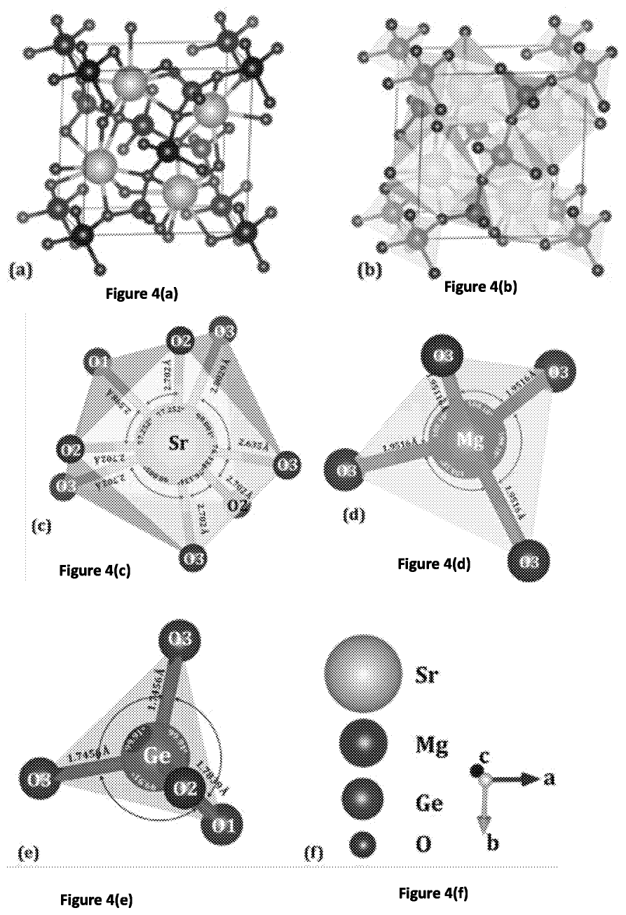

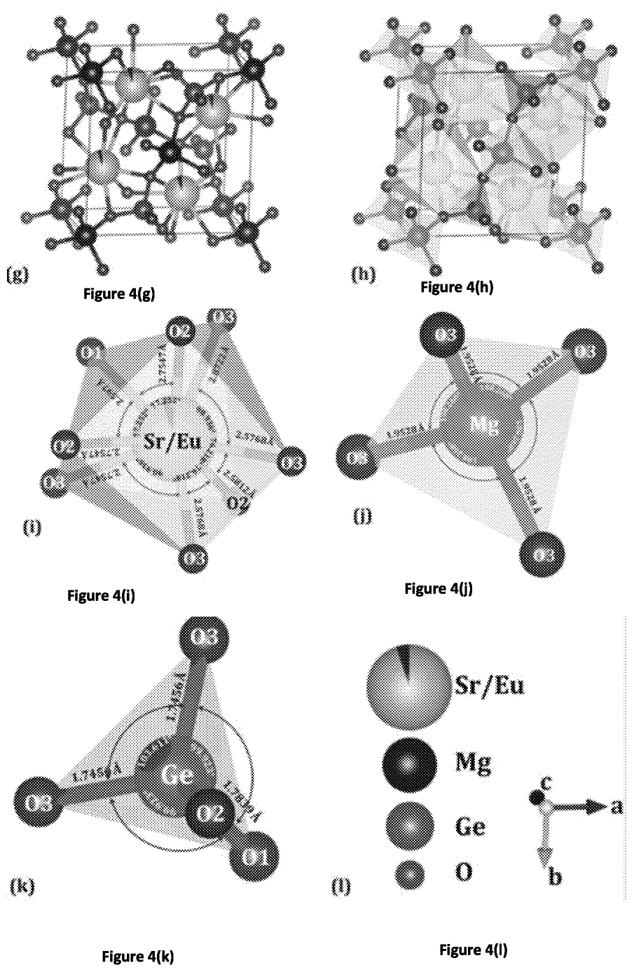

To provide a clear understanding of the structural changes induced by Eu³⁺ doping, detailed crystal structure models of both undoped SMGO and 2 mol % Eu³⁺-doped SMGO were visualized using the VESTA 3.5.8 software, based on Crystallographic Information Files (CIFs) refined from Rietveld analysis. The FIG. 4(a, b, c, d, e, and f) represents the undoped SMGO crystal structure, while the FIG. 4(g, h, i, j, k, and l) depicts the Eu³⁺ doped counterpart. Both structures crystallize in the tetragonal non-centrosymmetric melilite-type lattice (space group P4̅2₁m), characterized by a three-dimensional network of interconnected tetrahedral and dodecahedral units. FIGS. 4(a), 4(b), 4(g) & 4(h) illustrate the overall atomic arrangement in ball-and-stick and polyhedral formats, respectively. The host matrix is composed of rigid [GeO₄] and [MgO₄] tetrahedra, interspersed with larger [SrO₈] dodecahedra that provide the primary sites for Eu³⁺ incorporation. The substitution of Sr²⁺ (CN=8, 1.26 Å) by Eu³⁺ (CN=8, 1.12 Å) occurs without disrupting the global symmetry, owing to their similar ionic sizes. However, localized structural distortions are expected due to the slightly smaller size and higher charge of Eu³⁺.

FIGS. 4(c) & 4(i) provide a magnified comparison of the [SrO₈] and [Sr/EuO₈] coordination environments, respectively. In the undoped structure, Sr²⁺ is coordinated by eight oxygen atoms with relatively uniform bond lengths ranging from 2.2021 to 2.7547 Å. The O—Sr—O bond angles span 71.252° to 146.218°, indicating moderate polyhedral distortion inherent to the melilite framework. Upon Eu³⁺ doping, the Eu-0 bonds show a more asymmetric distribution, with lengths ranging from 2.5768 to 2.8722 Å. Additionally, the bond angles become more widely dispersed (76.218° to 162.480°), confirming local lattice contraction and increased distortion within the [Sr/EuO₈] polyhedron. These structural changes are consistent with the XRD peak shifts observed in the doped samples and affirm the successful incorporation of Eu³⁺ ions into the Sr²⁺ sublattice.

FIGS. 4(d) & 4(j) show the local geometry of the [MgO₄] tetrahedra before and after Eu³⁺ doping. Each Mg²⁺ ion remains tetrahedrally coordinated by four oxygen atoms, with negligible changes in bond lengths (~1.9516-1.9528 Å) and bond angles (~108.26° to 110.32°). This indicates that the [MgO₄] units retain their geometric integrity upon Eu³⁺ substitution and are not significantly affected by the nearby lattice distortion.

Similarly, FIGS. 4(e) & 4(k) display the [GeO₄] tetrahedra, which serve as the backbone of the melilite framework. The Ge—O bond lengths are uniformly ~1.7456 Å in both undoped and doped samples, and the corresponding O—Ge—O angles (~99.9° to 103.6°) remain unchanged. These observations suggest that the rigid [Ge₂O₇] groups, formed by corner-sharing [GeO₄] units, continue to maintain structural rigidity and contribute to the framework's mechanical stability despite Eu³⁺ doping. FIGS. 4(f) & 4(l) shows the atomic legend and compass. The collective comparison of undoped and doped structures indicates that Eu³⁺ doping selectively perturbs the Sr²⁺ sublattice, inducing local distortions in the [Sr/EuO₈] coordination environment while preserving the tetrahedral network of Mg²⁺ and Ge⁴⁺. The structural rigidity provided by the [Ge₂O₇] units allows the lattice to accommodate aliovalent doping with minimal global deformation. This structural robustness underpins the observed optical and functional properties and validates the potential of SMGO as a versatile host matrix for rare-earth ion doping.

The average crystallite size of the phosphors was determined using the Scherrer's equation.

$$D = \frac{k λ}{β cos θ} \qquad ( 2 )$$

where D is the mean crystallite size, k is the shape factor (typically 0.94), λ is the X-ray wavelength, β is the full width at half maximum (FWHM) of the diffraction peak, and θ is the Bragg angle.

Furthermore, micro-strain (ε) and D were estimated using the Williamson-Hall (W-H) approach, which is described by the equation.

$$β Cos θ = \frac{k λ}{D} + η sin θ \qquad ( 3 )$$

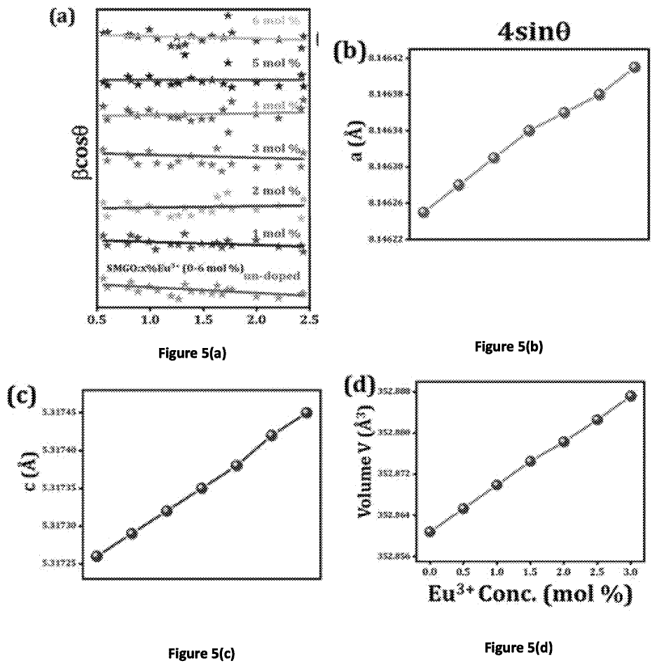

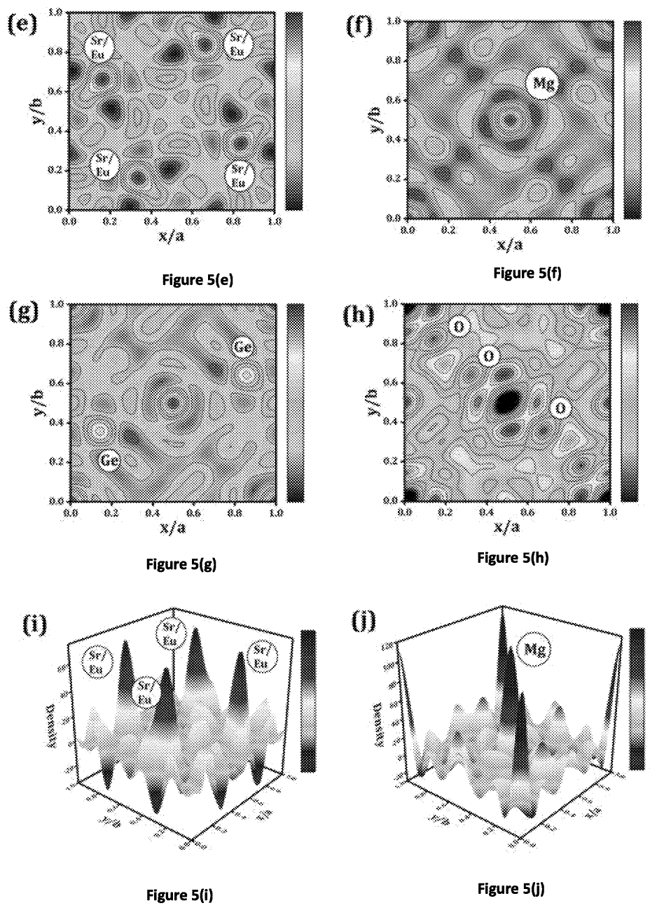

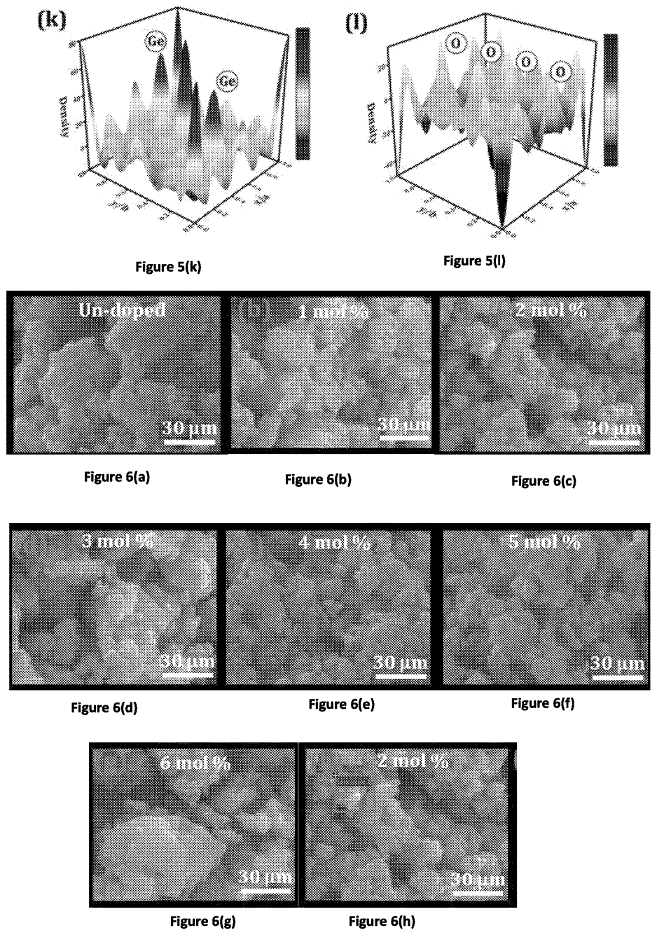

The corresponding W—H plots (FIG. 5(a)) were used to determine both crystallite size and strain for all SMGO:x % Eu³⁺ samples.

ε, arising from structural imperfections and distortions, was also calculated using the Stokes and Wilson relation.

$$ε = \frac{β cos θ}{4} \qquad ( 4 )$$

Dislocation density (δ), representing the density of crystallographic defects, was calculated as follows

$$δ = \frac{1}{{D}^{2}} \qquad ( 5 )$$

In addition, stacking fault (SF) probabilities were estimated using the equation.

$$SF = [ \frac{2 {π}^{2}}{45 {( 3 tan θ )}^{\frac{1}{2}}} ] β \qquad ( 6 )$$

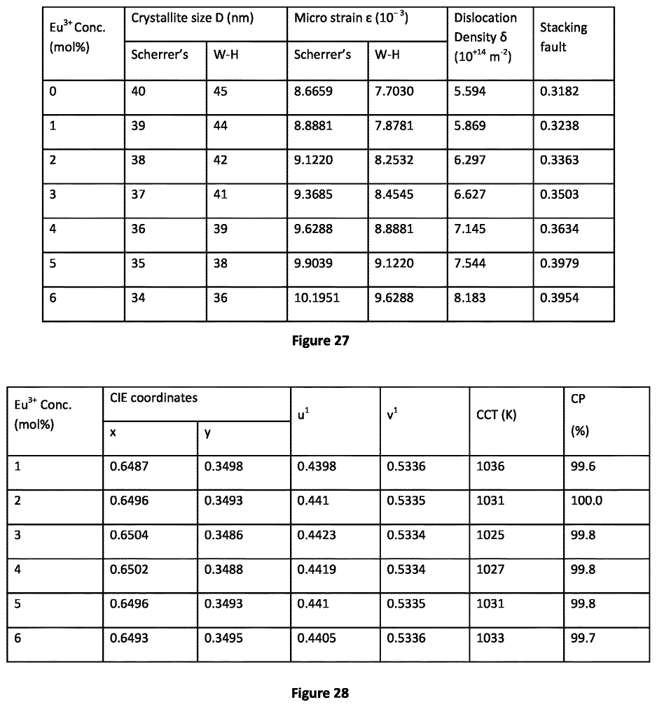

The incorporation of Eu³⁺ ions induces subtle yet measurable changes in the lattice parameters, indicating slight distortions within the SMGO crystal structure without disrupting its overall framework. These structural modifications are further supported by changes in crystallographic features such as crystallite size, lattice strain, dislocation density, and stacking fault probability, offering deeper insight into the impact of Eu³⁺ doping on the host matrix. As shown in Table shown in FIG. 27, the crystallite size decreases with increasing Eu³⁺ concentration, accompanied by a corresponding rise in microstrain. These trends underscore the structural adaptability of the SMGO lattice, affirming its potential for optoelectronic applications. Furthermore, a gradual decrease in the lattice parameters (a, b, c) and unit cell volume (V) is observed with increasing Eu³⁺ content, consistent with the peak shifts toward higher 2θ angles in the XRD patterns (FIGS. 5(b)-5(d)).

Electron density mapping (EDM) is performed to gain detailed insight into the electronic structure and bonding nature of the SMGO:2% Eu³⁺ crystal lattice. Based on the INF data file derived from Rietveld refinement; electron density maps are generated using the GFourier module within the FullProfSuite. FIGS. 5(e)-5(h) displays two-dimensional electron density maps, where the electron distribution around atomic positions is visualized through contour patterns corresponding to distinct charge concentration levels. Furthermore, the three-dimensional electron density maps (FIGS. 5(i)-5(l))) corresponding to Sr/Eu, Mg, Ge, and O atomic sites exhibit a uniformly distributed and interconnected electron cloud, forming a continuous mesh-like framework throughout the unit cell. These observations indicate robust atomic bonding and a highly ordered crystalline framework. Notably, elements such as Sr/Eu, Mg, and Ge exhibit higher electron density concentrations, attributable to their greater X-ray scattering factors, while the oxygen atoms manifest relatively diffuse density regions due to their lower atomic number. The analysis strongly indicates that Eu³⁺ ions predominantly replace Sr²⁺ at the 2a Wyckoff site, which alters the local electronic environment and introduces slight asymmetries in the surrounding tetrahedral coordination. These localized changes suggest that the substitution induces mild lattice strain without significantly disrupting the overall crystal symmetry. The altered charge distribution resulting from Eu³⁺ incorporation impacts charge transport dynamics and promotes the formation of localized defect states, which collectively modulate the optical and electronic properties of the SMGO:2% Eu³⁺ phosphor. Despite these local perturbations, the EDM analysis confirms that the overall melilite-type crystal framework retains its structural integrity post doping.

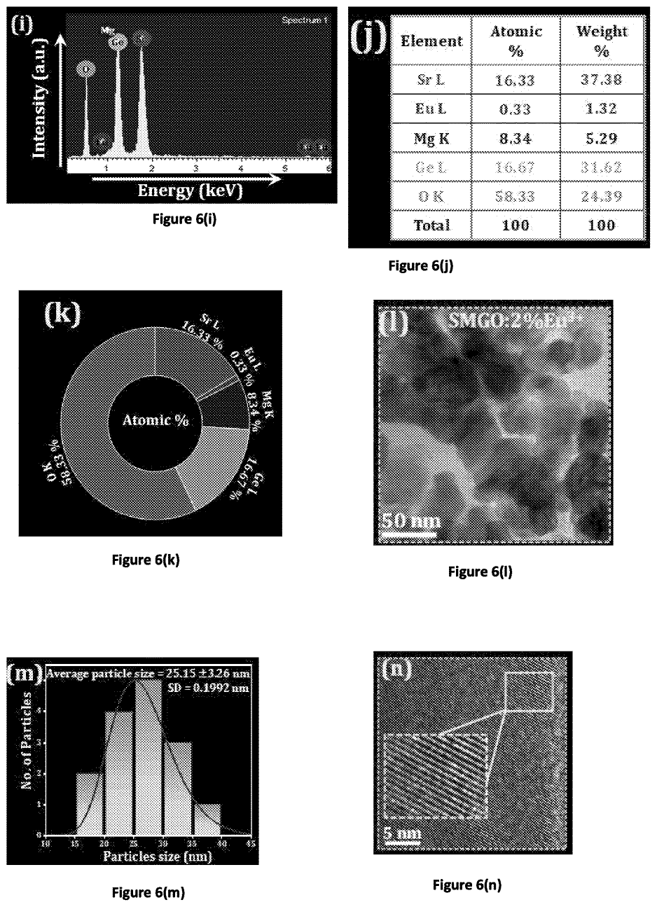

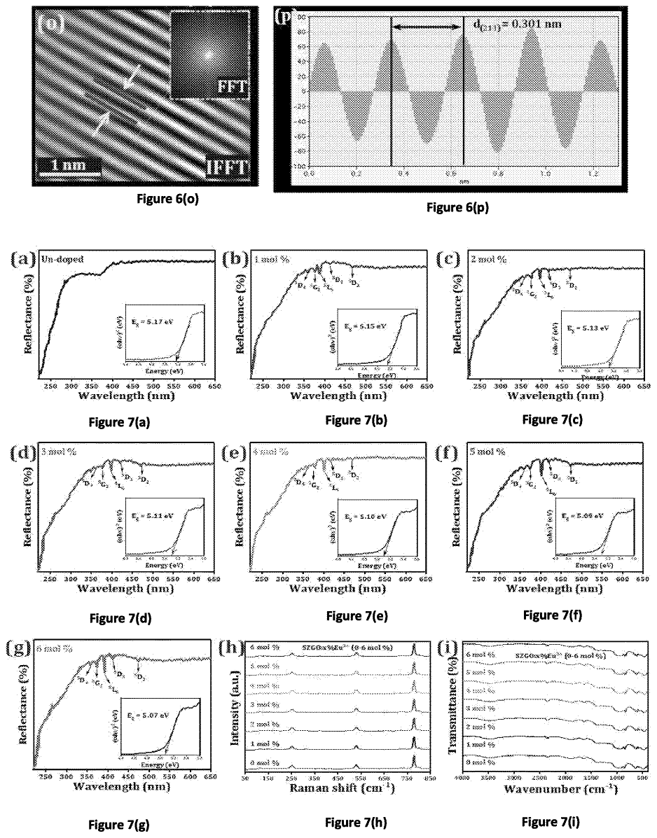

The surface morphology of SMGO:x % Eu³⁺ (x=0-6 mol %) phosphors was analyzed using FE-SEM, with the corresponding micrographs displayed in FIGS. 6(a)-6(g). The images reveal a predominantly agglomerated microstructure characterized by irregularly shaped particles across all Eu³⁺ doping concentrations. The phosphor particles exhibit a dense texture, and no distinct secondary phases are detected upon Eu³⁺ incorporation. Although minor changes in particle size and edge definition are observed with increasing dopant levels, the overall morphology remains largely uniform and consistent. These observations indicate that Eu³⁺ doping does not lead to any significant structural disruption but may subtly influence grain growth mechanisms during synthesis. FIG. 6(h) presents the FE-SEM image of the selected region in SMGO:2% Eu³⁺ phosphors. The corresponding EDS spectrum (FIG. 6(i)) confirms the presence of Sr, Mg, Ge, O and Eu, verifying the successful incorporation of Eu³⁺ into the host lattice. FIGS. 6(j) & 6(k) provides a quantitative analysis in the form of a table, summarizing the atomic and weight percentages of these elements within the selected region, thereby validating the stoichiometric composition of the synthesized phosphors.

To gain further insight into the microstructural features, TEM was employed for SMGO:2% Eu³⁺ phosphors. As illustrated in FIG. 6(l), the TEM images show well-dispersed particles with minimal agglomeration, aligning with the FE-SEM results. Statistical analysis of particle size, based on measurements from 15 randomly chosen nanoparticles and illustrated via a log-normal fitted histogram (FIG. 6(m)), reveals an average size ranging from 15 to 25 nm. This confirms the nanometric scale and indicates a relatively uniform size distribution among the synthesized phosphors. High-resolution TEM (HR-TEM) imaging (FIG. 6(n)) highlights distinct lattice fringes, confirming the crystalline nature and ordered atomic arrangement within the material.

To further investigate the crystallographic features at the nanoscale, Fast Fourier Transform (FFT) and inverse FFT (IFFT) analyses were carried out using the GA TAN software suite. These tools enabled detailed evaluation of periodicity, lattice orientation, and local structural order. The FFT and IFFT images (FIG. 6(o)) display discrete diffraction spots, indicative of a well-ordered crystalline structure. FIG. 6(p) presents a pixel intensity profile derived from the IFFT image corresponding to the (211) lattice plane. The observed interplanar distance (d) of 0.301 nm closely matches the theoretical value calculated from PXRD, validating both the phase purity of the material and the effective incorporation of Eu³⁺ ions into the SMGO lattice without inducing major structural distortions.

UV-visible DRS was employed to examine the optical characteristics of SMGO:x % Eu³⁺ (x=0-6 mol %) phosphors, with the reflectance spectra illustrating the influence of dopant concentration as shown in FIG. 7(a)-7(g). All samples, including the undoped and Eu³⁺-substituted SMGO phosphors, exhibit a distinct absorption feature near 250 nm, corresponding to inherent electronic transitions within the host crystal framework. The absorption intensity remains fairly stable across all doping concentrations, suggesting that Eu³⁺ incorporation does not notably alter the fundamental optical characteristics of the host material. Additionally, an absorption band observed around 391 nm (within the 350-500 nm range) corresponds to the characteristic 4f-4f electronic transitions of Eu³⁺ ions. Beyond the host's intrinsic absorption, extra absorption features appear in the UV region for the Eu³⁺-doped samples, aligning well with excitation transitions identified in the PLE spectra of Eu³⁺ ions. This alignment confirms that Eu³⁺ ions actively participate in the absorption processes and contribute to the material's optical behavior. The variation in optical band gap energy (E_{g}) resulting from different Eu³⁺ doping concentrations in SMGO was analyzed using Tauc's plot, employing the standard equation as outlined in reference:

$${( α hv )}^{1 / n} = A ( hv - {E}_{g} ) \qquad ( 7 )$$

In the above expression, α is the absorption coefficient, h represents Planck's constant, v denotes the photon frequency, A is a proportionality constant specific to the material, and n defines the type of electronic transition involved (e.g., direct or indirect). For direct allowed transitions, n=½, and for indirect allowed transitions, n=2. Tauc's plots derived from the DRS spectra (insets of FIGS. 7(a)-7(g)) reveal a gradual increase in the bandgap energy with increasing Eu³⁺ content. The bandgap energy of undoped SMGO is approximately 5.17 eV. With successive doping, the values decrease incrementally to 5.15, 5.13, 5.11, 5.10, 5.09, and 5.07 eV for Eu³⁺ concentrations of 1, 2, 3, 4, 5, and 6 mol %, respectively. This progressive bandgap narrowing can be attributed to a combination of lattice distortion, defect-state formation, and electronic coupling effects. The substitution of smaller Eu³⁺ ions (0.947 Å) for larger Sr²⁺ ions (1.18 Å) causes local lattice contraction and strain, which modifies the crystal field and orbital overlaps, resulting in a reduced bandgap. Additionally, aliovalent doping introduces charge-compensating defects such as oxygen vacancies or cation site disorder, which create shallow mid-gap states or band tailing. Furthermore, although Eu³+4f orbitals are largely localized, their presence near the conduction band can weakly perturb the band structure, forming intermediate energy levels. Similar mechanisms have been reported in Eu³⁺/Ho³⁺ co-doped Sr₂MgSi₂O₇ systems, confirming that Eu³⁺ doping subtly alters the electronic structure of SMGO and enables bandgap tuning for targeted optical applications.

Raman and FTIR spectroscopy were employed to investigate the vibrational and structural characteristics of SMGO phosphors doped with varying concentrations of Eu³⁺ ions (0-6 mol %) (FIG. 7(h)). The Raman spectra provide key insights into the lattice vibrations and bonding environment within the SMGO host. Prominent Raman bands were detected at approximately 779 cm⁻¹, 529 cm⁻¹, 251 cm⁻¹, and 112 cm⁻¹. The peak at 779 cm⁻¹ corresponds to the symmetric stretching mode of Ge—O—Ge bonds within the [Ge₂O₇] units, which form the backbone of the pyrogermanate framework. The band observed at 529 cm⁻¹ is attributed to the bending vibrations of Ge—O bonds, indicative of the internal vibrational motion within the germanate network. The signal at 251 cm⁻¹ arises from external vibrational modes involving the collective motion of cations in the crystal lattice. Meanwhile, the low-frequency peak around 112 cm⁻¹ is associated with translational and rotational motions of Sr²⁺ and Mg²⁺ ions embedded within the SMGO structure. Notably, the relative intensities and positions of these characteristic vibrational modes remain consistent across all Eu³⁺ concentrations. This invariance implies that Eu³⁺ incorporation does not significantly alter the vibrational dynamics of the lattice or induce structural deformation. The absence of new peaks or significant peak broadening further supports the notion that Eu³⁺ ions are effectively incorporated into the lattice sites without forming secondary phases or introducing amorphous regions. The preservation of these vibrational signatures across different doping levels confirms the structural stability of the SMGO framework and suggests that Eu³⁺ induces only localized lattice distortions without compromising the long-range crystalline order.

Complementary FTIR analysis was performed to further examine the bonding environment and confirm structural integrity following Eu³⁺ doping (0-6 mol %) (FIG. 7(i)). The FTIR spectra revealed distinct absorption bands characteristic of the SMGO host. The band near 770 cm⁻¹ corresponds to Ge—O—Ge stretching vibrations, while the region between 450 and 750 cm⁻¹ is attributed to O—Ge—O bending modes within the Ge-based polyhedral framework. Absorption features in the range of 952-967 cm⁻¹ are assigned to symmetric stretching vibrations of GeO₃ units. Additionally, a broad absorption peak centered around 3400 cm⁻¹ is observed, which is associated with 0-H stretching vibrations originating from adsorbed moisture on the phosphor surface. Slight shifts and minor broadening of specific absorption bands are evident with increasing Eu³⁺ concentration, indicating minor modifications in the local bonding environment due to dopant incorporation. However, the absence of new absorption features or significant changes in the overall spectra confirms that Eu³⁺ substitution does not disrupt the fundamental structural framework or introduce secondary phases. These findings validate the successful incorporation of Eu³⁺ ions into the SMGO host while preserving the overall crystallinity and lattice stability, thereby supporting the potential of these materials for advanced optical applications.

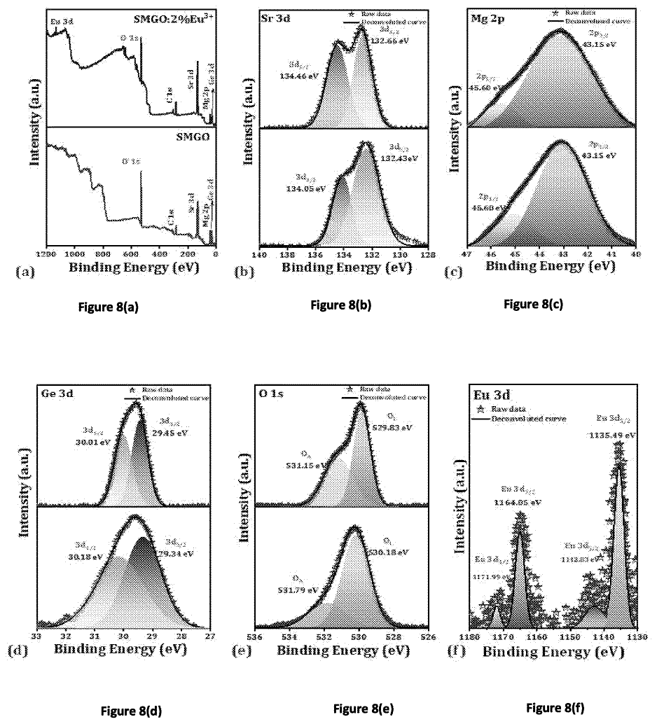

To investigate the chemical composition, oxidation states, and dopant incorporation within the SMGO host lattice, high-resolution XPS was performed on both undoped SMGO and Eu³⁺-doped SMGO:2% Eu³⁺ phosphors. The comparison provides critical insights into the surface chemical environment and verifies the successful substitution of Eu³⁺ ions without altering the host matrix. The wide-scan survey spectra (FIG. 8(a)) clearly confirm the presence of Sr, Mg, Ge, and O in both samples, while Eu peaks are exclusively observed in the doped composition, verifying successful europium incorporation. Notably, no extraneous or impurity-related peaks are detected, indicating the phase purity and chemical cleanliness of both samples. The Sr 3d high-resolution spectra (FIG. 8(b)) exhibit well-resolved doublets at ~134.46 eV and ~132.66 eV, attributed to Sr 3d_{3/2} and Sr 3d_{5/2}, respectively. The nearly identical peak positions and symmetry between the undoped and doped samples confirm that Sr remains in a stable +2 oxidation state and is unaffected by Eu³⁺ doping. Similarly, the Mg 2p spectra (FIG. 8(c)) show peaks at ~45.60 eV and ~43.15 eV, characteristic of Mg²⁺. The consistency across both samples indicates the chemical stability of Mg sites and no detectable change in local coordination upon Eu³⁺ integration. The Ge 3d spectra (FIG. 8(d)) reveal spin-orbit components at ~30.0 eV and ~29.3-29.4 eV for Ge 3d_{3/2} and Ge 3d_{5/2}, respectively, matching Ge⁴⁺ oxidation state. The minor shift in intensity but not energy suggests a structurally preserved local environment. The O 1s spectra (FIG. 8(e)) are deconvoluted into two primary components: a dominant peak at ~529.83-530.18 eV corresponding to lattice oxygen (O_{L}) and a secondary peak at ~531.15-531.79 eV attributed to surface-adsorbed oxygen or hydroxyl groups (O_{A}). The doped sample shows a slightly increased contribution from O_{A}, which may be linked to surface defect generation or modified adsorption behavior due to dopant addition.

Notably, the Eu 3d spectrum (FIG. 8(f)) exclusively appears in the doped sample, with sharp peaks at 1135.49 eV (Eu 3d_{5/2}) and 1164.05 eV (Eu 3d_{3/2}), along with strong satellite peaks at 1142.83 eV and 1171.99 eV. These features unambiguously confirm the presence of Eu³⁺ in the trivalent oxidation state, consistent with earlier literature. The absence of additional peaks further supports the complete substitutional incorporation of Eu³⁺ into the SMGO matrix without the formation of secondary europium-rich phases. Additionally, a C is peak is present in both undoped and doped samples, typically observed around 284.6 eV. This signal originates from adventitious carbon contamination due to atmospheric exposure during sample handling. As it does not reflect intrinsic material properties, it is considered extrinsic and does not impact the interpretation of the phosphor's chemical composition. Collectively, the XPS results demonstrate that all constituent elements in SMGO:Eu³⁺ maintain their expected oxidation states and chemical environments, and that Eu³⁺ ions are successfully and stably incorporated into the host lattice. The comparative analysis with the undoped sample validates the structural resilience and chemical compatibility of the SMGO framework, further substantiating its suitability as a host for rare-earth doping in advanced luminescent applications.

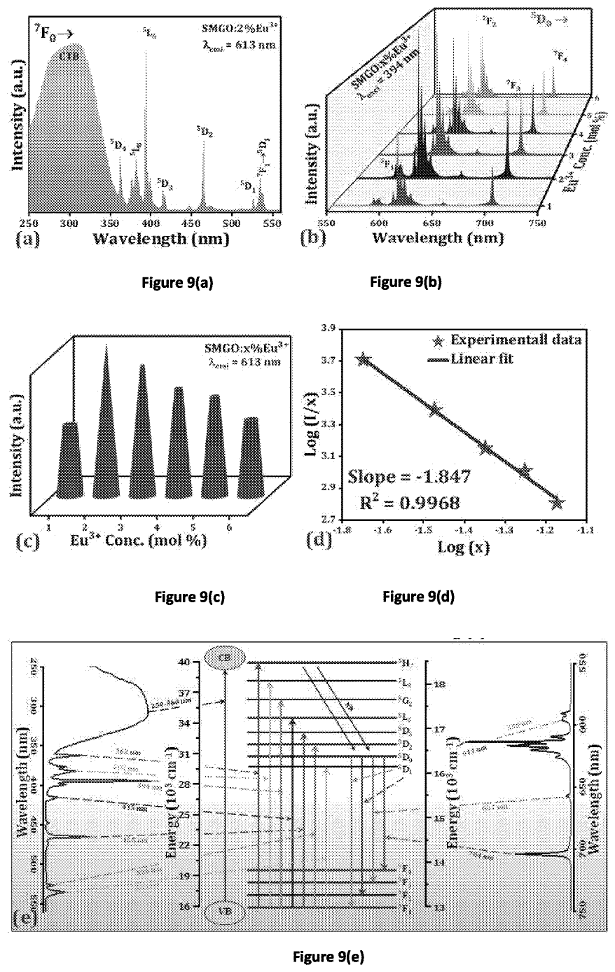

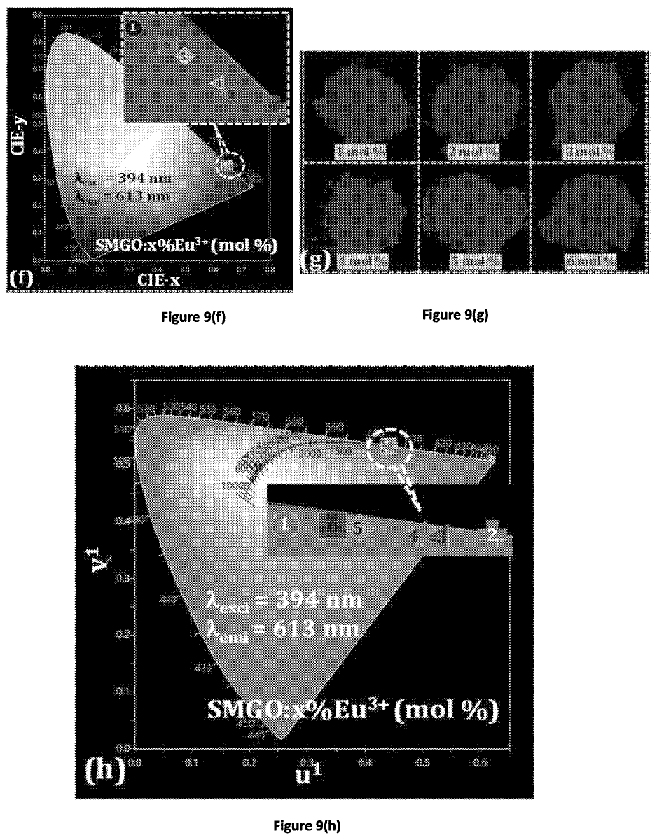

The excitation behavior of SMGO phosphors doped with 2 mol % Eu³⁺ was investigated using photoluminescence spectroscopy, as shown in FIG. 9(a). The excitation spectrum, recorded at an emission wavelength of 613 nm, reveals a broad band extending from 250 to 360 nm, along with several discrete absorption peaks spanning the 360-600 nm range. The broad excitation band is attributed to the charge transfer (CT) transition between O² ligands and Eu³⁺ ions, whereas the sharp absorption peaks correspond to the intra-4f transitions characteristic of Eu³⁺. Notable transitions include bands at 362 nm, 382 nm, 394 nm, 415 nm, 465 nm, 526 nm and 535 nm, each corresponding to specific transitions from the ground ⁷F_{θ} level to higher excited states of Eu³⁺. Among these, the 394 nm and 465 nm bands are of particular relevance for LED applications, as they align with the emission spectra of n-UV and blue LEDs, respectively. FIG. 9(b) illustrates the emission spectra of SMGO:x % Eu³⁺ phosphors (where x=1-6 mol %) under excitation at 394 nm. The emission profiles consist of prominent peaks at approximately 590 nm, 613 nm, 657 nm, and 704 nm, which are associated with the ⁵D₀→⁷F_{J} (J=1 to 4) transitions of Eu³⁺. Among these, the 613 nm peak-corresponding to the electric dipole (ED)⁵D₀→⁷F₂ transition exhibits the highest intensity, while the magnetic dipole (MD) ⁵D₀→⁷F₁ transition at 590 nm is comparatively weaker. This intense red emission suggests that SMGO:x % Eu³⁺ phosphors are well-suited as red-emitting components in w-LEDs, in combination with green and blue phosphors. The variation in emission intensity with Eu³⁺ doping concentration reveals an initial increase in luminescence, reaching a maximum at 2 mol % Eu³⁺ Beyond this concentration, a decline in intensity is observed, attributed to concentration quenching due to non-radiative energy transfer between closely spaced Eu³⁺ ions. Thus, 2 mol % is identified as the optimal doping concentration for maximizing red emission. As shown in FIG. 9(c), emission intensities for ⁵D₀→⁷F₁ and other transitions also follow a similar trend, further confirming 2 mol % Eu³⁺ as the ideal level for optimal luminescence.

To better understand the energy transfer dynamics leading to quenching, the critical distance (R_{c}) between Eu³⁺ ions was calculated using the equation:

$${R}_{c} = {2 [ \frac{3 V}{4 π {x}_{c} N} ]}^{\frac{1}{3}} \qquad ( 8 )$$

In this context, V denotes the unit cell volume, x_{c} is the critical quenching concentration, and N corresponds to the number of cation sites per unit cell. Based on a unit cell volume of 352.8783 Å³, a quenching concentration of 0.02, and N=2, the calculated critical distance (R_{c}) is approximately 25.63 nm. Since this value substantially exceeds the 0.5 nm threshold generally associated with exchange interactions, it suggests that the observed concentration quenching is predominantly driven by electric multipolar interactions rather than short-range exchange mechanisms. To gain deeper understanding of the quenching mechanism, Dexter's theory of non-radiative energy transfer was applied. According to this model, the relationship between emission intensity (I) and dopant concentration (x) can be described by:

$$\frac{I}{x} = {k [ 1 + {β ( x )}^{\frac{Q}{3}} ]}^{- 1} \qquad ( 9 )$$

Here, k and β are constants, and Q indicates the type of multipolar interaction. A plot of log(I/x) versus log(x), shown in FIG. 9(d), yields a linear relationship with a slope of approximately −1.847. This value closely matches −Q/3, where Q≈5.541, which is near 6 characteristics of electric d-d interactions. This analysis confirms that the quenching mechanism is predominantly governed by d-d interactions between Eu³⁺ ions. This finding aligns with the established classification, where Q values of 6, 8, and 10 denote d-d, dipole-quadrupole (d-q), and quadrupole-quadrupole (q-q) interactions, respectively. As Eu³⁺ content increases, the average distance between dopant ions decreases, increasing the probability of non-radiative transitions due to multipolar interactions. The analysis thus reinforces that d-d energy transfer is the dominant quenching mechanism in SMGO:x % Eu³⁺ phosphors, emphasizing the importance of optimizing doping levels to maintain high emission efficiency for lighting applications.

A schematic representation of the PL mechanism in Eu³⁺-doped SMGO is depicted in FIG. 9(e). Under 394 nm excitation, electrons are excited from the ⁷F₀ ground state to the ⁵L₆ level, followed by non-radiative relaxation to the ⁵D₀ level. From here, radiative transitions occur to various ⁷F_{J} levels, generating emissions at distinct wavelengths 590 nm (⁵D₀→⁷F₁), 613 nm (⁵D₀→⁷F₂), 657 nm (⁵D₀→⁷F₃), and 703 nm (⁵D₀→⁷F₄). The dominant emission at 613 nm, originating from the ED transition, confirms the potential of SMGO:x % Eu³⁺ as an efficient red-emitting phosphor for w-LEDs and solid-state lighting systems.

FIG. 9(f) displays the CIE chromaticity diagram for the SMGO:x % Eu³⁺ phosphors under 394 nm excitation. The chromaticity coordinates for various doping levels (1-6 mol %) consistently fall within the red region of the diagram. Notably, the sample with 2 mol % Eu³⁺ shows coordinates that shift further into the bright red region, indicating enhanced red emission intensity and color saturation.

The CP of the phosphors was calculated using the following formula:

$$CP = \frac{\sqrt{{( {x}_{s} - {x}_{i} )}^{2} + {( {y}_{s} - {y}_{i} )}^{2}}}{{( {x}_{d} - {x}_{i} )}^{2} + {( {y}_{d} - {y}_{i} )}^{2}} \qquad ( 10 )$$

Where (xₛ, yₛ) are the chromaticity coordinates of the sample, (xᵢ, yᵢ) denote the coordinates of the reference white point, and (x_{d}, y_{d}) represent the coordinates corresponding to the dominant wavelength. Higher CP values indicate more vivid and saturated emission. The calculated results confirm superior CP across all compositions, with the highest values recorded at 2 mol % Eu³⁺ concentration. Additionally, FIG. 9(g) displays digital images of the phosphors with varying Eu³⁺ concentrations, visually demonstrating the color evolution with increasing dopant content.

Additionally, the CCT was estimated using McCamy's empirical formula:

$$CCT = 449 {n}^{3} + 3525 {n}^{2} + 6823.3 n + 5520.33 \qquad ( 11 )$$

Where n is calculated as (x−xₑ)/(y−yₑ), and (xₑ, yₑ)=(0.332, 0.1858) represents the chromaticity coordinates of the reference white point. The resulting CCT values indicate that SMGO:x % Eu³⁺ phosphors emit in the warm white range, ideal for indoor lighting applications. Lower CCT values are typically preferred for creating comfortable, visually pleasant lighting environments. A summary of chromaticity coordinates, CP, and CCT values is presented in FIG. 9(h) and Table shown in FIG. 28. These results highlight the exceptional chromatic performance of SMGO:x % Eu³⁺ phosphors, especially at 2 mol % doping. Their intense red emission, high CP, and favourable CCT values affirm their suitability for use in energy-efficient solid-state lighting and advanced display systems.

The JO theoretical framework offers valuable insights into the local symmetry and chemical environment surrounding Eu³⁺ ions within the SMGO host lattice. The JO intensity parameters (Ω₂, Ω₄ and Ω₆), derived from the emission spectra, are essential for understanding various radiative properties, including transition probabilities (A_{0-J}), β, asymmetry ratios, and τ_{rad}. These parameters collectively provide a deeper understanding of the structural distortion and ligand bonding characteristics around the Eu³⁺ sites.

Among the three JO intensity parameters, Ω₂ and Ω₄ are particularly informative. The parameter Ω₂ is associated with the hypersensitive ⁵D₀→⁷F₂ transition, making it highly responsive to the local asymmetry and covalent bonding between Eu³⁺ ions and surrounding ligands. In contrast, Ω₄ is correlated with the ⁵D₀→⁷F₄ transition and is indicative of the rigidity and structural stiffness of the host material. The third parameter, Ω₆, corresponds to the D₀→⁷F₆ transition, but since this transition is not observed in the emission spectra of the synthesized SMGO:x % Eu³⁺ phosphors, Ω₆ could not be determined in this study.

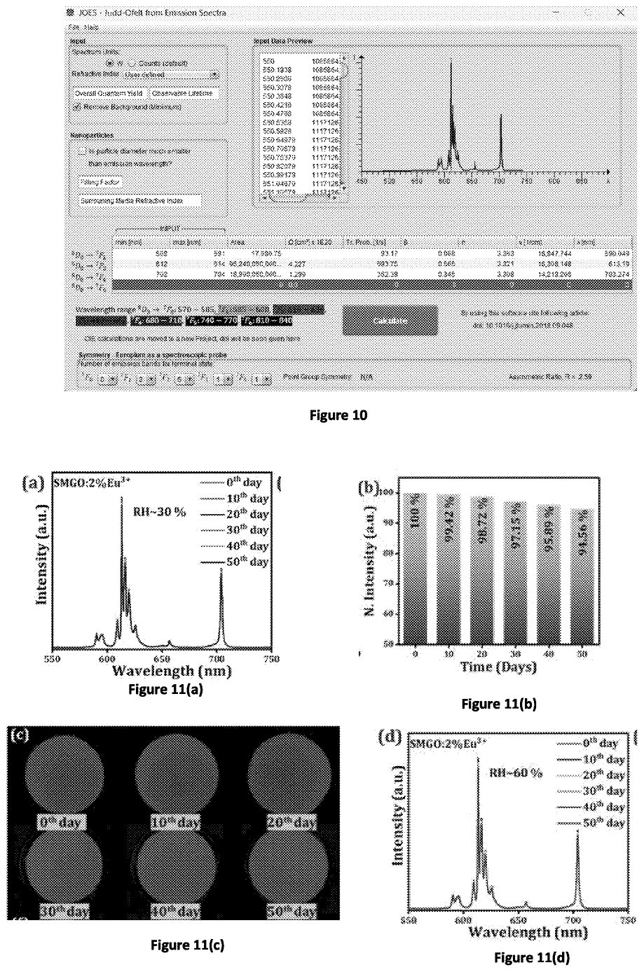

The Ω₂ and Ω₄ parameters were quantitatively estimated from the photoluminescence emission spectra using the JOES software. The UI of JOES is presented in FIG. 10. The magnetic dipole transition (⁵D₀→⁷F₁) serves as a reference for calculating the JO parameters, with its line strength (S_{MD}) given by:

$${S}_{MD} = 9.6 \times {10}^{- 42} {esu}^{2} ( 3.2022 \times {10}^{- 51} {C}^{2} ) \qquad ( 12 )$$

The JO parameters (Ω_{J}) can be calculated from emission data using the following relation:

$${Ω}_{J} = \frac{{S}_{MD} ( {v}_{1}^{3} )}{{e}^{2} ( {v}_{J}^{3} )} \frac{9 {n}^{3}}{{n ( {n}^{2} + 2 )}^{2}} \frac{\int {I}_{1} ( {v}_{1} )}{{\vert 〈 J \vert \vert {U}^{J} \vert \vert {J}^{′} 〉 \vert}^{2} \int {I}_{J} ( {v}_{J} )} \qquad ( 13 )$$

In this equation, v_{I} and v_{J} are the frequencies of the MD (⁵D₀→⁷F₁) and ED (⁵D₀→⁷F_{J}; J=2, 4) transitions, respectively, and I₁ and I_{J} denote their corresponding integrated intensities. e represents the elementary charge, and n is the refractive index of the SMGO host (2.4354 in this case).

The radiative transition probability (A_{0-J}) for a specific transition is determined by:

$${A}_{0 - J} = \frac{{I}_{0 - J}}{{I}_{0 - 1}} \frac{{hv}_{0 - 1}}{{hv}_{0 - J}} {A}_{0 - 1} \qquad ( 14 )$$

Here, A₀₋₁ is the magnetic dipole transition rate, typically assumed to be 50 s⁻¹ as it remains unaffected by crystal field variations.

The ED transition rates are calculated using:

$${A}_{0 - J} = \frac{64 {π}^{4} {e}^{2}}{3 h {λ}^{3}} \frac{1}{4 {πε}_{0}} χ {\sum }_{J = 2 , 4} {Ω}_{J} 〈 {5}_{{D}_{0}} \vert {U}^{( J )} \vert 〉 \qquad ( 15 )$$

Where the Lorentz field correction factor, χ, is defined as n(n²+2)/9, and the reduced matrix elements for Eu³⁺ transitions are constants: [symbol] D₀∥U²∥F₂ [symbol] ²=0.0032 and [symbol] ⁵D₀∥U⁴∥⁷F₄ [symbol] ²=0.0023.

The total radiative transition probability (A_{rad}) is obtained by summing the probabilities of all observed transitions:

$${A}_{rad} ( {ψ}_{J} ) = {\sum }_{J = 1 , 2 , 4} {A}_{0 - J} \qquad ( 16 )$$

The radiative lifetime of the excited state (τ_{rad}) is inversely related to the total transition probability:

$${τ}_{ra d} = \frac{1}{{A}_{r ad}} \qquad ( 17 )$$

The β for a particular transition is calculated using:

$$β ( {ψ}_{J} ) = \frac{A ( {ψ}_{J} , {ψ}_{{J}^{′}}^{′} )}{{A}_{r ad} ( {ψ}_{J} )} \qquad ( 18 )$$

The asymmetry ratio, representing the ratio of electric to magnetic dipole intensities, is determined by:

$$Asymmetric ratio = \frac{\int {I}_{e d} \cdot dλ}{\int {I}_{md} \cdot dλ} \qquad ( 19 )$$

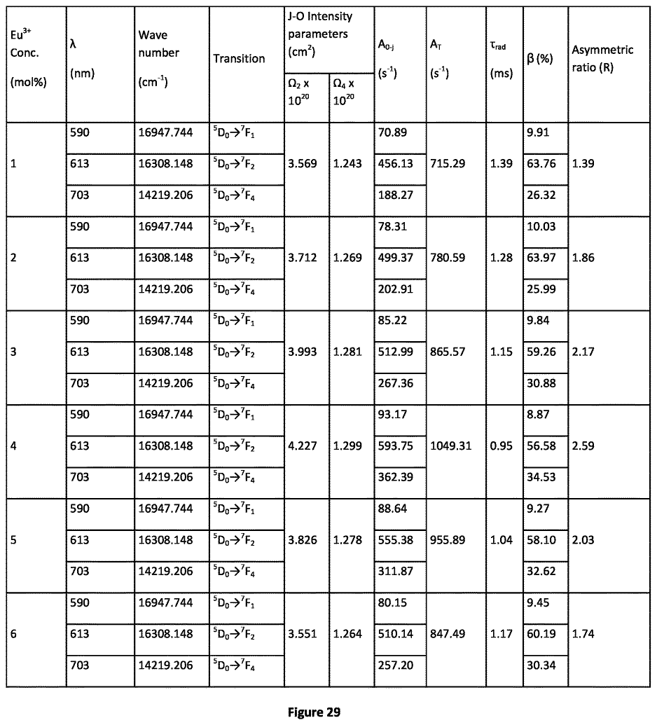

A higher Ω₂ value, along with an asymmetry ratio greater than 1, implies strong covalent bonding between Eu³⁺ and O²⁻ ligands and significant local distortion around the dopant ions. The results in Table shown in FIG. 29 show that Ω₂ values are consistently higher than Ω₄ across all doping concentrations, indicating a pronounced asymmetric environment and strong covalent interaction between Eu³⁺ ions and surrounding oxygen atoms. This also explains the high intensity of the ⁵D₀→⁷F₂ transition (613 nm) in the emission spectra, as this transition is particularly sensitive to local asymmetry and covalency.

Moreover, a higher branching ratio for the ⁵D₀→⁷F₂ transition compared to others signifies its dominant role in Eu³⁺ emission. These results are further corroborated by the calculated asymmetric ratios, which exceed unity, reinforcing the conclusion that Eu³⁺ ions occupy sites with significant asymmetry in the SMGO matrix. Overall, the JO analysis confirms that Eu³⁺ ions are situated in highly asymmetric and covalently bonded environments within the SMGO host. These findings correlate well with the photoluminescence properties and support the suitability of SMGO:x % Eu³⁺ phosphors for high-performance applications in solid-state lighting. A comprehensive summary of the JO parameters and radiative characteristics is provided in Table shown in FIG. 29.

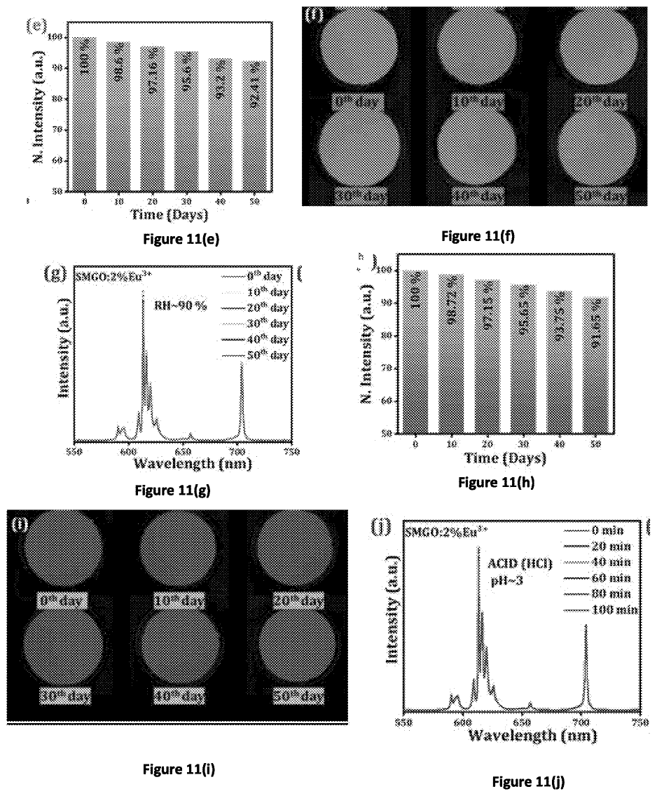

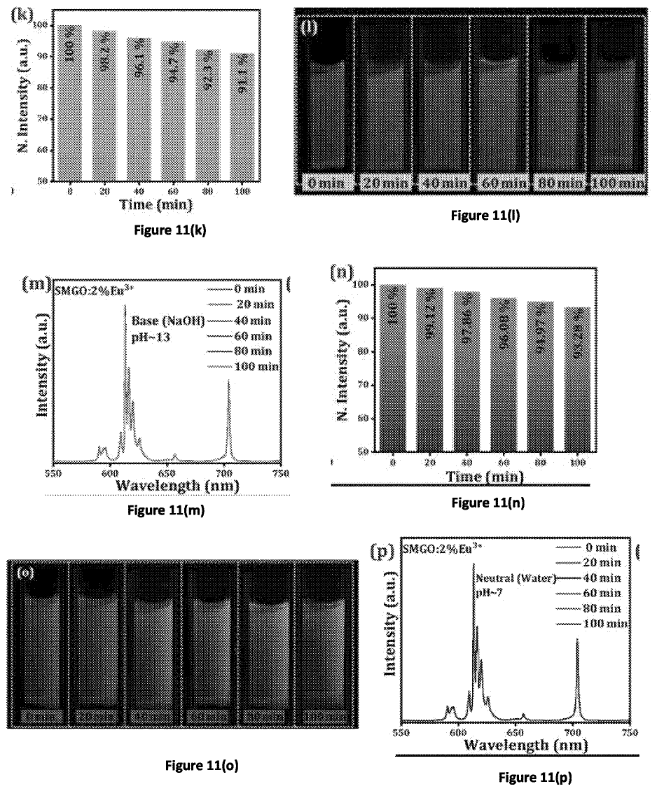

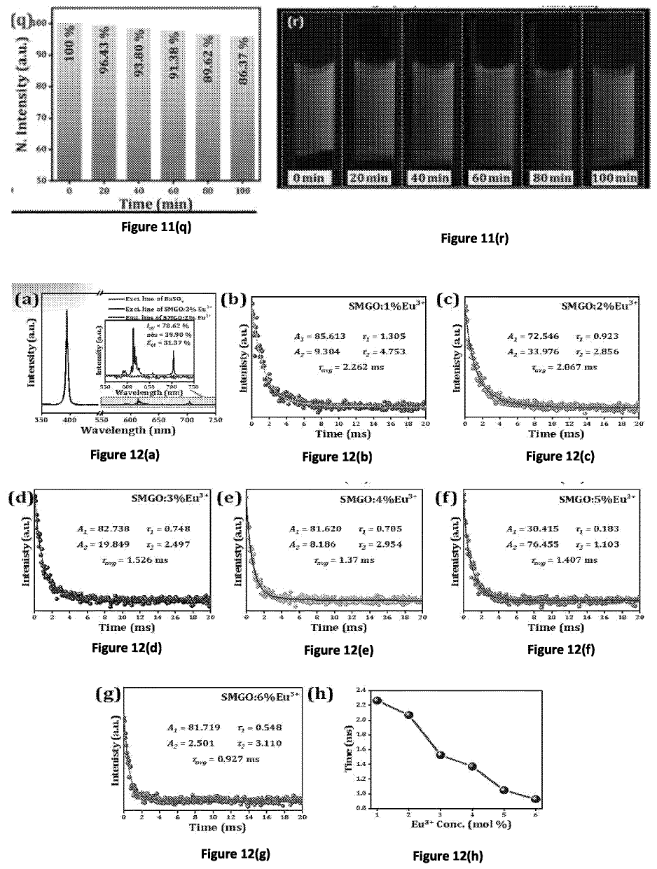

The photostability of SMGO:2% Eu³⁺ phosphors was investigated under varying relative humidity (RH) conditions of 30%, 60%, and 90% over a 50 day period. PL emission spectra were recorded at 10-day intervals (FIGS. 11(a), 11(d) & 11(g)), while the corresponding normalized PL intensity variations are illustrated in FIGS. 11(b), 11(e) & 11(h). Additionally, UV-excited digital images were captured at each time interval to assess macroscopic luminescence stability. The PL spectra (FIGS. 11(a), 11(d) & 11(g)) display no spectral shifts or additional defect-related emissions, confirming the phosphors' structural integrity. However, a gradual decrease in PL intensity is observed over time, with retention efficiencies of 94.56%, 92.41%, and 91.65% at RH~30%, 60%, and 90%, respectively, after 50 days (FIGS. 11(b), 11(e) & 11(h)). This decline is attributed to surface hydration effects rather than intrinsic lattice degradation, as no significant spectral distortions are detected. Photographs under UV excitation (FIGS. 11(c), 11(f) & 11(i)) visually confirm that the emission intensity remains relatively stable, even under high humidity conditions (RH~90%). The phosphor's excellent moisture resistance underscores its viability for applications requiring long-term stability in humid environments, such as white LEDs, anti-counterfeiting, and security marking.

To evaluate chemical durability, the phosphors were immersed in acidic (HCl, pH~3), neutral basic (NaOH, pH~13) and (H₂O, pH~7) solutions for up to 100 min. PL emission spectra were recorded at 0, 20, 40, 60, 80 and 100 min (FIGS. 11(j), 11(m) & 11(p)), with the corresponding normalized PL intensity retention shown in FIGS. 11(k), 11(n) & 11(q)). Macroscopic luminescence stability was further assessed through UV-excited photographs captured at each time interval. The PL spectra (FIGS. 11(j), 11(m) & 11(p)) exhibit a gradual reduction in intensity over time but no peak shifts or additional defect-related emissions, indicating that the Eu³⁺ luminescence centers remain intact. The retention efficiencies at 100 min are measured as 91.1% (pH~13), 93.28% (pH~3), and 86.37% (pH~7) (FIGS. 11(k), 11(n) & 11(q)). The higher degradation rate in neutral water suggests surface hydrolysis or minor dissolution, consistent with previously observed behaviors in oxide-based phosphors. The UV-excited digital images (FIGS. 11(l), 11(o) & 11(r)) further corroborate these trends, revealing slightly more pronounced fading in neutral water compared to acidic and basic conditions. The relatively better retention in acidic and basic solutions suggests that surface hydroxylation rather than bulk dissolution governs the luminescence attenuation. The combined results establish that SMGO:2% Eu³⁺ demonstrates excellent environmental and chemical stability, with >90% luminescence retention even under high humidity (RH~90%) and extreme pH conditions (pH~3 and pH~13). The absence of spectral distortions or defect-related emissions reinforces its structural robustness and resistance to hydrolysis, making it a promising candidate for long-term optoelectronic applications in solid-state lighting, AC, and security printing.

I_{QE} and external quantum efficiency (E_{QE}) of SMGO:2% Eu³⁺ phosphors were evaluated using an Edinburgh FLS980 fluorescence spectrometer integrated with an integrating sphere setup. These parameters are crucial for assessing the capability of phosphor materials to convert incident photons into luminescent output. The absorption efficiency (ε), I_{QE}, and E_{QE} were calculated using the following expressions:

$$ε = \frac{\int {E}_{R} - \int {E}_{s}}{\int {E}_{R}} \% \qquad ( 20 )$$

$${I}_{Q E} = \frac{\int {L}_{s}}{\int {E}_{R} - \int {E}_{s}} \% \qquad ( 21 )$$

$${E}_{Q E} = {I}_{Q E} \times ε \% \qquad ( 22 )$$

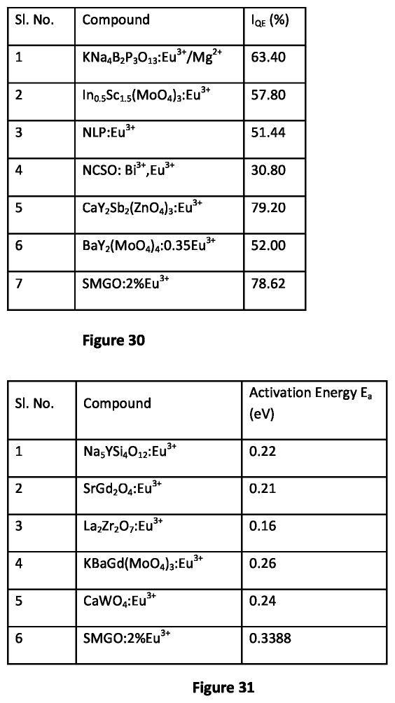

In these equations, E_{R} denotes the intensity of the excitation light without the sample, E_{S} represents the excitation intensity with the sample, and L_{S} corresponds to the integrated photoluminescence emission from the sample. Based on these calculations, the SMGO:2% Eu³⁺ phosphor demonstrates an e of 39.9%, an I_{QE} of 78.62%, and an E_{QE} of 33.37% (FIG. 12(a)). These values indicate that the phosphor exhibits excellent photon conversion efficiency and minimal non-radiative energy loss within the SMGO host matrix. A comparative analysis, as presented in Table shown in FIG. 30, highlights the superior I_{QE} of SMGO:2% Eu³⁺ phosphors compared to other host materials, reinforcing their potential for application in high-performance w-LEDs. The elevated quantum efficiency is largely attributed to the optimized doping level of 2 mol % Eu³⁺, which facilitates efficient energy transfer while mitigating the detrimental effects of concentration quenching. The phosphor's performance under UV excitation further confirms its suitability for advanced optoelectronic applications.

FIGS. 12(b)-12(g) illustrate the fluorescence decay curves of SMGO:x % Eu³⁺ phosphors for varying dopant concentrations (x=1-6 mol %). The decay profiles follow a bi-exponential model, suggesting that emission arises from a single luminescent center with two distinct decay processes. The decay behavior was modelled using the following double-exponential function:

$$I = {A}_{1} exp ( - t / {τ}_{1} ) + {A}_{2} exp ( - t / {τ}_{2} ) \qquad ( 23 )$$

Here, I(t) denotes the emission intensity at time t, while A₁ and A₂ are pre-exponential constants representing the amplitudes of the two components. τ₁ and τ₂ correspond to the fast and slow decay lifetimes, respectively.

To determine the average fluorescence lifetime (τ_{avg}), the following expression was employed:

$$< τ > = \frac{{A}_{1} {τ}_{1}^{2} + {A}_{2} {τ}_{2}^{2}}{{A}_{1} {τ}_{1} + {A}_{2} {τ}_{2}} \qquad ( 24 )$$

The variation in average lifetime across different Eu³⁺ concentrations is presented in FIG. 12(h). The results reveal a clear trend as the Eu³⁺ concentration increases, the average decay time decreases. This shortening of lifetime suggests enhanced energy migration among closely spaced Eu³⁺ ions, which facilitates non-radiative energy transfer processes. As Eu³⁺ ions become more proximate, energy transfer to quenching centers becomes more probable, leading to faster decay dynamics a characteristic signature of concentration quenching. This extension in lifetime is indicative of reduced non-radiative loss channels at optimal doping levels, while also implying the efficient occupation of Eu³⁺ ions at energetically favourable lattice sites. These findings not only validate the structural and compositional robustness of the SMGO matrix but also affirm the high luminescence retention and potential applicability of the phosphors in lighting technologies.

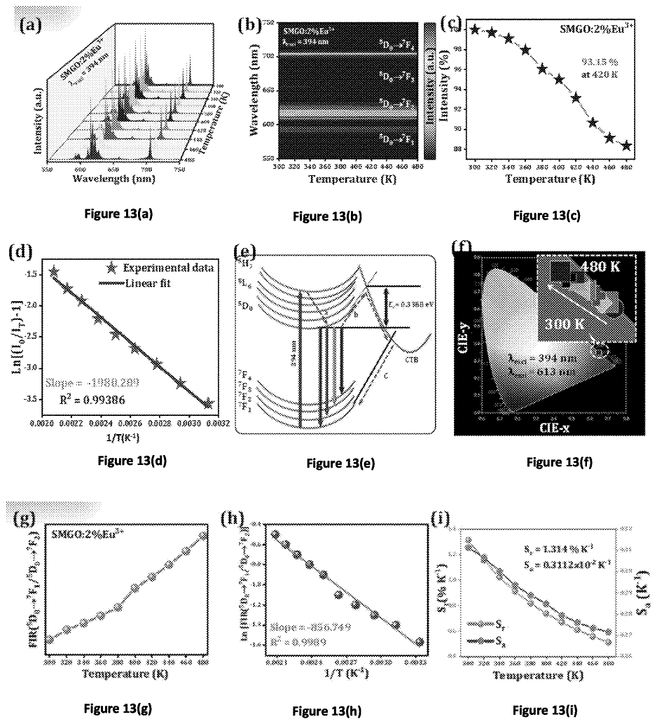

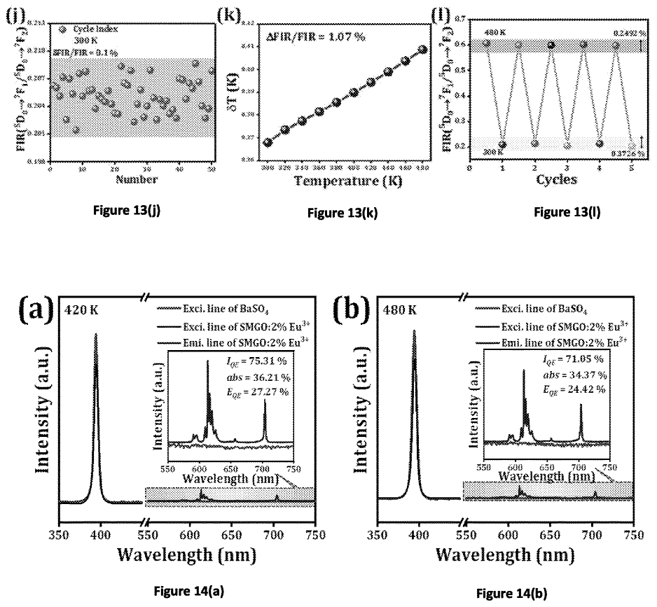

Thermal stability is a critical performance metric for phosphors intended for high-power applications, particularly in w-LEDs, where elevated junction temperatures are common during prolonged operation. To evaluate the robustness of SMGO:2% Eu³⁺ phosphors under thermal stress, temperature-dependent photoluminescence (TDPL) spectra were recorded in the 300-480 K range under 394 nm excitation. As illustrated in FIG. 13(a), the emission spectra consistently exhibit sharp transitions corresponding to the ⁵D₀→⁷F_{J} (J=0, 1, 2, 3, 4) transitions of Eu³⁺, with the most intense red emission centered at ~613 nm (⁵D₀→⁷F₂ electric dipole transition). Importantly, despite the increase in thermal energy, no significant shift or distortion in the spectral shape is observed, confirming that the local symmetry and coordination environment around Eu³⁺ ions remains stable. This behavior is consistent with other thermally robust systems such as LaGeSbO₆:Eu³⁺ and BaSrGa₄O₈:Eu³⁺, where the spectral profiles remain unchanged with increasing temperature, indicating a structurally resilient host framework.

The 2D contour plot of temperature-dependent PL spectra (FIG. 13(b)) further affirms the thermal integrity of the emission profile, while also reflecting the gradual decrease in intensity with rising temperature. A progressive decline in luminescence intensity is observed (FIG. 13(c)), primarily due to thermally activated non-radiative relaxation pathways that compete with radiative transitions. At 420 K a typical operating temperature for commercial LEDs SMGO:Eu³⁺ phosphors retain approximately 93.15% of their room-temperature emission intensity, demonstrating excellent thermal resistance. In contrast, commercial red phosphors such as SrBi₂B₂O₇:Eu³⁺ and Gd₂MoO₆:Eu³⁺ exhibit a much more rapid decline in emission beyond 400 K. Interestingly, as reported in hosts like Cd₂CaTeO₆:Eu³⁺ and YNb₂VO₉:Eu³⁺, some Eu³⁺ activated systems display anomalous thermal behavior, where emission intensity initially increases with temperature before undergoing quenching at higher levels. However, such abnormal enhancement is not observed in SMGO:Eu³⁺, indicating conventional thermal quenching governed by multiphonon relaxation processes.

In addition to TDPL, the temperature-dependent quantum efficiency was assessed to gain deeper insight into the optical performance under thermal load. As shown in Supplementary FIGS. 14(a) & 14(b), the I_{QE}, E_{QE} and ε were evaluated at both 300 K and 420 K. At room temperature, SMGO:Eu³⁺ exhibits an I_{QE} of 71.05%, E_{QE} of 24.42%, and ε of 34.37%. Remarkably, at 420 K, these values remain high I_{QE}=75.31%, E_{QE}=27.27%, and ε=36.21% indicating minimal deterioration of optical performance at elevated temperatures. This further substantiates the excellent thermal and optical reliability of SMGO:Eu³⁺ phosphors, making them promising candidates for high-power optoelectronic applications.

The thermal quenching mechanism is further evaluated using the Arrhenius equation:

$$I ( T ) = \frac{{I}_{0}}{1 + c exp ( \frac{- {E}_{a}}{k T} )} \qquad ( 25 )$$

where I(T) is the emission intensity at temperature T, I₀ is the initial intensity, C is a constant, Eₐ is the activation energy for quenching, and k is Boltzmann's constant. The linearized form of this equation is:

$$ln ( \frac{{I}_{0}}{I} - 1 ) = \frac{- {E}_{a}}{k T} + l n c \qquad ( 26 )$$

From the slope of the Arrhenius plot (FIG. 13(d)), the Eₐ was determined to be approximately 0.3388 eV, which is higher than that of previously reported phosphors (Table shown in FIG. 31). This value represents the energy threshold required for thermally induced non-radiative deactivation processes. The relatively high Eₐ indicates a strong confinement of Eu³⁺ ions within the SMGO host, effectively suppressing non-radiative losses even at elevated temperatures. This behavior is likely attributed to the rigid and well-ordered lattice structure of the SMGO matrix, which restricts carrier migration and minimizes energy dissipation. Consequently, the phosphor maintains its luminescence performance, making it a promising candidate for high-power LED applications where thermal stability is essential.

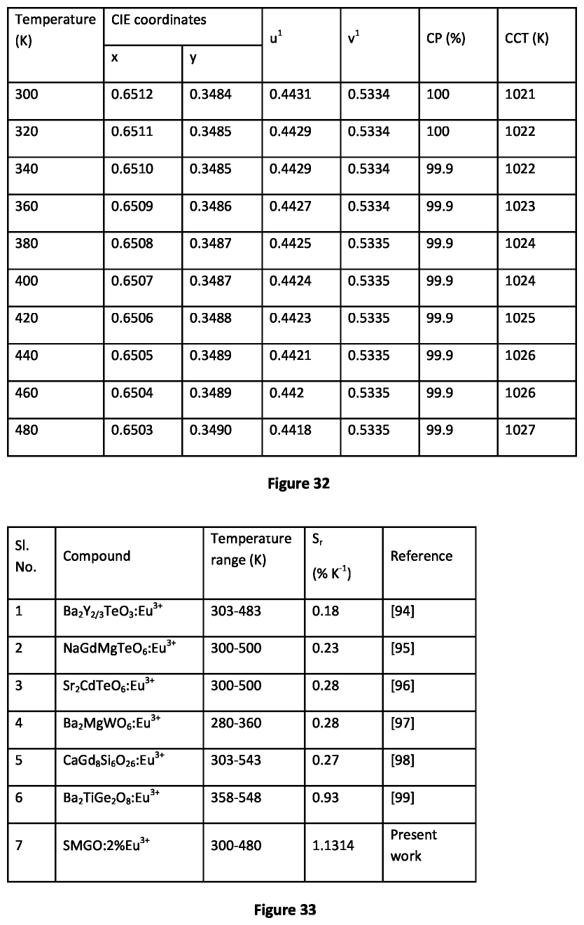

FIG. 13(e) illustrates the energy level diagram representing the luminescence mechanism of Eu³⁺ ions in SMGO phosphors. Upon 394 nm excitation, electrons transition from the ground state to the ⁵L₆ energy level, followed by rapid non-radiative relaxation to the ⁵D₀ state. Radiative transitions from this state to various ⁷F_{J} levels result in visible emissions. Competing thermal processes and non-radiative pathways are also shown, corresponding to the activation energy identified earlier. The temperature-induced variation in emission color is plotted on the CIE chromaticity diagram in FIG. 13(f), which reveals a slight shift in chromaticity coordinates with increasing temperature. Despite the thermal quenching, the color output remains consistent, indicating minimal degradation in chromatic performance. Such color stability is particularly important for applications requiring consistent visual output under thermal stress, such as high-intensity LEDs and laser-based lighting systems. The color parameters of SMGO:2% Eu³⁺ phosphors at different temperatures (300-480 K) were analyzed to evaluate their thermal stability. Table shown in FIG. 32 presents the CIE chromaticity coordinates, the CP, and the CCT. The CIE coordinates exhibit minimal shifts with increasing temperature, indicating excellent chromatic stability. The CP remains nearly constant at 99.9-100%, and the CCT values range from 1021 K to 1027 K, demonstrating the suitability of SMGO:2% Eu³⁺ phosphors for stable white light emission in high-temperature applications.

The ratio of the integral emission intensities at 590 nm (⁵D₀→⁷F₁) and 613 nm (⁵D₀→⁷F₂) was used to construct a FIR curve, which serves as a method for evaluating the phosphors temperature-sensing capability. The FIR curve was modelled using the following equation:

$$FIR = \frac{{I}_{1}}{{I}_{2}} = A + C exp ( - \frac{Δ E}{k T} ) \qquad ( 27 )$$

where I₁ and I₂ are the intensities of the 590 nm and 613 nm bands, respectively, and A is fitting constant and ΔE is the energy difference between ⁵D₀→⁷F₁ and ⁵D₀→⁷F₂. A plot of FIR versus T and a plot of ln(FIR) versus 1/T (FIGS. 13(g) & 13(h)) demonstrates a linear relationship, validating the thermometric potential of the SMGO:2% Eu³⁺ phosphors.

The absolute (Sₐ) and relative (Sᵣ) sensitivities of the phosphors were calculated using:

$${S}_{a} = \frac{d ( FIR )}{d T} = \frac{Δ E}{K {T}^{2}} \times FIR \qquad ( 28 )$$

$${S}_{r} = \frac{{S}_{a}}{FIR} = \frac{1}{FIR} \times \frac{d ( FIR )}{d T} = \frac{Δ E}{K {T}^{2}} \times FIR \qquad ( 29 )$$

The maximum values of Sₐ and Sᵣ at 300 K were 0.003112 K⁻¹ and 1.314% K⁻¹, respectively. As the temperature increased to 480 K, the Sᵣ gradually decreased to 0.5136% K⁻¹, which remains superior to the previously reported phosphors listed in Table shown in FIG. 33 (FIG. 13(i)). These results highlight the strong temperature responsiveness of SMGO:2% Eu³⁺, underscoring its potential as a reliable optical thermometer. To ensure statistical robustness and reproducibility, fifty independent measurements of the FIR response at 300 K were conducted. The results exhibited consistent trends across trials, enabling a comprehensive analysis of the underlying phenomena (FIG. 13(j))

The temperature resolution (δT) a measure of the minimum temperature difference that can be accurately detected—was calculated using:

$$δ T = \frac{Δ FIR}{FIR} \times \frac{{k}_{B} T}{Δ E} = \frac{Δ FIR}{{S}_{r}} \qquad ( 30 )$$

A lower δT corresponds to higher precision. In this case, the minimum resolution achieved was 1.07%, indicating high measurement accuracy (FIG. 13(k)). Additionally, thermal cycling tests over five consecutive heating and cooling cycles (300-480 K) were conducted to examine the material's repeatability. The SMGO phosphors showed minimal intensity variation only 0.3726% at 300 K and 0.2492% at 480 K confirming excellent thermal stability and reproducibility (FIG. 13(l)). These findings underscore the robustness of SMGO:2% Eu³⁺ phosphors, not only for high-temperature lighting applications but also for non-contact optical thermometry. The combination of strong thermal endurance, minimal color shift, and reliable repeatability positions these phosphors as promising candidates for multifunctional optoelectronic devices.

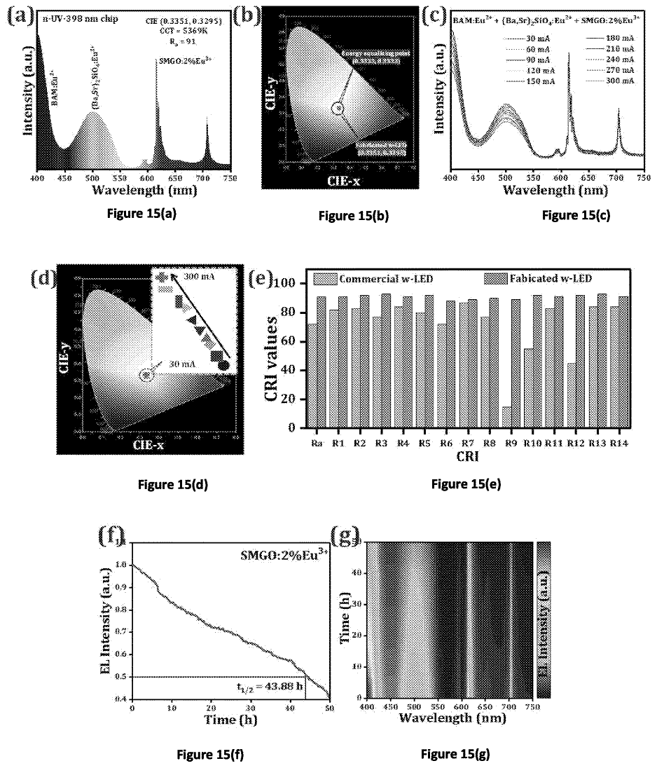

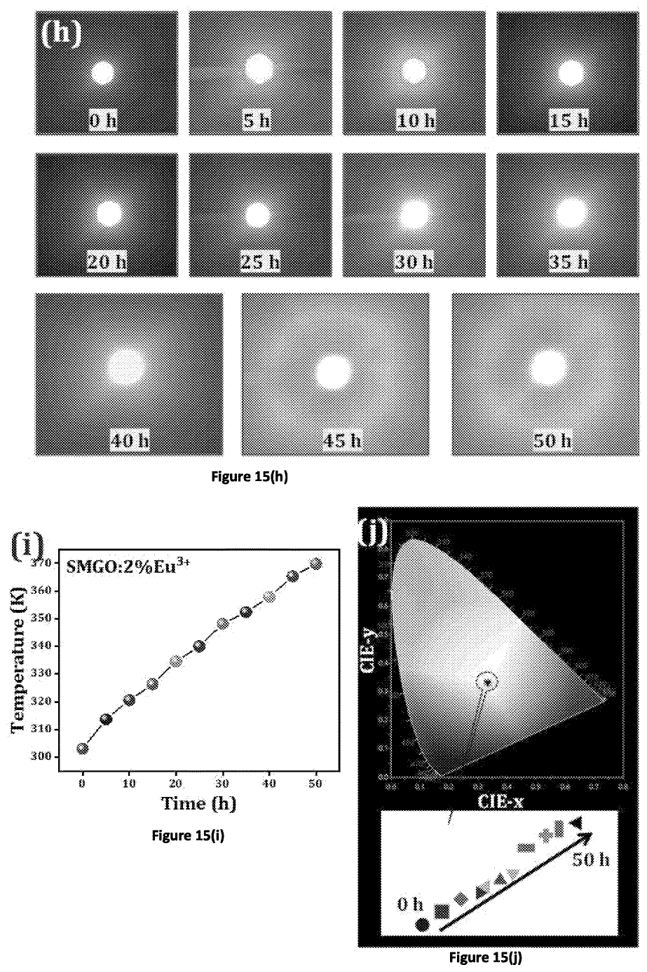

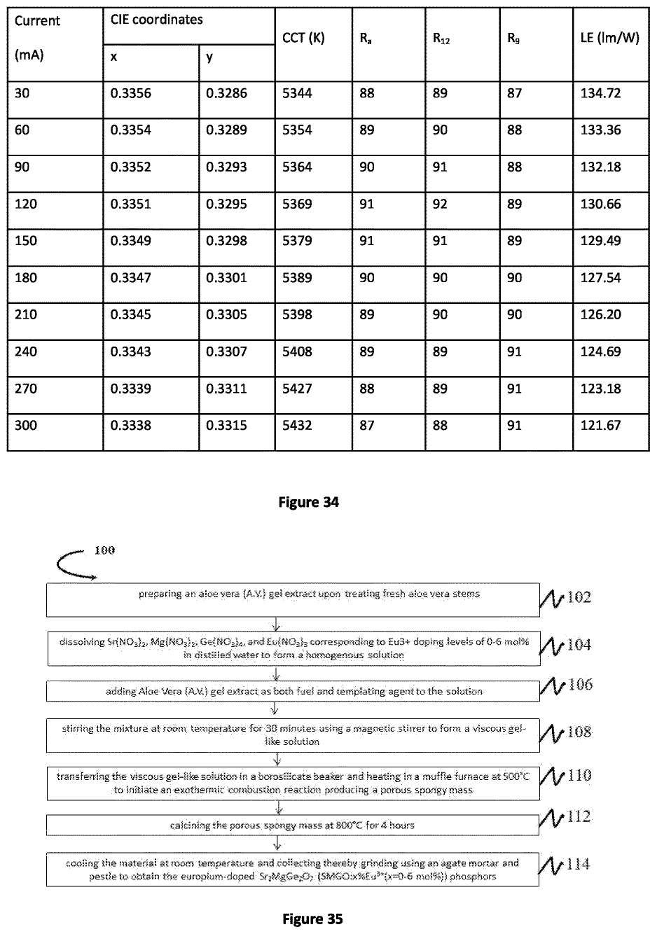

The comprehensive analysis of SMGO:x % Eu³⁺ phosphors highlights their remarkable luminescence characteristics and strong thermal quenching resistance, positioning them as ideal candidates for real-world w-LED applications. To validate their practical potential, SMGO:2% Eu³⁺ was selected as the red-emitting component in the fabrication of w-LED devices. The w-LEDs were engineered by combining three phosphor components: blue-emitting BaMgAl₁₀O₁₇:Eu²⁺ (BAM:Eu²⁺), green-emitting (Ba,Sr)₂SiO₄:Eu²⁺, and the synthesized red-emitting SMGO:2% Eu³⁺. These were excited using a 398 nm n-UV LED chip. This trichromatic combination is designed to yield a balanced white-light output, offering enhanced color rendering and improved thermal reliability. FIG. 15(a) displays the EL spectrum of the fabricated w-LED under a 120 mA forward bias. The spectrum clearly illustrates the contributions from all three phosphors, confirming the effective integration of SMGO:2% Eu³⁺ in the w-LED configuration. The corresponding CIE chromaticity coordinates and energy equalizing point are shown in FIG. 15(b), revealing that the emission color falls within the desirable white-light region. To assess the performance under different operating conditions, Electroluminescence (EL) spectra were recorded at drive currents ranging from 30 to 300 mA (FIG. 15(c)). The associated chromaticity coordinates are plotted in FIG. 15(d), where the emission color consistently remains close to the energy equalizing point, indicating stable white-light output across a wide current range. Key photometric parameters were evaluated to assess device performance. With increasing current, the CCT rises modestly from 5344 K at 30 mA to 5432 K at 300 mA, indicating a shift toward cooler white light. Meanwhile, the CRI exhibits a substantial enhancement from 90.1 at 30 mA to a peak value of 93.7 at 120 mA exceeding that of many commercially available w-LEDs. Such a high CRI demonstrates the effectiveness of the SMGO:2% Eu³⁺ phosphor in enriching the emission spectrum and delivering accurate color perception, which is crucial for high-fidelity lighting applications. However, the luminous efficacy (LE) declines with increasing current, decreasing from 134.72 lm/W at 30 mA to 121.67 lm/W at 300 mA. This drop in efficacy is likely due to enhanced thermal losses, reduced light extraction efficiency, and reabsorption effects associated with higher drive currents particularly from the addition of the red-emitting phosphor. A complete summary of the CIE chromaticity coordinates, CCT, and CRI values across the operating current range is provided in Table shown in FIG. 34. As illustrated in FIG. 15(e), the fabricated w-LEDs outperform typical commercial counterparts in terms of CRI, emphasizing the superior color rendering capabilities of the SMGO:2% Eu³⁺ phosphor. The stability of the chromaticity coordinates and consistent color quality under varying electrical inputs further affirm the reliability of this phosphor for practical applications. Overall, the successful implementation of SMGO:2% Eu³⁺ in w-LED fabrication, coupled with its high thermal endurance and outstanding CRI, underscores its potential as an efficient red-emitting component for next-generation solid-state lighting. With continued refinement of the phosphor composition and device architecture, further improvements in luminous efficacy and operational lifetime are anticipated, paving the way for its integration into high-performance lighting technologies.

To assess the operational reliability of the packaged w-LED, EL stability was examined under continuous operation. The device was driven at a constant current of 120 mA, and the variation in luminous intensity over time was recorded and presented as a relative intensity decay profile (FIG. 15(f)). A gradual decline in EL intensity was observed, consistent with the expected operational behavior of w-LEDs. Notably, the device encapsulated with SMGO:2% Eu³⁺ phosphor exhibited a luminescence half-life of 43.88 h, demonstrating its long-term stability under high-current conditions. The variation in EL intensity during sustained 120 mA operation is further illustrated in the counterplot (FIG. 15(g)). To investigate thermal effects, real-time imaging and temperature mapping were conducted using a camera (FIG. 15(h)). As the operation time increased, the device surface temperature progressively rose due to continuous heat generation. After 43.88 h, the temperature stabilized at approximately 370 K, while the luminescence remained relatively stable, highlighting the exceptional thermal quenching resistance of the SMGO:2% Eu³⁺ phosphor. The detailed temperature evolution of the w-LED over prolonged operation is presented in FIG. 15(i). Even after 50 h of continuous operation, the device had not reached its maximum operating temperature, underscoring its high efficiency and thermal stability. Furthermore, the CIE chromaticity diagram (FIG. 15(j)) confirms that the chromaticity coordinates remained nearly unchanged throughout the stability test, verifying the excellent color stability of the fabricated w-LED. These findings demonstrate the strong potential of SMGO:2% Eu³⁺ phosphors for next-generation w-LED applications.

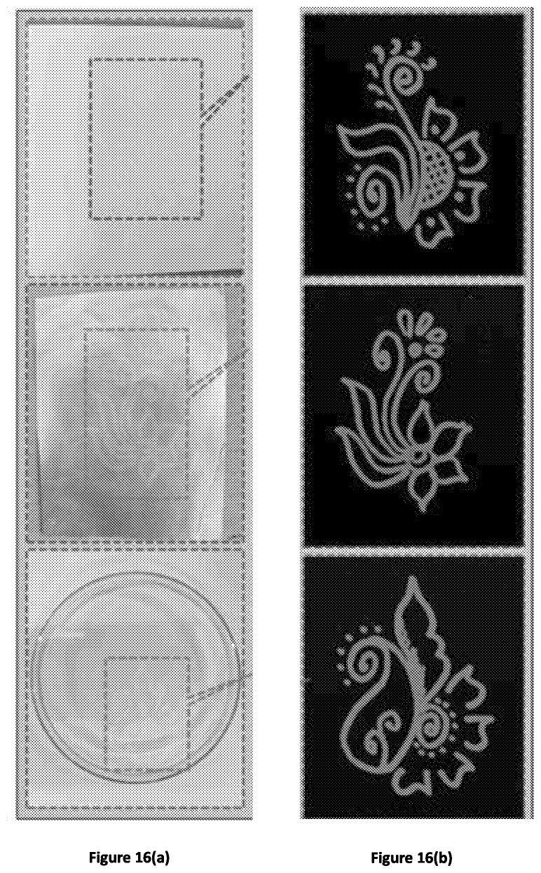

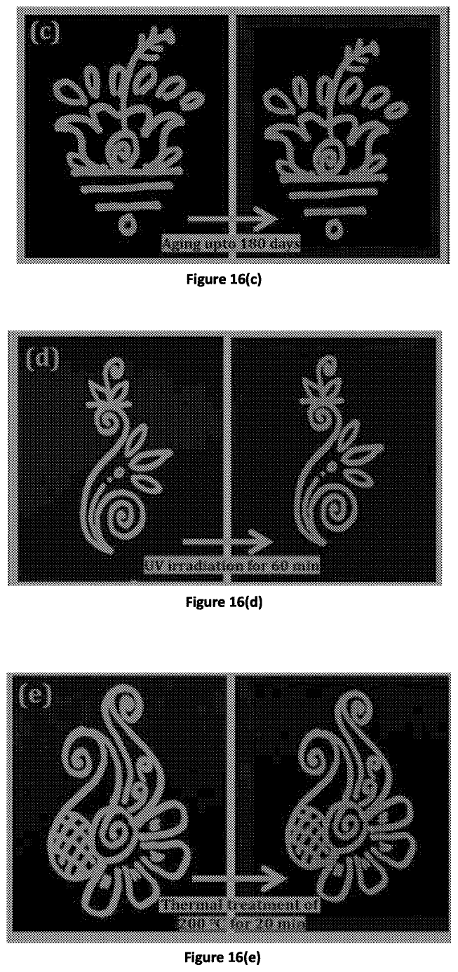

To investigate the applicability of SMGO:2% Eu³⁺ phosphors in AC technologies, a functional security ink was formulated by dispersing the phosphor powder in a PVA solution. The resultant luminescent ink was loaded into the ink reservoir of a standard sketch pen to facilitate precise and convenient application. Using this modified writing tool, various encrypted patterns were inscribed onto diverse substrates, including paper, aluminium foil, and glass, as depicted in FIG. 16(a). The visibility of these encoded markings was assessed under normal lighting conditions and under 365 nm UV illumination. As illustrated in FIG. 16(b), the patterns remained nearly invisible under daylight, with only faint traces observable due to residual PVA staining. However, when exposed to UV light at 365 nm, the encoded patterns exhibited a vivid red luminescence, originating from the SMGO:2% Eu³⁺ phosphor. This distinct optical behavior allows for concealed information to remain hidden under regular lighting but be readily revealed under UV exposure a critical feature for secure authentication and anticounterfeiting applications.

To assess the robustness and environmental resilience of the ink, a series of durability tests were conducted, with the outcomes presented in FIG. 16(c)-16(e). FIG. 16(c) demonstrates the results of an aging test, in which the encrypted markings were stored under ambient conditions for up to 180 days. Remarkably, the encoded patterns retained strong luminescent visibility with no significant degradation, highlighting the ink's exceptional stability over extended time periods. Photostability was examined by subjecting the patterns to continuous UV exposure for 60 min at 365 nm (FIG. 16(d)). Post-irradiation, the luminescent patterns remained clearly distinguishable, exhibiting only a minor reduction in brightness. This indicates strong resistance to photodegradation, an essential attribute for real-world security applications. Thermal resilience was further evaluated by exposing the samples to a high-temperature treatment of 200° C. for 20 min, as shown in FIG. 16(e). Although a slight reduction in luminescence intensity was observed, the encoded patterns remained visible and detectable. These results suggest that the ink retains satisfactory performance under moderate thermal conditions, though extreme heat may partially compromise its optical output. Taken together, these findings underscore the durability and effectiveness of SMGO:2% Eu³⁺ phosphor-based security ink. Its ability to generate covert markings that remain inconspicuous under daylight but become vividly luminescent under UV illumination makes it highly suited for advanced anticounterfeiting measures. The ink's long-term environmental stability, strong resistance to UV-induced degradation, and moderate thermal tolerance enhance its reliability for practical use in secure labeling, document protection, and tamper-evident packaging. With further refinement and integration into specialized printing technologies, this luminescent ink holds significant promise for next-generation security systems across high-risk and sensitive sectors.

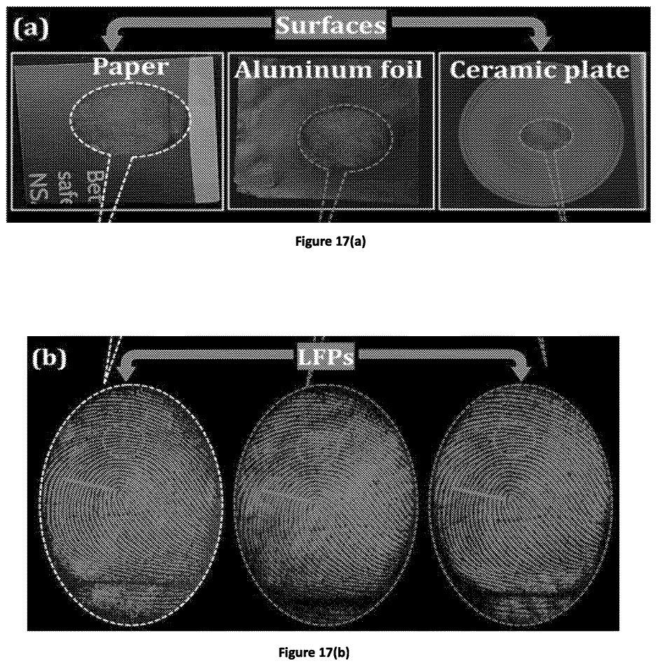

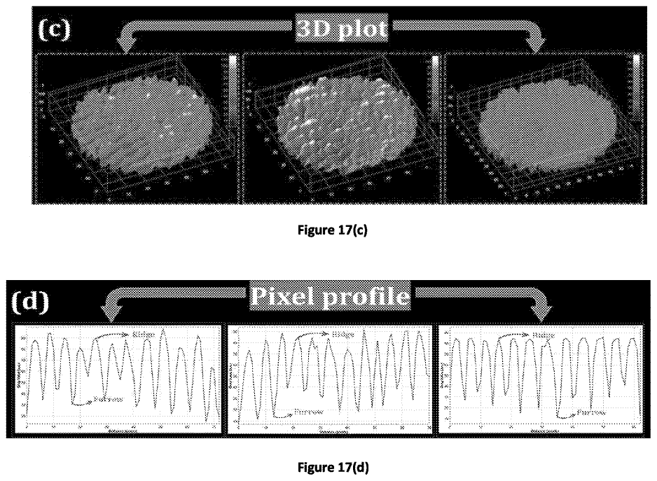

To explore the forensic applicability of SMGO:2% Eu³⁺ phosphor, its effectiveness in developing LFPs was assessed using the powder-dusting technique. This method remains one of the most widely adopted and practical approaches for visualizing LFPs on non-porous surfaces due to its simplicity, rapid execution, and cost-effectiveness. While chemical-based detection techniques such as ninhydrin staining or cyanoacrylate fuming are employed for porous materials, they typically require more complex procedures and longer processing times. As such, powder-based detection continues to be preferred in forensic investigations, particularly for quick and reliable FP development. Traditional FP powders often consist of black, white, or metallic particles that adhere to the oily and sweaty residues deposited on the FP ridges. However, these conventional powders often lack adequate contrast-especially on multi-colored or patterned surfaces-limiting their efficacy. In contrast, luminescent phosphor-based powders offer improved visibility under UV light, enhancing the clarity of ridge patterns while reducing background interference. This approach not only improves visualization in low-light settings but also allows for more accurate identification of fine FP features. In this study, SMGO:2% Eu³⁺ phosphor exhibiting strong red luminescence under 365 nm UV light was employed to detect LFPs. FPs were collected from a female donor to maintain consistency in ridge features and were deposited onto three different substrates: paper, aluminium foil, and glass. The FPs were subsequently developed using a dusting technique with the phosphor powder, followed by illumination under UV light for visualization. As shown in FIGS. 17(a) & 17(b), the SMGO:2% Eu³⁺ powder adhered selectively to the FP ridges while leaving the grooves uncoated, resulting in sharp and well-defined ridge patterns across all tested surfaces. This selective adhesion enhances visibility and enables effective FP identification. To perform a quantitative analysis, three-dimensional (3D) surface maps and pixel intensity profiles were generated using ImageJ software for the regions marked in yellow circles (FIG. 17(c)). These 3D plots provide spatial information on ridge topography, offering a deeper understanding of FP morphology. The corresponding pixel intensity profiles (FIG. 17(d)) clearly illustrate the contrast between ridges and grooves, confirming the precise and consistent binding behavior of the phosphor to the ridge areas. The SMGO:2% Eu³⁺ phosphor demonstrated excellent luminescent performance and ridge contrast on all tested surfaces, confirming its adaptability for LFP visualization in forensic scenarios. Moreover, FP analysis is based on three hierarchical levels of detail: Level 1 (overall ridge flow), Level 2 (ridge minutiae), and Level 3 (microstructures such as sweat pores and ridge contours). The phosphor-based FP imaging technique employed in this study successfully captured all three levels of FP detail.

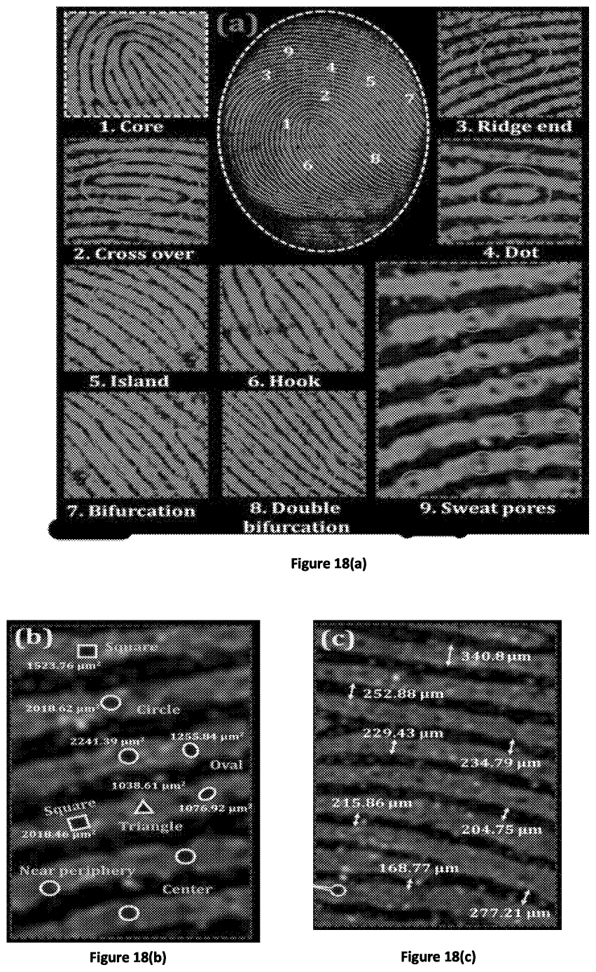

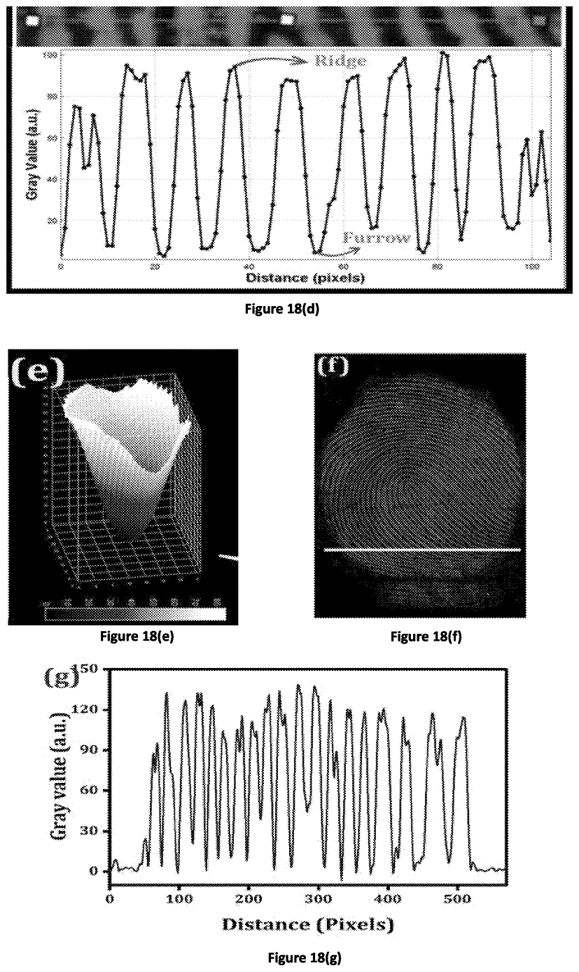

FIG. 18(a) shows Level 1 features, including core, loop, and ridge patterns, which are critical for initial FP classification and narrowing down potential suspects. Level 2 details, which comprise minutiae such as bifurcations, ridge endings, islands, hooks, and crossovers, are also clearly distinguishable, as shown in FIG. 18(a), allowing for individual FP identification based on unique features. The technique also demonstrated the capability to capture Level 3 features microscopic details that provide enhanced discrimination in forensic analysis. FIG. 18(b) illustrates the shape (triangular, square, oval, or circular), location (central or peripheral), and area of sweat pores. The measurement of ridge and furrow widths at various FP regions (FIG. 18(c)) adds further granularity to the analysis. The pixel intensity distribution across yellow-highlighted regions (FIG. 18(d)) reconfirms the strong adhesion of the phosphor to ridge areas, leaving furrows with minimal residue. A detailed 3D rendering of a sweat pore (FIG. 18(e)) further demonstrates the high-resolution capability of the phosphor-based visualization method.

To assess the contrast quality between ridges and furrows, grayscale pixel intensity analysis was conducted, with profiles illustrated in FIGS. 18(f) & 18(g). The sharp distinction between high-intensity ridges and low-intensity furrows highlights the phosphor's efficiency in differentiating FP structures. Contrast was quantitatively evaluated using the Michelson contrast equation:

$${C}_{m} = \frac{{I}_{m ax} - {I}_{m i n}}{{I}_{m ax} + {I}_{m i n}} \qquad ( 31 )$$

Here, Iₘₐₓ and Iₘᵢₙ represent the peak intensity of FP ridges and the minimum intensity in furrows, respectively. With values of Iₘₐₓ 172.24 and Iₘᵢₙ=8.47, the resulting contrast value is:

$${C}_{m} = \frac{172.24 - 8.74}{172.24 + 8.74} = 0.906 \qquad ( 32 )$$

A contrast value close to 1 indicates highly efficient ridge-to-furrow differentiation, affirming the suitability of SMGO:2% Eu³⁺ phosphor for high-contrast FP visualization, even on challenging substrates. Overall, the experimental results establish that SMGO:2% Eu³⁺ phosphor offers a robust, sensitive, and non-destructive technique for LFP detection. It successfully highlights all three levels of FP minutiae with excellent clarity and contrast, enabling high-resolution forensic analysis. The bright luminescence under UV illumination, combined with strong adhesion to FP residues and resistance to background noise, makes this phosphor an ideal material for real-world forensic investigations. The findings confirm that phosphor-based powder-dusting using SMGO:2% Eu³⁺ is a promising approach for precise and reliable FP identification in modern forensic science.

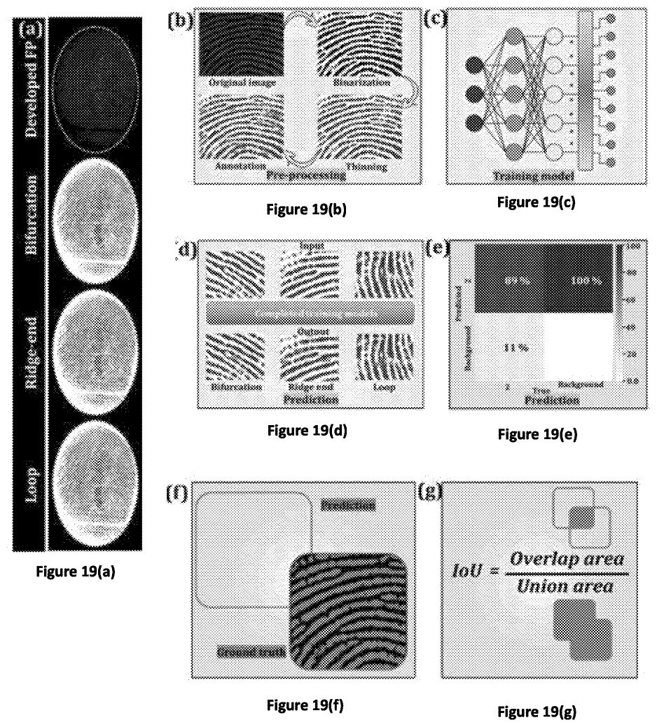

The extended variant of the YOLOv8 model (YOLOv8x) has gained prominence as a robust solution for real-time object detection, offering superior accuracy, fast inference speeds exceeding 60 frames per second, and reduced computational demands relative to conventional CNN-based detection architectures. Given these advantages, YOLOv8x was employed in this study to automate and improve the detection of FP features, leveraging its cutting-edge architecture for forensic image analysis. To train YOLOv8x for FP minutiae recognition, a customized dataset was created using FPs developed with SMGO:2% Eu³⁺ phosphors. The dataset was manually labeled using bounding boxes to identify key minutiae features, including ridge endings, bifurcations, loops, and scars, as illustrated in FIG. 19(a). The network was trained over 90 epochs using sigmoid and ReLU activation functions to enhance the learning efficiency. The working environment is a machine using an NVIDIA 3060 12G, equipped with an Intel® Core™ i5-12700 CPU and 16 GB RAM. The deployment process included setting up the environment, installing dependencies (Python, Git, and the preferred deep learning framework such as PyTorch), downloading and configuring the YOLOv8x repository, compiling the model, and testing it on FP datasets. Once the model was successfully compiled, its effectiveness was tested by running predictions on sample FP images. Through a combination of convolutional and pooling layers, the model effectively extracted hierarchical features, enabling precise localization and classification of FP minutiae via bounding box regression. Here's a general outline of the process:
Install all required dependencies, including Python, Git, and core development libraries, to establish a functional software environment.
Based on project needs, choose an appropriate deep learning framework (e.g., TensorFlow, PyTorch, or Darknet) and install it alongside requisite dependencies.
Acquire the YOLOv8x implementation by either cloning the official GitHub repository using Git or downloading and extracting the ZIP file from the source platform.
Access the YOLOv8x directory and configure the model based on your hardware specifications and dataset requirements. Follow the repository's instructions for compiling and optimizing the model for your system. This may involve executing specific scripts or commands to enhance network performance.
Following successful compilation, perform functional testing of the model using representative images or video inputs.
Optimize the model's parameters through fine-tuning to better suit the targeted application. Concurrently, track system resource usage including CPU, GPU and memory and implement appropriate adjustments to enhance overall efficiency.
Document all installation procedures and configuration settings thoroughly to ensure reproducibility. In case of difficulties, refer to the official model documentation, relevant community forums, or support resources for troubleshooting guidance.

After training, the YOLOv8x model effectively detects and localizes minutiae points in previously unseen FP images. The network utilizes convolutional and pooling layers to extract relevant FP features, followed by bounding box predictions to determine the presence and precise spatial locations of minutiae. The output of YOLOv8x consists of bounding boxes enclosing the detected minutiae, providing precise coordinates for further processing. This capability enables efficient FP matching and verification against established databases. By providing a rapid and precise method for minutiae detection, YOLOv8x significantly improves the performance of automated FP recognition systems utilized in biometric identification, access control, and forensic investigations. FIG. 19(b) illustrates the computational analysis process for FP identification utilized in this study. The YOLOv8x object detection workflow comprises several key steps, as outlined below.

a. Pre-processing and feature extraction: FP images are first subjected to pre-processing procedures including resizing, normalization, binarization, and annotation to prepare them for input into the YOLOv8x framework. The model then employs a multi-layered neural network architecture to extract features across various scales, enabling it to predict bounding boxes, class probabilities, and confidence levels effectively.
b. Model training: A set of pre-processed FP images consistent in image ratio and object scale but differing in illumination due to phosphor variations were used to train the YOLOv8x model (FIG. 19(c)). The training involved feature learning across various layers to accurately distinguish fine details like bifurcations and ridge ends.
c. Prediction and post-processing: Post-processing techniques, including non-maximum suppression (NMS), were used to refine detection results by eliminating redundant bounding boxes and retaining high-confidence outputs (FIG. 19(d)). The model produced labelled bounding boxes indicating the location and class of detected minutiae features.
d. Network optimization and configuration enhancements: Considering the intricate nature of FPs with densely packed, small-scale, and often overlapping features—the YOLOv8x architecture was modified for optimal performance. The input images were resized to 640×640 pixels to activation maps, allowing better detection granularity. The training dataset consisted of FP images in 640×640 PNG format and was trained over 90 epochs with a batch size of 32. Model performance was evaluated using precision, recall, and F1-score curves, alongside confusion matrices illustrating true positives (TP), false positives (FP), false negatives (FN), and true negatives (TN) (FIG. 19(e)).
e. Evaluation metrics and accuracy analysis: To assess model accuracy, key metrics such as Precision, Recall, and F1-score were computed as follows:

$$Precision = \frac{T P}{T P + F P} \qquad ( 33 )$$

$$Recall = \frac{T P}{T P + F N} \qquad ( 34 )$$

$$F 1 = \frac{2 * P * R}{P + R} \qquad ( 35 )$$

Mean Average Precision (mAP), a comprehensive metric accounting for multiple detections and varying thresholds, was used to assess detection accuracy:

$$mAP = \frac{1}{N} {\sum }_{i = 1}^{N} A {P}_{i} \qquad ( 36 )$$

FP stands for false positives, P stands for precision, TP stands for true positives, FN stands for false negatives, AP stands for average precision and R stands for recall.
The Intersection over Union (IoU) metric is a key measure in object detection, used here to evaluate the YOLOv8x model's accuracy. IoU calculates the overlap ratio between predicted bounding boxes and corresponding ground truth annotations, as illustrated in FIG. 19(f). This metric offers a stringent assessment of the model's ability to precisely define object boundaries. In deep learning-based detection, the IoU threshold is crucial for deciding whether a predicted bounding box qualifies as a True Positive (TP). The threshold sets the minimum required overlap for a predicted bounding box to qualify as a correct detection. Commonly, a value of 0.5 is used, meaning the predicted and ground truth boxes must overlap by at least 50% to be counted as a positive detection (FIG. 19(g)). Adjusting the IoU threshold can greatly affect model outcomes. Raising the threshold enforces more stringent conditions, demanding closer alignment between predicted bounding boxes and the ground truth for successful detection. Although increasing the threshold improves precision by minimizing false positives, it may reduce recall since fewer predictions meet the criteria for true positives. This trade-off highlights the importance of selecting an optimal IoU threshold to achieve a balanced performance between precision and recall.

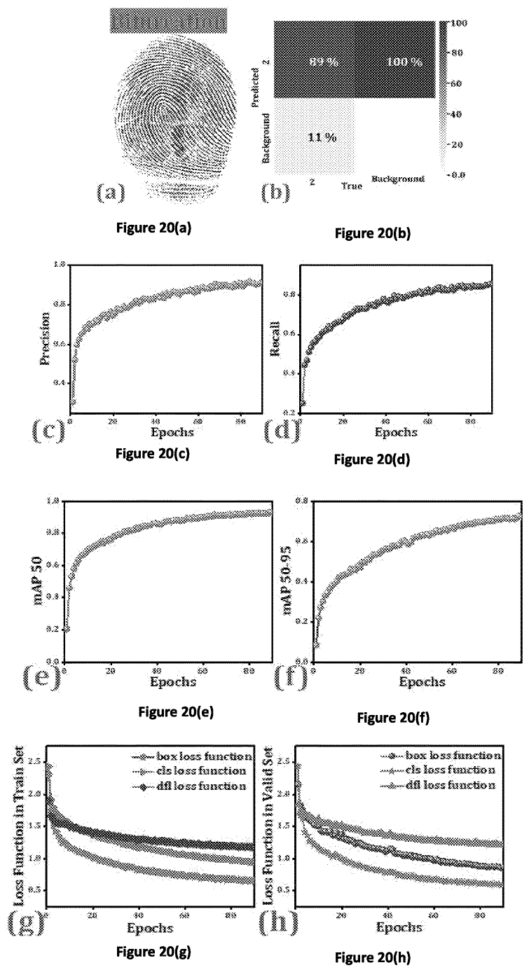

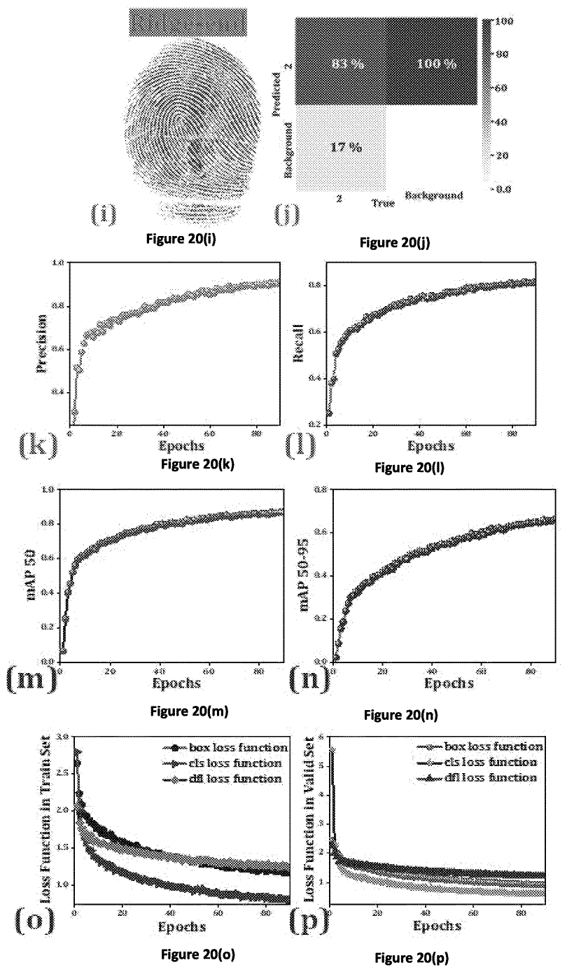

The YOLOv8x model was trained for 90 epochs using a labeled FP image dataset. Its structure is to dynamically divide each image into grids of different sizes, each grid cell can predict multiple boundary boxes at most, enabling accurate detection of FP minutiae such as bifurcations, ridge endings and loops. During training, the model effectively localizes and classifies these minutiae, ensuring high accuracy in FP recognition. FIG. 20(a) illustrates the bifurcation feature, where a single ridge splits into two branches, with detected instances highlighted in red. Detecting bifurcations presents challenges due to their variability in angle and length, as well as their potential intersections with other ridges. Similarly, FIG. 20(i) showcases the ridge-end feature, characterized by a terminating ridge. The small size and high density of ridge-ends make manual annotation time-intensive and introduce challenges in detection efficiency. To enhance feature recognition, FP images undergo binarization, which simplifies the structural information and improves detection accuracy. The model achieves Precision and Recall values of ~85% for both bifurcations and ridge-ends, demonstrating robust performance in FP analysis. FIGS. 20(b) & 20(j) present confusion matrices for these features, revealing an 89% recognition rate for ridge-ends and a 91% identification accuracy for bifurcations. Misclassified instances are categorized as background due to the absence of explicitly defined background features. The impact of training epochs on key performance metrics precision, recall, mAP@50, and mAP@50-95 for bifurcation and ridge-end detection is illustrated in FIGS. 20(c)-20(f) & FIGS. 20(k)-20(n). The study attains a mean Average Precision at 50% IoU (mAP@50) of 0.86 for detecting ridge endings and 0.94 for identifying bifurcations, demonstrating a notable improvement in FP recognition performance compared to current state-of-the-art methods. This enhancement is attributed to data augmentation techniques, which improve the model's generalization capability.

A comparison of the FP-YOLO baseline model's performance before and after 90 training epochs (FIGS. 20(g)-20(h) & FIGS. 20(o)-20(p)) reveals significant enhancements in:
Box loss (box_loss)—reflecting improved precision in the predicted bounding box coordinates.
Classification loss (cls_loss)—reflecting improved feature classification.
Distribution focal loss (dfl_loss)—signifying better handling of feature distribution variations.

The validation set results confirm the YOLOv8x model's superior performance, evidenced by improved feature localization and a reduction in both missed detections and false positives. These findings reinforce the model's reliability and practical applicability in FP-based biometric identification.

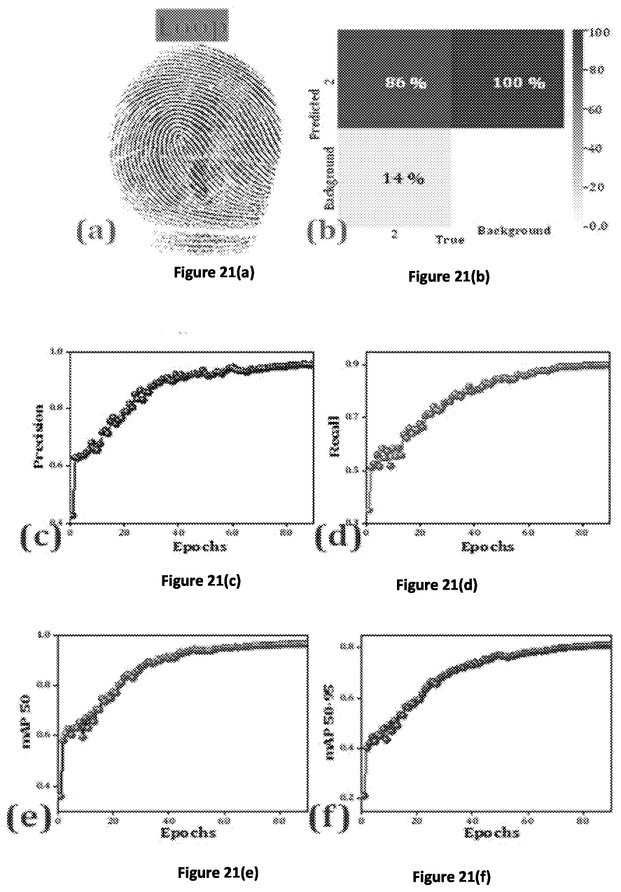

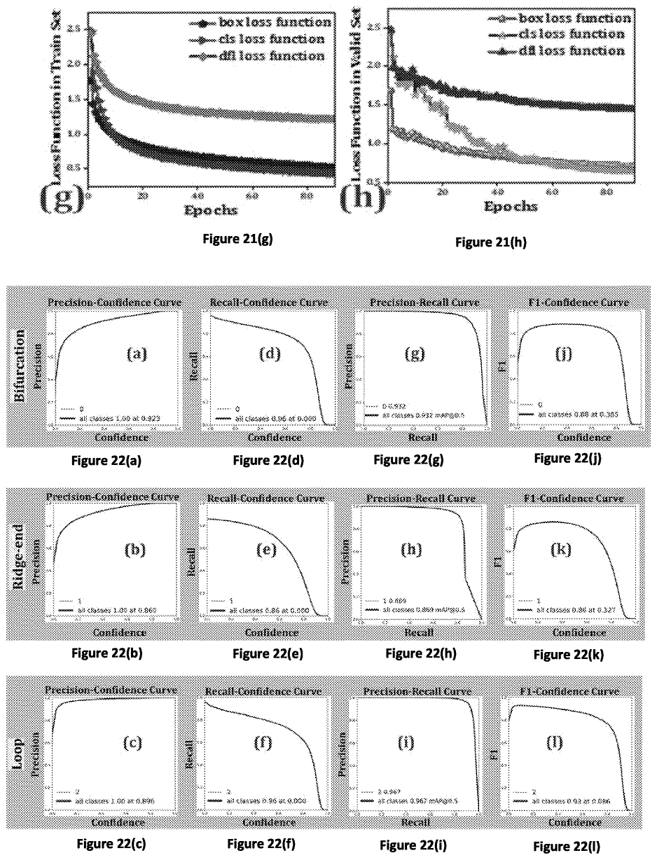

The model also exhibits exceptional capability in detecting loop features in FP images. FIG. 21(a) visualizes the loop feature, where a ridge curves back onto itself, with detected instances highlighted in red. Due to the variation in loop angles and lengths, detection is inherently challenging. Despite these complexities, the model attains a Precision and Recall of ~80% for loops, demonstrating its efficacy in recognizing this minutiae type. FIG. 21(b) presents confusion matrices for loop features. During training, loop feature were assigned a label of 0. The model achieved and a 86% recognition rate for loops. Since background features were not explicitly defined, misclassified instances were categorized accordingly.

FIGS. 21(c)-21(f) show the changes in precision, recall, mAP@50, and mAP@50-95 scores across training epochs for loop features. The model achieves a state-of-the-art mAP@50 of 0.96 for loops and 0.99 for scars, highlighting its exceptional performance in FP recognition. A comparative assessment of the FP-YOLO base model after 90 epochs (FIGS. 21(g) & 21(h)) highlights substantial reductions in box loss, classification loss, and distribution focal loss, signifying improved accuracy and reliability in feature classification and bounding box prediction. The refined model exhibits: Fewer missed detections, Fewer false positives Greater confidence in detection outcomes.

These improvements affirm YOLOv8x's robustness in recognizing and categorizing FP minutiae with unparalleled precision. FIG. 22 presents a comparative analysis of YOLOv8x's performance pre- and post-training across bifurcation, ridge-end and loop detection. Performance is evaluated using precision-recall curves, where optimal detection is indicated by values approaching 1.0 in our case. High precision ensures minimal false positives, while superior recall demonstrates the model's capability to detect all relevant features. FIG. 22(a)-22(l) illustrates precision-confidence, recall-confidence, precision-recall, and F1-confidence curves, offering insights into the model's predictive accuracy across varying confidence thresholds. A confidence level of 1.0 reflects optimal performance, where precision, recall, and F1-score converge towards their highest values, reinforcing YOLOv8x's reliability.

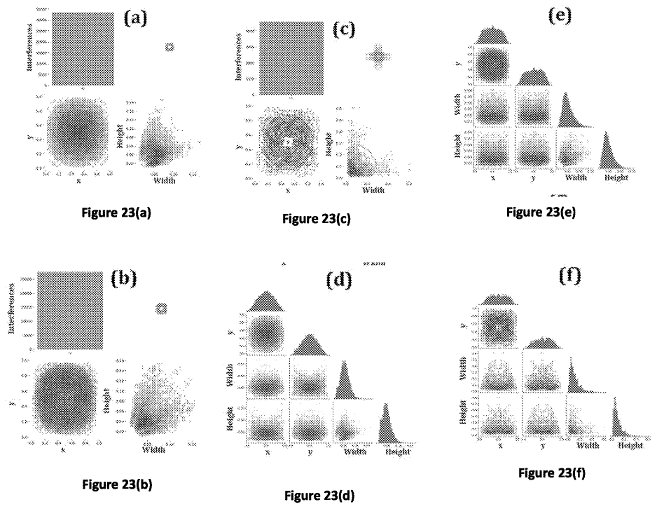

FIG. 23(a)-23(c) present bounding box annotations for detected FP features, including bifurcation, ridge-end, and loop characteristics. Every predicted bounding box is given a distinct ID along with a confidence score between 0 and 1, reflecting the model's strong accuracy in detecting FP features. These results further affirm YOLOv8x's adaptability to varying FP image conditions and structures. FIG. 23(d)-23(f) present a correlogram illustrating the detected FP features, providing a detailed visual overview of the relationships between various minutiae. The correlation coefficients, which vary from −1 to 1, measure both the strength and direction of these interactions. Deeper blue hues represent stronger positive correlations, revealing key structural linkages among scars, ridge-ends, loops, and bifurcations. This analysis deepens the understanding of FP feature interdependencies, aiding the development of improved biometric security key systems.

This study highlights notable progress in deep learning approaches for FP analysis, especially in reducing data dimensionality and accurately extracting minutiae features. When applied to FPs developed using SMGO:2% Eu³⁺ phosphors, the YOLOv8x model demonstrates markedly improved clarity and contrast, outperforming traditional detection techniques. By leveraging a deep convolutional neural network (DCNN) and robust training strategies, the model consistently detects and classifies minutiae with high precision. This research establishes a highly effective framework for automated FP recognition, with profound implications for forensic science, biometric authentication, and secure identification systems. The integration of YOLOv8x with optimized data augmentation strategies further enhances detection accuracy, pushing the boundaries of state-of-the-art FP analysis.

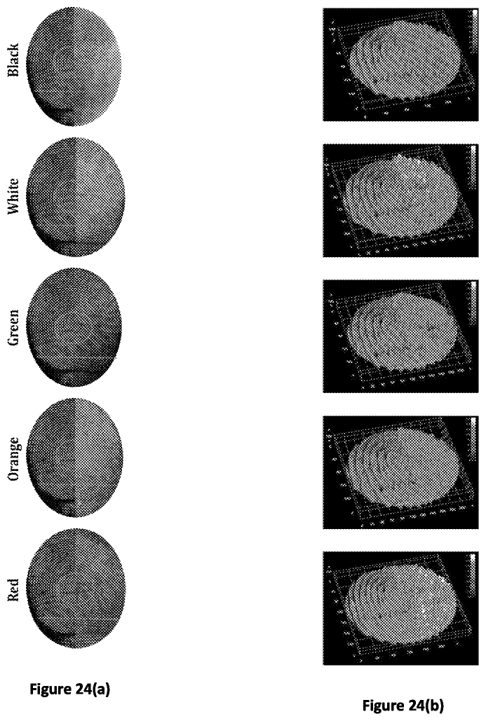

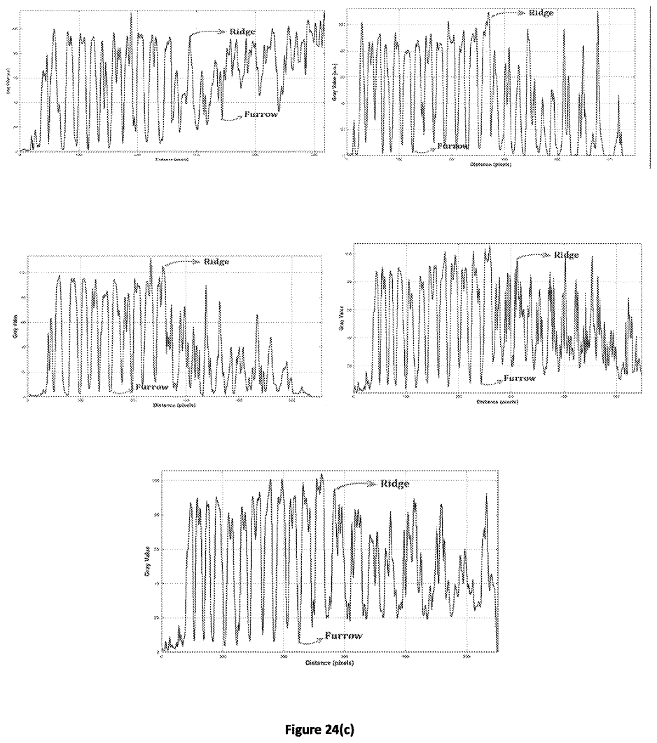

To assess the forensic potential of SMGO:2% Eu³⁺ phosphor relative to existing commercial standards, LFPs were developed using SMGO alongside five widely available phosphor powders black, white, green, orange, and red and evaluated under day light and 365 nm UV illumination. As shown in FIG. 24(a), all powders enabled ridge visualization on non-porous glass substrates, but with varying levels of fidelity and contrast. In each case, the region marked by a yellow circle was analyzed in greater detail using grayscale intensity profiles and 3D surface mapping. The SMGO:Eu³⁺ phosphor exhibited superior ridge clarity, characterized by pronounced peak-to-valley intensity fluctuations in the gray-value profile, indicating distinct differentiation between ridges and furrows. This is further supported by the uniform spacing and amplitude across the ridge structure, which reflects high binding selectivity and surface adherence. The 3D surface topography generated using ImageJ software highlights the elevated ridge morphology with minimal background noise, confirming consistent particle accumulation along FP residue patterns.

In comparison, some commercial powders displayed broader ridge features or reduced intensity contrast, likely due to less selective binding or higher background scattering. Notably, the green and orange powders showed uneven distribution and lower ridge resolution. The SMGO:Eu³⁺ phosphor thus matched or outperformed commercial counterparts across both 2D and 3D spatial analyses, as shown in FIG. 24(c), and FIG. 24(b), effectively capturing the full ridge flow and enhancing Level 1 and Level 2 FP features with excellent luminescent contrast. These results substantiate the efficacy of SMGO:Eu³⁺ phosphor as a viable forensic material for high-resolution LFP detection, offering a compelling alternative to existing commercial powders, especially under UV-assisted visualization scenarios.

The present invention relates to a method for synthesizing Sr₂MgGe₂O₇:xEu³⁺ (SMGO:xEu³⁺) phosphors (where x=0.5-6 mol %) by a green solution combustion method, wherein Stoichiometric molar amounts of strontium nitrate (Sr(NO₃)₂), magnesium nitrate (Mg(NO₃)₂·6H₂O), germanium dioxide (GeO₂), and europium nitrate (Eu(NO₃)₃·6H₂O) were dissolved in deionized water. Aloe vera gel extract was used as a natural fuel, and the resultant solution was stirred to obtain a homogeneous redox mixture. The beaker containing the solution was placed in a preheated muffle furnace (~500° C.). The solution boiled, ignited to form a gel, and combusted into a fine powder while releasing gases such as CO₂, H₂O, and N₂. The as-synthesized powder was subsequently annealed at 1000° C. for improved crystallinity. According to the findings, a tetragonal single-phase Sr₂MgGe₂O₇ crystal structure was obtained, and X-ray diffraction (XRD) analysis confirmed the absence of secondary impurity peaks. The Fourier Transform Infrared (FTIR) spectra of the synthesized samples displayed characteristic vibrational bands of germanate groups, confirming the phase formation. The scanning electron micrographs (SEM) revealed that the particles exhibited a uniform distribution with irregular/spherical morphology and porous nature, while EDAX spectra confirmed the elemental composition consistent with the nominal stoichiometry. The photoluminescence (PL) analysis of the phosphors exhibited strong red emission centered at ~613 nm, attributed to the \hat{ }5D₀→\hat{ }7F₂ transition of Eu³⁺ ions, with the optimal emission observed at 2 mol % doping concentration. The luminescence properties showed high color purity (>90%) with Commission Internationale de l'Éclairage (CIE) chromaticity coordinates (0.6512, 0.3484) in the red region, an internal quantum efficiency (IQE) of 78%, and excellent thermal stability retaining >90% intensity at 420 K. The thermometric performance was evaluated using the fluorescence intensity ratio (FIR) technique, where the phosphors demonstrated an absolute sensitivity (Sₐ) of 0.003112 K⁻¹ and a relative sensitivity (Sᵣ) of 1.314% K⁻¹ at 300 K, indicating suitability for optical temperature sensing applications. The phosphors were incorporated into a white light-emitting diode (w-LED) prototype, producing devices with chromaticity coordinates of (0.3421, 0.3278), a correlated color temperature (CCT) of ~5040 K, and a color rendering index (CRI) Ra of 93, demonstrating their potential for solid-state lighting. The phosphors were further applied in latent fingerprint (LFP) detection, showing excellent ridge detail visualization under UV excitation. Automated fingerprint recognition was achieved using a YOLOv8x deep learning model, which enabled rapid and accurate detection of ridge endings, bifurcations, and loops. The phosphors were also demonstrated as potential candidates for anti-counterfeiting security applications, owing to their stable luminescent properties and tunable emission under near-UV excitation.

FIG. 35 illustrates a flow chart of a process for synthesizing europium-doped Europium-doped strontium magnesium germanate (Sr²MgGe₂O₇) phosphors for white LEDs, latent fingerprint detection, and anti-counterfeiting applications, in accordance with an embodiment of the present disclosure. Referring to FIG. 35, the process (100) comprises a plurality of steps as described under:

At step 102, the method 100 includes preparing an aloe vera (A.V.) gel extract upon treating fresh aloe vera stems; At step 104, the method 100 includes (b) dissolving Sr(NO₃)₂, Mg(NO₃)₂, Ge(NO₃)₄, and Eu(NO₃)₃ corresponding to Eu³⁺ doping levels of 0-6 mol % in distilled water to form a homogenous solution; At step 106, the method 100 includes adding Aloe Vera (A.V.) gel extract as both fuel and templating agent to the solution; At step 108, the method 100 includes stirring the mixture at room temperature for 30 minutes using a magnetic stirrer to form a viscous gel-like solution; At step 110, the method 100 includes transferring the viscous gel-like solution in a borosilicate beaker and heating in a muffle furnace at 500° C. to initiate an exothermic combustion reaction producing a porous spongy mass; At step 112, the method 100 includes calcining the porous spongy mass at 800° C. for 4 hours; and At step 114, the method 00 includes cooling the material at room temperature and collecting thereby grinding using an agate mortar and pestle to obtain the europium-doped Sr₂MgGe₂O₇ (SMGO:x % Eu³⁺ (x=0-6 mol %)) phosphors.

In an embodiment, the preparing of the aloe vera (A.V.) gel extract comprising: cleaning the fresh Aloe Vera stems thoroughly using distilled water to eliminate surface impurities; removing an outer green skin from the stems using a sterilized knife and extracting the inner transparent gel; blending the extracted inner transparent gel to form a smooth and uniform consistency using a household blender; and storing the prepared A.V. gel extract in a sanitized container for subsequent use. In an embodiment, the preparation of the Aloe vera gel extract begins with the careful cleaning of freshly harvested Aloe vera stems using distilled water so that any externally adhered dust particles, soil residues, or microbial contaminants are removed before the gel is introduced into the precursor formulation. The elimination of these impurities is technically significant because foreign particulates, especially mineral grit or organic residues, alter the fuel-to-oxidizer balance during the subsequent combustion step and can lead to uncontrolled ignition or incomplete combustion. Following the cleaning step, the outer green rind of each stem is removed manually using a sterilized knife to ensure that only the inner parenchymatous transparent gel is collected. This separation is essential because the green cortex contains anthraquinones and fibrous tissues that char excessively during combustion, whereas the inner gel contains high concentrations of polysaccharides, glucomannan, amino acids, and phytochemicals that act as a uniform bio-fuel and natural chelating matrix. The extracted gel, once isolated from the outer rind, is then subjected to mechanical blending in an ordinary household blender until a consistent, smooth, homogenized gel is obtained. This blending step is crucial for breaking internal fibrous clumps, producing a uniform viscosity across the entire gel mass, and ensuring that every portion of the Aloe vera extract contains comparable concentrations of organic constituents. A uniformly blended gel promotes uniform metal-organic chelation with the precursor metal nitrates, leading to a highly homogeneous sol-gel complex that combusts evenly and yields a porous intermediate structure with consistent microstructural properties. The blended gel is finally stored in a sanitized, preferably airtight, container to prevent microbial growth, moisture uptake, or oxidative degradation during storage. Maintaining the gel in clean and controlled storage conditions preserves its organic integrity, ensuring its reproducibility as a fuel, chelating agent, and templating component in the green solution combustion synthesis of Sr₂MgGe₂O₇:x % Eu³⁺ phosphors. Experimental trials demonstrate that batches prepared with well-cleaned, blended, and properly stored Aloe vera gel produce more uniform combustion fronts, higher porosity in the intermediate spongy mass, and stronger photoluminescence intensities in the final calcined phosphor product compared to batches prepared with unprocessed or inconsistently prepared gel.

In an embodiment, the SrMgGeO4:x % Eu³⁺ (x=0-6 mol %) phosphors is prepared via a green solution combustion technique, repeated for each Eu³⁺ concentration from 0 to 6 mol %. In an embodiment, the SrMgGeO₄:x % Eu³⁺ phosphors are prepared using a green solution combustion technique in which the entire synthesis sequence is performed independently for each europium concentration from 0 to 6 mol % so that every batch exhibits a precisely controlled dopant level without cross-contamination or statistical dopant drift. Each synthesis run begins with dissolving stoichiometrically calculated quantities of strontium nitrate, magnesium nitrate, germanium nitrate or acid-converted GeO₂, and europium nitrate corresponding to a specific target doping level, followed by the addition of Aloe vera gel as a renewable fuel and bio-templating agent. The sol-gel precursor is stirred until complete homogeneity is reached, ensuring that europium ions are uniformly distributed within the gel matrix. Conducting the process separately for each doping level is technically significant because fluorescence properties of Eu³-activated phosphors are extremely sensitive to dopant concentration, and even trace variations can cause shifts in emission intensity, spectral bandwidth, and quenching onset. By preparing each Eu³⁺ concentration in an isolated combustion sequence, the diffusion of europium ions between batches is prevented, ensuring that 0, 1, 2, 3, 4, 5, and 6 mol % samples each undergo their own auto-ignition, gas-evolving combustion, and porous intermediate formation under identical oxidizer-fuel conditions. This approach enables systematic tuning of photoluminescence characteristics, evident from experimental observations where 2 mol % Eu³⁺ yields the brightest red emission, while higher dopant levels exhibit concentration quenching. The repetition of the synthesis process for each concentration also enhances reproducibility, as each batch experiences its own controlled thermal events, flame propagation pattern, and calcination behavior. The green solution combustion route further ensures energy-efficient synthesis because Aloe vera-derived organics supply the fuel necessary for rapid exothermic oxidation of nitrate ions, generating sufficient localized heat to initiate crystallization even before the final calcination stage. The eco-friendly nature of the fuel, combined with dopant-specific batch isolation, yields a series of compositionally precise phosphors with predictable optical performance suitable for applications in white LEDs, latent fingerprint visualization, and anti-counterfeiting. In an embodiment, preparing the Sr₂MgGe₂O₇:x % Eu³⁺ phosphors via the green solution combustion technique comprises preparing a separate precursor batch for each europium concentration by dissolving individually weighed quantities of the metal nitrates in preheated distilled water, adjusting the total oxidizer content by calculating oxygen equivalence from the nitrate ions, adding a measured amount of Aloe vera gel to each batch to establish a fuel-to-oxidizer ratio suitable for self-propagating combustion, stirring each batch until a uniform viscous gel is obtained, and transferring each viscous gel to a designated combustion vessel so that each europium concentration undergoes an independent combustion cycle, and wherein the green solution combustion technique for each europium concentration further comprises heating each viscous gel in a furnace that has been stabilized at a pre-dehydration temperature between 250° C. and 300° C. to remove entrapped moisture, subsequently elevating the furnace temperature to 500° C. to initiate auto-ignition of the gel matrix, permitting the combustion to propagate across the full gel mass through internally generated gases, holding each batch inside the furnace for a settling period after flame extinction to allow post-combustion intermediate phases to consolidate, and collecting the porous spongy mass corresponding to each europium concentration in a separately labeled container.

In an embodiment, preparation of the Sr₂MgGe₂O₇:x % Eu³⁺ phosphors through the green solution combustion technique involves formulating a separate precursor batch for each europium concentration in the 0-6 mol % range so that each dopant level is processed under isolated, controlled, and contamination-free conditions. For each batch, individually weighed quantities of strontium nitrate, magnesium nitrate, germanium nitrate or acid-converted GeO₂, and europium nitrate corresponding to the intended doping level are dissolved in distilled water that has been preheated to facilitate rapid solubilization and to improve homogeneity of the resulting cationic solution. The oxidizer content for each batch is calculated using oxygen equivalence derived from nitrate ions, ensuring precise stoichiometric balance between nitrate-derived oxidizing species and the bio-organic fuel contained in Aloe vera gel. By adding a measured amount of Aloe vera gel to each batch, a tailored fuel-to-oxidizer ratio is established that reliably supports self-propagating combustion without producing excess carbonaceous residues or incomplete ignition zones. Stirring each batch until it transforms into a uniform viscous gel ensures intimate mixing of metal cations with Aloe-derived polysaccharides, thereby forming stable metal-organic complexes that govern both combustion kinetics and crystal nucleation during subsequent thermal steps. Each viscous gel is transferred to its own designated combustion vessel, guaranteeing that europium ions do not diffuse or mix between batches and ensuring that each dopant concentration undergoes an independent ignition, combustion, and intermediate formation cycle.

The green solution combustion technique then proceeds by placing each precursor gel into a furnace that has been pre-stabilized at a controlled pre-dehydration temperature in the range of 250-300° C. This thermal stage ensures the slow and uniform removal of physically entrapped moisture and volatile phytochemicals from the gel matrix without triggering premature combustion or causing violent boiling. Once visible steam evolution diminishes, the furnace temperature is elevated to approximately 500° C., at which point the gel matrix undergoes auto-ignition driven by exothermic oxidation of Aloe organics by nitrate ions. Internally generated gases such as CO₂, NOₓ, and water vapor forcefully expand throughout the gel, creating an interconnected network of pores and generating the characteristic lightweight spongy structure. Allowing the combustion to propagate fully across the entire gel mass ensures that no cold spots or unburnt regions remain, which would otherwise compromise crystallinity and luminescent performance. After flame extinction, each batch is held inside the furnace for a settling period so that intermediate oxide phases, including partially formed Sr—Mg—Ge—O networks, stabilize and cool gradually without thermal shock. The porous spongy mass produced from each combustion cycle is collected in a separately labeled container corresponding to its europium concentration, ensuring perfect traceability of dopant levels for subsequent calcination and characterization. Experimental implementation of this embodiment demonstrates that maintaining separate combustion cycles for each europium percentage yields phosphors with highly reproducible emission behavior, superior phase purity, and tunable luminescence intensity, all attributed to the precise control of the fuel-to-oxidizer balance, moisture removal, combustion propagation, and batch isolation.

In an embodiment, the green solution combustion technique for each europium concentration additionally comprises crushing the porous spongy mass obtained from each combustion run, pre-drying each crushed mass at 120-150° C. to eliminate residual volatiles, loading each dried mass into a separate ceramic crucible, calcining each crucible at 800° C. for four hours while maintaining a controlled temperature ramp of 3-5° C. per minute, cooling each crucible naturally to room temperature inside the furnace chamber without forced convection, and subsequently grinding, sieving, and desiccating each calcined phosphor batch independently so that no cross-contamination occurs between different europium doping levels. In an embodiment, the green solution combustion technique for each europium concentration further includes a structured sequence of post-combustion thermal and mechanical treatments designed to stabilize the intermediate material, eliminate residual volatiles, and crystallize the Sr₂MgGe₂O₇:x % Eu³⁺ phase with high purity and consistent dopant distribution. After completion of the combustion event for a given europium concentration, the resulting porous spongy mass is carefully crushed to break down the expanded cellular structure into smaller fragments, thereby increasing the surface area available for subsequent drying and calcination. Crushing the mass also releases any semi-trapped gases and breaks weakly bound agglomerates that would otherwise inhibit uniform heat penetration. Each crushed batch is then subjected to a pre-drying step at 120-150° C., a temperature range selected to remove residual moisture, volatile organics, and incomplete combustion byproducts without inducing premature phase transition or structural collapse. This pre-drying stage is essential because even minor amounts of volatiles can evolve rapidly at calcination temperatures and create micro-explosions that disrupt the developing crystal lattice.

Following pre-drying, each europium-specific batch is loaded into its own ceramic crucible to prevent metal contamination and ensure thermal uniformity. Calcination is performed at 800° C. for four hours under a controlled temperature ramp of 3-5° C. per minute, a rate intentionally selected to promote gradual solid-state diffusion and controlled formation of the Sr₂MgGe₂O₇ host lattice while preventing thermal shock or dopant segregation. The extended dwell at 800° C. enables complete crystallization of the host matrix and uniform site occupancy of Eu³⁺ ions within the Sr- or Ge-coordinated environments. After calcination, each crucible is allowed to cool naturally inside the furnace chamber without forced convection so that the material experiences slow, uniform thermal relaxation, which reduces internal stress, minimizes crack formation, and prevents oxygen vacancy defects that negatively affect luminescence efficiency. Once the material reaches room temperature, each batch is independently ground to reduce particle size and improve powder homogeneity. Grinding also serves to collapse any remaining weak agglomerates formed during calcination. The ground powders are then sieved to achieve a consistent particle size distribution, typically excluding coarse fragments that scatter excitation light and reduce phosphor brightness. Each batch is finally desiccated under low-humidity conditions to stabilize the surface chemistry and prevent hygroscopic degradation, particularly in higher-doped europium samples where surface-bound moisture can quench luminescence. Critically, all grinding, sieving, and desiccation steps are performed independently for each europium concentration, ensuring no cross-contamination of dopant levels. This strict batch isolation is essential for maintaining luminescence predictability, as minor europium migration between batches could alter emission intensity, peak wavelength, and quenching behavior. Experimental results confirm that batches treated with this controlled sequence exhibit consistent red-emission characteristics and enhanced crystallinity, demonstrating the synergistic benefit of controlled crushing, drying, calcination, and isolated post-processing.

In an embodiment, further comprising preparing a first aqueous solution by heating distilled water to 75-85° C. and dissolving strontium nitrate and magnesium nitrate therein until the salts are visually dissolved; preparing a second solution by reacting germanium dioxide with nitric acid until a clear Ge-containing nitrate solution is obtained and filtering the Ge-containing solution through a 0.45 μm PTFE membrane to remove undissolved particulates; combining the first and second solutions and stirring the combined solution at 600-800 rpm until a homogeneous cationic precursor solution is formed; cooling the homogeneous precursor solution to ambient temperature; adding europium nitrate to the cooled precursor solution and stirring until the europium salt is fully dispersed; and thereafter adding the prepared Aloe vera gel extract to the combined nitrate solution while maintaining continuous stirring to give a uniformly mixed precursor gel.

In an embodiment, the process further includes preparing highly controlled aqueous precursor solutions so that all metal ions required for Sr₂MgGe₂O₇:x % Eu³⁺ formation are present in a uniform and chemically stable environment before gelation and combustion. This begins by heating distilled water to a temperature between 75-85° C., a range selected because it significantly enhances the dissolution rate of strontium nitrate and magnesium nitrate without causing premature thermal decomposition. When these salts are added to the heated water, they fully dissolve to form a transparent solution, ensuring that Sr²⁺ and Mg²⁺ ions are evenly distributed and immediately available for subsequent coordination with germanium and europium species. Parallel to this, a second solution is prepared by reacting germanium dioxide with nitric acid under controlled heating until the suspension transitions into a clear, particle-free Ge-containing nitrate solution. This transformation is critical because GeO₂ exhibits limited solubility in water, but reacts completely with nitric acid to form soluble germanium nitrate complexes. The resulting solution is then passed through a 0.45 μm PTFE membrane filter to remove any undissolved particulates or colloidal silica-like residues that would otherwise introduce heterogeneity, act as unwanted nucleation sites, or interfere with later combustion behavior. The first and second solutions are blended and stirred at 600-800 rpm to generate a homogeneous cationic precursor mixture in which Sr²⁺, Mg²⁺, and Ge⁴⁺ ions coexist in a uniformly distributed state. Maintaining this stirring speed is important because it promotes rapid ion mixing without introducing mechanical shear strong enough to cause premature gelation. After the solution is homogenized, it is cooled to ambient temperature, a step that stabilizes the system before europium nitrate addition. Introducing europium nitrate into the cooled solution prevents heat-triggered localized precipitation or hydrolysis of Eu³⁺ species, ensuring that europium ions disperse uniformly. Continued stirring ensures complete dissolution and full distribution of europium ions throughout the mixed precursor, which is crucial because europium luminescence properties depend heavily on uniform dopant incorporation within the final crystalline lattice.

Once all metal nitrates are fully dissolved and homogeneously distributed, the previously prepared Aloe vera gel extract is gradually added to the precursor solution while maintaining continuous stirring. Aloe vera contains polysaccharides, amino acids, and organic acids that chelate metal ions, enhance sol-gel formation, and serve as a bio-fuel during combustion. Continuous stirring during gel incorporation prevents localized over-gelation and creates a uniformly mixed precursor gel with consistent viscosity and homogeneity. This uniformity ensures that during the subsequent combustion step, heat release, gas evolution, and pore formation occur evenly across the entire gel matrix, producing a spongy intermediate with reproducible microstructural properties. Experimental comparisons show that precursor batches prepared using the dual-solution approach followed by controlled blending with Aloe vera exhibit significantly improved combustion uniformity, reduced secondary phase formation, and enhanced post-calcination crystallinity compared to batches prepared by directly mixing all components in a single step. This embodiment therefore plays a critical enabling role in ensuring structural integrity, dopant homogeneity, and luminescent efficacy in the final Sr²MgGe₂O₇:x % Eu³⁺ phosphor material.

In an embodiment, further comprising warming the Aloe vera gel extract to 40-50° C. to reduce its viscosity prior to incorporation into the precursor solution; calculating and setting a fuel-to-oxidizer stoichiometry based on the total nitrate oxygen content so that the overall mixture is slightly fuel-lean; adding the warmed Aloe vera gel extract to the homogeneous nitrate solution in a controlled, continuous feed so as to avoid local hot spots; maintaining the mixed system under a controlled shear provided by stirring at 400-550 rpm until the mixture attains a viscous gel state indicative of metal-phytochemical chelation; and holding the resultant viscous gel under gentle agitation for a further 20-40 minutes to permit equilibration of metal-ligand complexes within the gel matrix. The warmed Aloe vera gel is then added to the homogeneous nitrate solution in a controlled, continuous feed rather than in a single addition. This slow-feed method prevents the formation of localized hot spots or premature gelation zones caused by sudden chelation between metal ions and organic ligands. Such controlled addition also ensures that viscosity increases uniformly across the volume of the precursor, maintaining an even distribution of Sr²⁺, Mg²⁺, Ge⁴⁺, and Eu³⁺ ions within the forming gel. The mixture is stirred at a controlled shear rate of 400-550 rpm, a range selected to provide sufficient dynamic mixing to break micro-domains of concentrate while avoiding excessive shear that could disrupt early coordination structures forming between metal ions and Aloe-derived phytochemicals. As stirring continues, the mixture transforms into a viscous gel, a state that reflects the formation of metal-phytochemical chelate networks in which Aloe polysaccharides bind with cations, providing a uniform nanoscale distribution of metal precursors. This uniform gel structure is foundational for achieving consistent combustion propagation and homogeneous pore formation in the subsequent furnace ignition step.

After the gel has reached the desired viscosity, it is held under gentle agitation for an additional 20-40 minutes to allow equilibration of metal-ligand complexes throughout the matrix. This equilibration period is critical because it permits slow rearrangement and stabilization of coordination bonds, ensuring that the europium dopant becomes uniformly integrated into the precursor structure rather than aggregating or segregating. Experimental studies reveal that gels which undergo this equilibration exhibit markedly improved combustion behavior, yielding intermediate spongy masses with finer porosity and fewer unburnt residues, and upon calcination produce Sr₂MgGe₂O₇:x % Eu³⁺ phosphors with higher crystallinity, stronger emission intensity, and reduced concentration quenching. Thus, the warming, stoichiometric balancing, controlled feed addition, shear-managed mixing, and gel equilibration steps collectively form a synergistic set of conditions that ensure the precursor matrix is chemically and structurally optimized for high-quality phosphor formation.

In an embodiment, further comprising: mixing synthesized SMGO:2% Eu³⁺ red-emitting phosphor with blue-emitting BaMgAl₁₀O₁₇:Eu²⁺ phosphor and a green-emitting (Ba,Sr)₂SiO₄:Eu²⁺ phosphor to form a phosphor blend; combining the phosphor blend with a 398 nm blue LED chip; mixing the phosphor blend and chip with organic silica gel in a mass ratio of 1:1:2; stirring the phosphor-silica mixture to ensure even dispersion; uniformly applying the mixture over the blue LED chip surface; and curing the composite at 100° C. for 10 hours. The resulting phosphor blend is combined with a 398 nm InGaN-based blue LED chip, whose near-UV excitation wavelength is chosen because it can simultaneously excite Eu²⁺ and Eu³⁺ dopants across all three phosphors. To convert the phosphor mixture into a workable LED-packaging composite, the blend is mixed with an organic silica gel binder in a mass ratio of 1:1:2 (phosphor:chip:silica). This ratio ensures that the silica gel provides sufficient encapsulation strength and optical transparency while allowing adequate phosphor loading for high luminous output. The silica matrix also protects the phosphor particles from environmental degradation and enhances thermal dissipation during device operation.

The phosphor-silica mixture is then stirred thoroughly to ensure even dispersion of the phosphor particles throughout the viscous silica medium. Uniform dispersion is technically critical because particle clustering causes optical scattering, localized color shift, and reduced luminous efficiency. After achieving a homogeneous suspension, the composite is uniformly applied over the surface of the blue LED chip, forming a continuous and optically stable phosphor-converting layer. Uniform coating ensures that the excitation light interacts equally with all phosphor types, producing a balanced white output without spectral asymmetry. The applied composite is then subjected to curing at 100° C. for ten hours, a condition that allows the silica gel to polymerize into a transparent, mechanically robust encapsulant. This curing step locks the phosphor particles into a stable three-dimensional network while preventing sedimentation, phase separation, or micro-void formation. Prototype LED packages fabricated using this embodiment exhibit smooth white emission with strong red contribution from the SMGO:2% Eu³⁺ phosphor, enabling improved color rendering index (CRI), enhanced stability under continuous operation, and minimized thermal quenching. The synergistic combination of a stable inorganic host lattice (Sr₂MgGe₂O₇), optimal Eu³⁺ doping level, uniformly dispersed phosphor blend, and controlled silica encapsulation results in a highly efficient, thermally robust, and reproducible LED phosphor composite suitable for commercial lighting, display backlighting, and specialty illumination applications.

In an embodiment, further comprising: mixing 10 mL of distilled water with polyvinyl alcohol (PVA) as a binder; heating the mixture to 85° C. with continuous stirring to form a clear, uniform solution; incorporating SMGO:2% Eu³⁺ phosphor powder into the solution; subjecting the mixture to ultrasonic treatment for homogeneous dispersion and to prevent particle agglomeration.

In an embodiment, the process further comprises preparing a polyvinyl alcohol (PVA)-based dispersion of the SMGO:2% Eu³⁺ phosphor to enable its use in flexible films, latent fingerprint visualization matrices, and surface-coating applications. This begins by mixing 10 mL of distilled water with an appropriate quantity of PVA serving as a film-forming binder. Distilled water is selected to avoid ionic contaminants that may interfere with phosphor surface chemistry. The mixture is heated to approximately 85° C. under continuous stirring, a temperature high enough to dissolve PVA completely and disrupt intermolecular hydrogen bonds, thereby yielding a clear, homogenous polymer solution. The clarity of the solution serves as a practical indicator that PVA chains are fully solvated and able to uniformly encapsulate phosphor particles in the subsequent mixing stage.

Once the PVA solution becomes transparent and uniform, SMGO:2% Eu³⁺ phosphor powder—chosen because its europium concentration yields maximum red luminescence—is added directly to the polymer solution. Incorporating the phosphor at this stage ensures intimate mixing between the polymer chains and the particle surfaces before the system cools and viscosity begins to increase. The dispersion is immediately subjected to ultrasonic treatment, typically using a probe or bath sonicator, to break apart any agglomerates formed during powder handling or initial mixing. Ultrasonic cavitation introduces localized microturbulence and collapse of vapor bubbles, generating high-shear zones that separate aggregated phosphor particles and distribute them evenly throughout the PVA matrix. This step is technically critical because particle agglomeration leads to light scattering, reduced luminescence homogeneity, and overshadowing of ridge detail when used in latent fingerprint development.

Through this ultrasonic-assisted homogenization, the phosphor particles become well dispersed and coated with thin layers of solvated PVA, enhancing suspension stability and preventing particle settlement. When this phosphor-PVA mixture is later applied onto a substrate or surface, the uniformly dispersed phosphor particles interact consistently with incident UV or near-UV radiation, producing bright, continuous luminescence. In forensic testing scenarios, this uniform luminescence produces sharp ridge contrast between fingerprint valleys and peaks. In thin-film applications, the PVA-phosphor composite dries into a flexible, transparent film containing evenly distributed SMGO:2% Eu³⁺ particles embedded in a mechanically stable polymer matrix. The synergy between the hydrophilic PVA binder, the high-emission phosphor, and ultrasonic dispersion results in a reproducible, stable, and high-performance coating system suitable for forensic, optical, and display-related uses.

In an embodiment, further comprising transferring the viscous gel into a borosilicate vessel and preheating a muffle furnace to 250-300° C., inserting the vessel into the furnace and maintaining the preheat temperature for a period sufficient to drive off physically adsorbed water, rapidly raising the furnace temperature to 500° C. to initiate self-propagating exothermic combustion across the gel volume, allowing the combustion to proceed to completion such that gaseous products evolve and a porous spongy mass forms, and removing the spongy mass from the furnace after visible cessation of combustion; and breaking the large agglomerates of the porous spongy combustion product to obtain a free-flowing powder; pre-drying the powder at 120-150° C. for 1-2 hours to remove residual moisture and volatile organics; loading the dried powder into a ceramic crucible and placing the crucible into a calcination furnace; increasing the furnace temperature from ambient at a controlled ramp rate of 3-5° C. per minute to 800° C., holding at 800° C. for 4 hours to enable solid-state diffusion and phase formation, and allowing the furnace to cool naturally to room temperature within the closed furnace chamber before unloading the calcined product. During combustion, internally generated gases-including CO₂, NOₓ, steam, and organic decomposition products-expand within the gel matrix, producing a foamed, porous, spongy mass characterized by a high surface area and an intermediate oxide framework of Sr—Mg—Ge—O species. Allowing the combustion to propagate completely ensures that the entire gel mass experiences uniform thermal exposure, which is crucial for achieving consistent porosity and precursor homogeneity. Once visible flame activity ceases, the borosilicate vessel is removed from the furnace and the lightweight spongy combustion product is collected. At this stage, the mass typically contains large agglomerates formed during the foaming process, and these are manually broken down to obtain a free-flowing powder that can undergo uniform heat treatment. The broken-down intermediate powder is then subjected to a pre-drying step at 120-150° C. for 1-2 hours to remove any residual moisture and volatile organic fragments left from incomplete combustion. This step prevents rapid gas evolution during high-temperature calcination, which could otherwise cause particle cracking or disrupt crystallite growth. After drying, the powder is loaded into a separate ceramic crucible, chosen for its inertness and ability to withstand high-temperature oxidation environments, and placed into a calcination furnace. The furnace temperature is increased from ambient at a controlled ramp rate of 3-5° C. per minute to ensure gradual densification and thermal equilibration; excessively rapid heating could create thermal gradients leading to defect formation or dopant segregation. Upon reaching 800° C., the temperature is maintained for four hours, providing sufficient time for solid-state diffusion and complete crystallization of the Sr₂MgGe₂O₇ lattice doped with Eu³⁺ ions. This prolonged dwell at 800° C. enables the transition of amorphous or partially crystalline intermediates into a well-ordered tetragonal or orthorhombic structure characteristic of the targeted host matrix.

Once calcination is complete, the furnace is switched off and the crucible is allowed to cool naturally within the closed chamber. Natural cooling minimizes thermal shock and preserves lattice integrity, preventing microcracking that would otherwise reduce luminescent efficiency. The resulting calcined phosphor, when removed at room temperature, exhibits enhanced crystallinity, stable morphology, and a uniform distribution of europium dopants, which collectively contribute to higher emission intensity and better thermal stability in subsequent LED, forensic, and anti-counterfeiting applications. This staged thermal protocol-preheating, combustion, pre-drying, controlled ramping, sustained calcination, and natural cooling-acts synergistically to create a structurally and optically optimized phosphor material with excellent batch reproducibility.

In an embodiment, the process 100 further comprising: grinding the calcined mass in an agate mortar and pestle using a circular grinding motion for 20-30 minutes to provide a uniformly milled phosphor powder; sieving the milled powder through a non-metallic sieve having nominal pore dimensions between 100 μm and 150 μm to remove oversized agglomerates; placing the sieved powder into a desiccator to equilibrate under low humidity conditions prior to packaging; and storing the equilibrated powder in sealed, inert-lined containers to prevent atmospheric contamination; and preparing separate precursor batches for each desired europium doping concentration in the range 0-6 mol % by weighing Sr(NO₃)₂, Mg(NO₃)₂, Ge precursor and Eu(NO₃)₃ on an analytical balance to the required molar ratios, dissolving and combining the precursors to form an individual homogeneous solution for each doping level, adding Aloe vera gel to each batch to form a respective viscous gel, subjecting each batch independently to the combustion and calcination sequence described above.

In an embodiment, the process 100 further comprising converting GeO₂ to a soluble Ge nitrate prior to precursor mixing by adding a stoichiometric excess of nitric acid, heating the GeO₂-acid mixture until complete dissolution of GeO₂ is evidenced by the absence of solids, neutralizing any excess acid to a pH of about 3.0-4.0 to maintain ionic activity suitable for metal complexation, filtering the resultant Ge nitrate solution to remove insoluble residues, and immediately using the filtrate in precursor preparation to avoid hydrolytic precipitation; and adjusting the pH of the viscous precursor gel to a value between 3.0 and 4.0 by controlled addition of nitric acid to stabilize dissolved Ge and Eu species, continuing gentle stirring of the pH-adjusted gel for a period of 20-30 minutes to enable redistribution of cations within the Aloe-based chelating matrix, monitoring the viscosity of the gel using a viscometric sensor until the viscosity range of 2-6 Pa s is attained, and transferring the gel to a borosilicate reaction vessel only after said viscosity range is reached.

In an embodiment, the process 100 further comprises post-calcination refinement of the phosphor powder, beginning with the grinding of the calcined mass using an agate mortar and pestle for a duration of 20-30 minutes under a consistent circular grinding motion. Agate is selected because it is non-reactive and introduces no metallic contamination that could alter luminescence properties, particularly in Eu³⁺-activated phosphors where trace impurities can cause parasitic emission bands. The controlled grinding duration ensures that the brittle calcined agglomerates are uniformly reduced to fine particles without overheating or destroying the crystalline domains formed during calcination. Once grinding is complete, the powder is passed through a non-metallic sieve with pore sizes between 100 μm and 150 μm, enabling the removal of oversized agglomerates that can scatter excitation light and reduce both emission uniformity and coating smoothness in practical applications. The fraction that passes through the sieve contains the desirable particle size distribution needed for consistent optical properties, efficient LED encapsulation, or smooth fingerprint visualization layers.

The sieved powder is placed in a desiccator and allowed to equilibrate under low-humidity conditions so that the particle surfaces remain dry and free from moisture adsorption. This conditioning step is technically significant because moisture-induced surface hydroxylation can quench Eu³⁺ luminescence or destabilize phosphor-binder interfaces in later device fabrication. After equilibration, the phosphor is stored in sealed containers lined with inert polymer coatings to prevent atmospheric contamination, cross-reactivity with container surfaces, and unintended adsorption of airborne particulates. This ensures long-term stability and reproducibility of optical performance. In addition to handling the calcined product, the embodiment further requires preparing entirely separate precursor batches for each europium doping concentration in the 0-6 mol % range. For each desired doping level, precise quantities of Sr(NO₃)₂, Mg(NO₃)₂, Ge precursor (either Ge(NO₃)₄ or acid-dissolved GeO₂), and Eu(NO₃)₃ are weighed on an analytical balance to achieve accurate molar ratios. These salts are dissolved and combined to form an individual homogeneous solution for each concentration, ensuring that Eu³⁺ ions are fully dispersed and available for uniform incorporation into the Sr₂MgGe₂O₇ lattice during crystal growth. Aloe vera gel is added separately to each precursor solution to form a distinct viscous gel, with each batch undergoing its own combustion reaction and calcination sequence in strict isolation. This practice prevents unintentional transfer of europium ions between batches, a critical requirement because even minor dopant contamination can significantly shift emission peaks, alter quenching thresholds, or distort concentration-dependent photoluminescence comparisons.

Once each batch is processed through the combustion, drying, calcination, and grinding-sieving protocol, the resulting phosphor powders are meticulously labeled and segregated according to their nominal Eu³⁺ concentration. This enables accurate correlation between synthesis parameters and final optical properties, ensuring that the material behaves predictably in LED packaging, anti-counterfeiting luminescent inks, or latent fingerprint visualization agents. The strict independence of batch preparation, combined with careful grinding, conditioning, and contamination-free storage, produces a suite of phosphors exhibiting high crystallinity, controlled dopant distribution, and consistent performance across all europium concentrations.

In an embodiment, comprising degassing the homogeneous precursor solution by applying low-pressure evacuation for 3-5 minutes to remove dissolved air pockets that may disrupt combustion, returning the degassed solution to atmospheric pressure, reheating the solution to 40-50° C. to maintain reduced viscosity, and subsequently adding the Aloe vera gel under continuous stirring to form a uniformly aeration-free viscous gel. In an embodiment, the process further comprises an essential degassing step in which the homogeneous precursor solution is subjected to low-pressure evacuation for approximately 3-5 minutes to remove dissolved air pockets and entrained microbubbles that would otherwise influence the combustion dynamics. When nitrate-Aloe vera precursor solutions contain dissolved gases, rapid expansion of these trapped air pockets during the onset of combustion can generate micro-explosions or uneven flame propagation, thereby disrupting the uniformity of pore formation and compromising the homogeneity of the resulting spongy combustion product. By placing the precursor solution under reduced pressure, these dissolved gases escape as visible bubbles, ensuring that the mixture transitions into a more stable, gas-free state. After degassing, the precursor is returned to atmospheric pressure in a controlled manner to prevent re-introduction of air into the solution.

The degassed precursor is then reheated gently to a temperature between 40-50° C. to maintain a slightly reduced viscosity, facilitating smooth incorporation of the Aloe vera gel fuel component. Maintaining this temperature range ensures that the solution remains fluid enough for thorough mixing while avoiding thermal decomposition of the organic phytochemicals present in the Aloe vera extract. Once the solution has reached the desired temperature, the Aloe vera gel is introduced gradually under continuous stirring, allowing the polymeric and phytochemical constituents of the gel to interact uniformly with the dissolved metal nitrates. This slow addition prevents the formation of air pockets during mixing and ensures that the resulting material remains aeration-free. Continuous stirring during gel incorporation establishes a controlled interaction between the metal ions and Aloe-derived organic ligands, promoting the formation of a smooth, uniformly thick viscous gel with consistent structural integrity. An aeration-free gel is critical for combustion uniformity, as trapped air pockets can act as irregular ignition points, producing uneven temperature zones or incomplete reaction regions. Experimental outcomes demonstrate that precursor gels processed through this degassing and controlled mixing protocol combust far more uniformly, generating finer, more consistent pore structures in the intermediate spongy mass and ultimately yielding calcined phosphors with superior crystallinity, improved luminescence intensity, and minimized defect density. Thus, the combined steps of degassing, viscosity-controlled reheating, and uniform gel formation contribute synergistically to a robust and highly reproducible green combustion synthesis route for Sr₂MgGe₂O₇:x % Eu³⁺ phosphors.

In an embodiment, further comprising: placing the borosilicate vessel containing the viscous gel in a preheated muffle furnace maintained at 250-300° C. for a pre-dehydration phase, holding the gel at this temperature until steam evolution visibly subsides, raising the temperature rapidly to 500° C. to initiate combustion, and retaining the vessel in the furnace until the combustion front propagates throughout the entire gel matrix and visibly forms a lightweight porous mass; and allowing the combusted porous mass to remain within the furnace chamber for an additional residence period of 5-10 minutes after flame extinction to stabilize intermediate oxide species, removing the vessel from the furnace while maintaining ambient airflow around the vessel, mechanically crushing the mass immediately while still warm to reduce macro-agglomerates, and then transferring the crushed powder into a drying oven. Once adequate dehydration is achieved, the furnace temperature is rapidly increased to approximately 500° C., which is the ignition threshold at which the nitrate oxidizers undergo vigorous exothermic reaction with the Aloe vera-derived organic fuel. This sudden temperature rise triggers a self-propagating combustion front that travels through the gel, generating internally evolving gases such as CO₂, NOₓ, and steam. These expanding gases create a highly porous, foamed architecture characteristic of solution combustion intermediates. Retaining the vessel in the furnace during this phase allows the combustion front to propagate fully throughout the entire gel matrix, ensuring that no cold or unburnt regions remain. The end result is a lightweight, spongy mass that contains uniformly distributed precursor oxide species.

After the visible flame has extinguished, the porous mass is allowed to remain in the furnace chamber for an additional residence period of 5-10 minutes. This brief post-combustion stabilization period enables the intermediate oxide species to undergo partial sintering and structural rearrangement under residual furnace heat, helping to lock the primary oxide framework into a more stable configuration prior to mechanical handling. Removing the material immediately after flame extinction without this stabilization step can lead to structural collapse of the porous matrix, incomplete oxidation, or premature cooling that freezes undesirable amorphous phases.

Once the stabilization period is complete, the vessel is carefully removed from the furnace while maintaining ambient airflow around the vessel to ensure gradual, uniform cooling of the lightweight mass. The porous material, still warm and mechanically fragile, is then immediately crushed to reduce large macro-agglomerates into manageable fragments. Crushing while warm is advantageous because the material is less brittle and fractures cleanly along its porous boundaries, resulting in a more uniform particle size distribution prior to drying. The crushed intermediate powder is subsequently transferred into a drying oven, where residual moisture and combustion byproducts are eliminated, producing a thermally conditioned powder ready for calcination. This embodiment ensures consistent combustion behavior, homogeneous pore formation, reduced defect sites, and improved phase evolution during calcination, all of which contribute to high-performance Sr₂MgGe₂O₇:x % Eu³⁺ phosphors.

In an embodiment, further comprising: drying the crushed porous product at 120-150° C. for 1-2 hours to remove moisture generated during combustion, mixing the dried material thoroughly prior to calcination to redistribute fine and coarse fragments, placing the mixed powder into a high-purity ceramic crucible, and positioning the crucible in the central heating zone of a programmable calcination furnace; initiating calcination by ramping the furnace temperature at 3-5° C. per minute from ambient temperature to 800° C., maintaining a uniform temperature distribution around the crucible by centering the crucible within the furnace, holding the temperature at 800° C. for 4 hours to enable solid-state diffusion pathways to complete, and subsequently allowing the furnace to cool naturally to room temperature without forced ventilation; and removing the calcined mass from the furnace only after the temperature reaches below 80° C., transferring the calcined mass to an agate mortar, applying continuous circular grinding force until the powder achieves a visually uniform texture, and performing intermediate mixing during grinding to collapse residual agglomerates. Calcination is initiated by ramping the furnace temperature from ambient to 800° C. at a controlled rate of 3-5° C. per minute, a range optimized to allow gradual removal of residual organic fragments, promote progressive solid-state diffusion, and minimize thermal shock to the developing Sr₂MgGe₂O₇ lattice. A rapid ramp would risk collapsing the porous structure prematurely or generating micro-cracks, while an excessively slow ramp may encourage unwanted secondary phases. Maintaining a uniform temperature distribution around the crucible ensures isotropic growth of crystalline grains, suppressing dopant segregation or spatially uneven formation of the Eu³⁺-activated luminescent centers. Holding at 800° C. for 4 hours provides sufficient time for solid-state diffusion pathways to complete, enabling the precursor oxides to react fully and form a phase-pure Sr₂MgGe₂O₇ host lattice with europium ions incorporated into stable substitutional sites. This dwell time is also important for eliminating residual structural disorder that can act as non-radiative recombination centers and reduce emission efficiency.

After calcination, the furnace is allowed to cool naturally to room temperature without forced ventilation. Natural cooling avoids abrupt thermal gradients that could induce microstructural stress or fracture the crystallized phosphor particles. The calcined mass is removed only after the temperature drops below approximately 80° C., ensuring safe handling and preventing damage from thermal shock. The cooled mass is then transferred to an agate mortar, and continuous circular grinding is applied until the powder achieves a visually uniform texture. Agate is chosen because it avoids metal contamination that could modify the electronic environment of Eu³⁺ ions. Intermediate mixing during grinding helps collapse residual agglomerates formed during calcination, producing a more refined and consistent particle-size distribution. This post-calcination refinement improves powder flowability, enhances coating uniformity when applied in LED or forensic formulations, and optimizes the optical behavior of the final phosphor by minimizing light-scattering defects. The synergy between controlled drying, precise thermal ramping, uniform furnace positioning, extended high-temperature soaking, natural cooling, and rigorous post-processing yields a high-crystallinity, defect-minimized Sr₂MgGe₂O₇:x % Eu³⁺ phosphor with superior luminescent performance and batch reproducibility.

In an embodiment, the process further comprising: sieving the ground phosphor powder through a non-metallic sieve having a nominal pore dimension of 100-150 μm, collecting the fraction of powder that passes through the sieve as the target product, returning the coarse fraction above the sieve to the mortar for additional grinding, and repeating grinding and sieving cycles until no oversized particles remain; transferring the sieved phosphor powder to a desiccator containing a moisture-adsorbing medium, holding the powder in the desiccator for a conditioning period sufficient to achieve low-humidity equilibrium, and storing the conditioned powder in sealed containers lined with inert polymer coatings for subsequent handling; and preparing separate precursor mixtures for each europium concentration in the range 0-6 mol %, dissolving metal nitrates for each mixture individually to avoid cross-contamination, adding Aloe vera gel to each solution separately to produce individual viscous gels, and conducting combustion and calcination for each doping level independently so that each concentration yields its own distinct phosphor batch.

After achieving the desired particle refinement, the sieved phosphor powder is transferred into a desiccator containing a moisture-adsorbing medium such as silica gel or phosphorus pentoxide. The powder is held in the desiccator for a conditioning period sufficient to achieve low-humidity equilibrium. This moisture reduction step is essential because the surface of Eu³-doped phosphors is prone to hydroxylation, and adsorbed water molecules can quench luminescence by creating non-radiative decay pathways. Conditioning ensures that the powder remains dry, structurally stable, and optically consistent for downstream processes. Following conditioning, the powder is stored in sealed, inert-lined containers to safeguard it from atmospheric humidity, airborne contaminants, and container-surface interactions. Using inert polymer linings prevents contamination from metal ions that could leach from conventional containers, thereby ensuring that the phosphor maintains its emission purity and structural integrity during storage and handling.

This embodiment further requires strict separation of precursor preparation steps for each europium concentration in the 0-6 mol % doping range. To achieve reliable doping control, metal nitrates for each doping level—Sr(NO₃)₂, Mg(NO₃)₂, Ge precursor, and Eu(NO₃)₃—are weighed and dissolved independently so that no inadvertent transfer of europium ions occurs between batches. Each nitrate mixture is blended with Aloe vera gel separately to produce an individual viscous precursor gel, ensuring that the fuel-to-oxidizer ratio and chelation behavior remain specific to that doping level. Each batch is then subjected to its own combustion and calcination cycle, completely isolated from other concentrations. This independent processing prevents cross-contamination of dopant ions, which is crucial because europium concentration strongly influences photoluminescence intensity, quenching behavior, and emission peak position. Maintaining distinct precursor formulations and combustion-calcination pathways for each doping level allows systematic tuning of luminescent output and ensures that each Eu³⁺ concentration yields its own predictable and reproducible phosphor profile. The combination of rigorous particle-size refinement, moisture conditioning, contamination-free storage, and carefully maintained batch independence provides a robust and fully enabled process for producing high-quality Sr₂MgGe₂O₇:x % Eu³⁺ phosphors across the complete doping range.

In an embodiment, further comprising: preparing the Ge nitrate precursor by adding nitric acid dropwise to the GeO₂ under continuous stirring, heating the mixture until the GeO₂ visibly dissolves, adjusting the resulting solution to a pH of approximately 3.0-4.0 to stabilize the Ge species, filtering the acidified solution to remove insoluble residues, and immediately incorporating the filtered Ge nitrate into the primary precursor mixture; maintaining the homogeneous precursor solution at an elevated temperature between 40-50° C. before Aloe vera gel addition to improve miscibility, stirring the mixture under controlled shear conditions until metal-ligand interactions within the gel matrix are visibly established, and aging the gel for an interval of 10-20 minutes to permit rearrangement of metal ions within the gel structure prior to combustion.

Following the integration of the Ge nitrate, the homogeneous precursor solution is maintained at a moderately elevated temperature between 40-50° C. prior to the addition of Aloe vera gel extract. This controlled temperature enhances miscibility between the aqueous nitrate phase and the organic components of the Aloe vera gel, reducing gelation gradients and preventing early aggregation of metal-ligand complexes. Maintaining this temperature range also reduces viscosity, ensuring efficient interaction between cations and the polysaccharide-rich Aloe matrix once the gel is introduced. Under controlled shear stirring, the mixture gradually transitions into a structured gel in which metal-ligand interactions—such as coordination of Sr²⁺, Mg²⁺, Ge⁴⁺, and Eu³⁺ ions with Aloe-derived organic moieties—become visibly established. These interactions promote nanoscale homogeneity and create a precursor system that combusts more uniformly due to the intimately mixed oxidizer-fuel network. After gel formation, the precursor is aged for 10-20 minutes under gentle agitation to allow slow rearrangement and equilibration of metal ions within the gel structure. This aging period is critical because it permits the metal ions to migrate into energetically favorable coordination environments within the organic matrix, resulting in a more uniform distribution of europium dopant and improved structural regularity in the gel. Experimental observations show that aged gels produce a more consistent combustion front, finer and more uniform pore structures in the spongy intermediate, and ultimately yield Sr₂MgGe₂O₇:x % Eu³⁺ phosphors with higher crystallinity, sharper emission peaks, and reduced defect-associated quenching. Thus, the combination of controlled Ge nitrate preparation, pH stabilization, temperature-regulated mixing, and gel aging provides a synergistic foundation for producing high-quality europium-doped phosphors with predictable and reproducible optical performance.

In an embodiment, further comprising: loading the viscous precursor gel into a muffle furnace that has been pre-stabilized at temperature to avoid transient thermal gradients, allowing the gel to undergo pre-dehydration until visually consistent evaporation occurs, initiating combustion by raising the furnace temperature to 500° C., and maintaining the vessel in the furnace until the internal combustion propagates uniformly across the entire gel structure; forming the final phosphor powder by performing repeated cycles of grinding, drying, calcination, and sieving until the powder reaches a uniform particle distribution suitable for downstream incorporation into devices, and packaging the final powder in moisture-controlled conditions for subsequent use in light-emitting or forensic applications.

In an embodiment, the process further comprises loading the viscous precursor gel into a muffle furnace that has been pre-stabilized at the intended pre-dehydration temperature so that transient thermal gradients are avoided during furnace insertion. This pre-stabilization is essential because abrupt temperature fluctuations can induce localized overheating or incomplete moisture removal, which may trigger premature ignition or create combustion irregularities within the gel matrix. Once placed inside the pre-stabilized furnace, the gel undergoes a controlled pre-dehydration phase in which visibly consistent evaporation of entrapped water and Aloe vera-derived volatiles occurs. This phase ensures that most physically bound water is removed before the exothermic reaction begins, thereby preventing violent bubbling or uncontrolled flame dynamics during ignition. After the evaporation rate visibly stabilizes, the furnace temperature is raised to approximately 500° C. to initiate combustion. At this temperature, nitrate oxidizers react vigorously with the organic constituents of the Aloe vera fuel, producing a self-propagating combustion front. Maintaining the vessel in the furnace during this stage ensures that internal combustion propagates uniformly throughout the entire gel structure, thereby generating a consistently porous, low-density spongy mass that serves as the intermediate precursor for crystalline phosphor formation.

After combustion, the resulting porous material is processed through repeated cycles of grinding, drying, calcination, and sieving to refine the powder and achieve a uniform particle-size distribution suitable for optical and device-level applications. Grinding reduces the brittle spongy material into smaller fragments, while drying removes residual moisture that can cause micro-explosions during calcination. Calcination at the appropriate temperature consolidates the intermediate oxides into a well-defined Sr₂MgGe₂O₇ lattice with europium dopants properly incorporated into their substitutional sites. Sieving eliminates oversized agglomerates, ensuring that only fine and uniformly sized particles are retained. These cycles may be repeated as required until the powder exhibits a consistent granular morphology, optimized light-scattering properties, and uniform dopant distribution across all particles. Such iterative refinement is especially important for applications in LEDs and forensic imaging, where homogeneous particle size directly affects luminance uniformity, spectral stability, and surface-coating smoothness.

Once the desired powder uniformity is achieved, the phosphor is packaged under moisture-controlled conditions to preserve its structural and optical integrity. Moisture control is critical because Eu³⁺-activated oxide phosphors can exhibit luminescence quenching or surface hydroxylation if exposed to ambient humidity. Packaging in sealed, low-humidity containers—often with desiccant inserts or inert internal linings—ensures long-term stability of the phosphor, preventing surface degradation or agglomeration during storage. This enables the final product to remain ready for incorporation into light-emitting devices, latent fingerprint powders, anti-counterfeiting inks, and other applications requiring high luminescent efficiency and reliable performance. The synergy between controlled combustion, repeated refinement cycles, and moisture-stable packaging yields a reproducible, device-ready Sr₂MgGe₂O₇:x % Eu³⁺ phosphor with consistent optical properties across production batches.

In an embodiment, comprising pre-conditioning the distilled water prior to precursor dissolution by heating the water to 90-95° C. to expel dissolved atmospheric gases, cooling the degassed water to 50-60° C. before metal salt dissolution, and subsequently introducing the metal nitrates into the pre-conditioned water in a staggered manner so that each nitrate salt dissolves under identical solvent conditions, thereby maintaining uniform ionic distribution before Aloe vera gel incorporation. In an embodiment, the process comprises pre-conditioning the distilled water prior to precursor dissolution by heating the water to 90-95° C. to expel dissolved atmospheric gases, cooling the degassed water to 50-60° C. before metal salt dissolution, and subsequently introducing the metal nitrates into the pre-conditioned water in a staggered manner so that each nitrate salt dissolves under identical solvent conditions, thereby maintaining uniform ionic distribution before Aloe vera gel incorporation. Heating distilled water to 90-95° C. serves to drive off dissolved oxygen and other gases that can nucleate bubbles during later thermal steps or promote unwanted oxidation pathways; this degassing reduces the likelihood of micro-porosity and unpredictable gas evolution during combustion. After a brief hold at the elevated temperature to ensure thorough degassing, the water is allowed to cool to 50-60° C., a range chosen because it is warm enough to accelerate salt dissolution yet low enough to avoid initiating any hydrolysis or thermal decomposition of nitrate salts. Introducing the metal nitrates in a staggered sequence for example, first dissolving strontium nitrate and magnesium nitrate to form a clear alkaline-earth solution, then adding the filtered germanium nitrate solution, and finally incorporating europium nitrate once the primary cation matrix is established ensures that each salt dissolves under the same solvent conditions and minimizes localized supersaturation or transient pH gradients that could precipitate insoluble species. This controlled addition strategy promotes homogeneous ionic distribution, reduces the formation of micro-heterogeneities, and prepares a chemically uniform precursor solution that, upon subsequent addition of Aloe vera gel, yields a consistent gel matrix with well-distributed metal-ligand coordination. Empirically, precursor batches prepared using this water pre-conditioning and staggered dissolution approach exhibit more uniform combustion behavior, fewer secondary phases after calcination, and improved reproducibility of photoluminescent properties across different europium doping levels.

In an embodiment, comprising introducing a pre-heating holding period during calcination in which the furnace temperature is retained at 400-450° C. for 20-30 minutes prior to ramping to 800° C., allowing early-stage oxide intermediates to stabilize, and thereafter increasing the temperature at a controlled ramp rate until the set calcination temperature is reached and maintained for the intended duration; and implementing a post-calcination thermal conditioning phase in which the calcined powder is reheated to a temperature between 200-250° C. for a duration of 15-25 minutes after natural furnace cooling, agitating the powder between reheating intervals to break thermally weakened agglomerates, and cooling the conditioned powder to ambient temperature prior to grinding.

In an embodiment, the process further comprises introducing an intermediate pre-heating hold during the calcination profile in which, after the initial temperature ramp from ambient, the furnace temperature is retained at a controlled plateau of 400-450° C. for 20-30 minutes prior to further ramping to the final calcination setpoint of 800° C.; this intermediate hold allows early-stage oxide intermediates formed during combustion to decompose residual organics slowly, initiate low-temperature solid-state reactions and partial sintering, and stabilize nascent oxide networks so that subsequent rapid temperature increases do not shock the forming lattice or trap high concentrations of structural defects. After the pre-heating hold the furnace temperature is increased at the prescribed controlled ramp rate to 800° C. and maintained for the intended dwell period to complete crystallization and enable full solid-state diffusion of Eu³⁺ into substitutional lattice sites. Following natural cooling of the calcined batch to ambient temperature, the embodiment further comprises a post-calcination thermal conditioning stage in which the calcined powder is subjected to brief reheating cycles at 200-250° C. for 15-25 minutes; during these conditioned reheats the powder is intermittently agitated so that thermally weakened agglomerates fracture along particle boundaries, volatile surface species are desorbed, and strain relaxation occurs at particle surfaces without disturbing the established crystal lattice. Repeating brief reheating and agitation (or performing a single controlled conditioning cycle) reduces cohesive forces between particles, facilitates easier downstream grinding, and lowers the incidence of hard agglomerates that would otherwise persist after mechanical milling. The net effect of the pre-heating hold and the post-calcination conditioning is synergistic: the pre-hold prevents premature defect fixation and encourages uniform phase evolution during the high-temperature dwell, while the mild post-conditioning weakens interparticle bonds and removes residual surface impurities, together yielding powders that grind more readily to a narrow particle-size distribution, exhibit improved crystallinity, reduced non-radiative defect densities, and enhanced and more reproducible photoluminescent performance in LED, forensic, and anti-counterfeiting applications.

In an embodiment, in the synthesis of Europium-doped strontium magnesium germanate phosphors, Aloe vera gel extract is used as both a natural fuel and a natural templating agent. In an embodiment, strontium nitrate, magnesium nitrate, germanium dioxide, and europium nitrate have a purity of 99.99% and are used without any additional purification. In an embodiment, the stirring time at room temperature is maintained for 30 minutes to ensure homogeneous mixing of the precursor solution with A.V. gel. In an embodiment, the muffle furnace temperature for combustion is maintained at 500° C., wherein the muffle furnace is preheated to 500° C., and wherein the calcination temperature is 800° C. and the calcination duration is 4 hours. In an embodiment, the solution is boiled, ignited to form a gel, and combusted into a fine powder while releasing gases such as CO₂, H₂O, and N₂. In an embodiment, the synthesized fine powder is subsequently annealed at 1000° C. for improved crystallinity. The present invention relates to the synthesis, characterization, and multifunctional application of synthesized SMGO:Eu³⁺ phosphors prepared via a solution combustion technique. The present invention aims to evaluate the suitability of synthesized phosphors for three critical applications: (1) as a red phosphor to enhance color quality and thermal stability in w-LEDs, (2) for AC purposes owing to their distinct and durable luminescence, and (3) in LFP detection, utilizing the deep learning framework for improved detection accuracy.

The synthesis process employed high-purity starting materials, including strontium nitrate [Sr(NO₃)₂; 99.99%], magnesium nitrate [Mg(NO₃)₂; 99.99%], germanium dioxide [GeO₂; 99.99%], and europium nitrate [Eu(NO₃)₃; 99.99%]. These nitrates were used without any additional purification. In the case of oxide precursors, they were transformed into nitrates by dissolving them in nitric acid (HNO₃) solution. Aloe Vera (A.V.) gel extract, is utilized as a fuel and complexing agent. Fresh A.V. stems were acquired, and then cleaned thoroughly using distilled water to eliminate surface impurities. The outer green skin was carefully removed using a sterilized knife, and the inner transparent gel was extracted. The gel was then blended into a smooth and uniform consistency using a household blender. The extracted A.V. gel serves dual roles as a green fuel and chelating medium in the phosphor fabrication process. The prepared gel was stored in a sanitized container for subsequent use. The SMGO:x % Eu³⁺ (x=0-6 mol %) phosphors were synthesized via a solution combustion technique, with A.V. gel functioning as both a fuel and a natural templating agent. Stoichiometric quantities of Sr(NO₃)₂, Mg(NO₃)₂, Ge(NO₃)₄, and Eu(NO₃)₃, corresponding to varying Eu³⁺ doping levels (0-6 mol %), were accurately weighed and dissolved in a minimal volume of distilled water to form a homogenous solution. A.V. gel was subsequently added in a predetermined amount and thoroughly mixed into the precursor solution. This mixture was stirred continuously at room temperature for 30 min on a magnetic stirrer to achieve a viscous gel-like solution. The mixture was then transferred to a borosilicate beaker and placed inside a muffle furnace preheated to 500° C. The exothermic combustion reaction resulted in the formation of a porous, spongy mass due to the rapid evolution of gases. Post-combustion, the obtained product was subjected to calcination at 800° C. for 4 h to enhance crystallinity and eliminate residual organic content. After natural cooling to room temperature, the resulting material was collected and finely ground using an agate mortar and pestle to obtain the final SMGO:x % Eu³⁺ phosphor powders. This procedure was repeated for all specified Eu³⁺ concentrations.

In an embodiment, to construct w-LED devices, a EL Spectrum HP9000 instrument was employed. The synthesized SMGO:2% Eu³⁺ red-emitting phosphor was mixed with commercially available blue-emitting BAM:Eu²⁺ and green-emitting (Ba,Sr)₂SiO₄:Eu²⁺ phosphors. This phosphor blend was combined with a 398 nm (1 W) blue LED chip. ZWL8820 organic silica gel served as the encapsulating medium, with the phosphors and gel combined in a mass ratio of 1:1:2, respectively. The phosphor-silica mixture was thoroughly stirred to ensure even dispersion and then uniformly applied over the blue chip surface. The composite was cured at 100° C. for 10 h to solidify the encapsulation and secure the phosphors in place. These fabricated LED devices were subsequently subjected to performance testing to analyze their photometric and electrical properties.

In an embodiment, to prepare a security ink formulation, 10 mL of distilled water was mixed with polyvinyl alcohol (PVA) to act as a binder. The solution was heated to 85° C. with continuous stirring until a clear, uniform solution was achieved. The synthesized SMGO:2% Eu³⁺ phosphor powder was then incorporated into the solution, followed by ultrasonic treatment to ensure homogeneous dispersion and avoid particle agglomeration. The resulting ink was applied to various substrates such as paper, plastic sheets, aluminium foil, glass, wood with painted surfaces, currency notes, and metal plates using a sketch pen. This method enabled the creation of fine and detailed patterns. The ink's luminescent patterns were observed under daylight, ultraviolet light (365 nm), and complete darkness. Under ambient light, patterns appeared faint due to residual PVA markings. Upon UV exposure, a bright red emission was observed, facilitating clear visualization and authentication. The ink demonstrated good adhesion across different substrates and maintained consistent luminescence under UV irradiation, indicating its suitability for long-term security applications.

In an embodiment, LFP samples were obtained from a 24-year-old male volunteer, ensuring no prior treatment on the fingertip to retain natural skin oils. The volunteer pressed his thumb onto different substrates including paper, aluminium foil, and ceramic tiles. The SMGO:2% Eu³⁺ phosphor powder was gently dusted over the FP impressions using a soft brush to allow the powder to adhere to the FP ridges. Excess powder was carefully removed, enhancing the ridge pattern visibility. The developed prints were captured using a Canon EOS 4000D DSLR camera equipped with an EF-S 18-55 mm f/3.5-5.6 III lens under 365 nm UV illumination. This method provided high-contrast, detailed FP images suitable for forensic documentation.

1. A process for synthesizing europium-doped Sr₂MgGe₂O₇ phosphors, the process comprising:
preparing an aloe vera (A.V.) gel extract upon treating fresh aloe vera stems;
(b) dissolving Sr(NO₃)₂, Mg(NO₃)₂, Ge(NO₃)₄, and Eu(NO₃)₃ corresponding to Eu³⁺ doping levels of 0-6 mol % in distilled water to form a homogenous solution;
adding Aloe Vera (A.V.) gel extract as both fuel and templating agent to the solution;
stirring the mixture at room temperature for 30 minutes using a magnetic stirrer to form a viscous gel-like solution;
transferring the viscous gel-like solution in a borosilicate beaker and heating in a muffle furnace at 500° C. to initiate an exothermic combustion reaction producing a porous spongy mass;
calcining the porous spongy mass at 800° C. for 4 hours; and
cooling the material at room temperature and collecting thereby grinding using an agate mortar and pestle to obtain the europium-doped Sr²MgGe₂O₇ (SMGO:x % Eu³⁺ (x=0-6 mol %)) phosphors, wherein the SrMgGeO4:x % Eu³⁺ (x=0-6 mol %) phosphors is prepared via a green solution combustion technique, repeated for each Eu³⁺ concentration from 0 to 6 mol %;
wherein preparing the Sr₂MgGe₂O₇:x % Eu³⁺ phosphors via the green solution combustion technique comprises preparing a separate precursor batch for each europium concentration by dissolving individually weighed quantities of the metal nitrates in preheated distilled water, adjusting the total oxidizer content by calculating oxygen equivalence from the nitrate ions, adding a measured amount of Aloe vera gel to each batch to establish a fuel-to-oxidizer ratio suitable for self-propagating combustion, stirring each batch until a uniform viscous gel is obtained, and transferring each viscous gel to a designated combustion vessel so that each europium concentration undergoes an independent combustion cycle, and wherein the green solution combustion technique for each europium concentration further comprises heating each viscous gel in a furnace that has been stabilized at a pre-dehydration temperature between 250° C. and 300° C. to remove entrapped moisture, subsequently elevating the furnace temperature to 500° C. to initiate auto-ignition of the gel matrix, permitting the combustion to propagate across the full gel mass through internally generated gases, holding each batch inside the furnace for a settling period after flame extinction to allow post-combustion intermediate phases to consolidate, and collecting the porous spongy mass corresponding to each europium concentration in a separately labeled container, and
wherein the green solution combustion technique for each europium concentration additionally comprises crushing the porous spongy mass obtained from each combustion run, pre-drying each crushed mass at 120-150° C. to eliminate residual volatiles, loading each dried mass into a separate ceramic crucible, calcining each crucible at 800° C. for four hours while maintaining a controlled temperature ramp of 3-5° C. per minute, cooling each crucible naturally to room temperature inside the furnace chamber without forced convection, and subsequently grinding, sieving, and desiccating each calcined phosphor batch independently so that no cross-contamination occurs between different europium doping levels.

2. The process of claim 1, wherein the preparing of the aloe vera (A.V.) gel extract comprising:
cleaning the fresh Aloe Vera stems thoroughly using distilled water to eliminate surface impurities;
removing an outer green skin from the stems using a sterilized knife and extracting the inner transparent gel;
blending the extracted inner transparent gel to form a smooth and uniform consistency using a household blender; and
storing the prepared A.V. gel extract in a sanitized container for subsequent use.

3. The process of claim 1, further comprising preparing a first aqueous solution by heating distilled water to 75-85° C. and dissolving strontium nitrate and magnesium nitrate therein until the salts are visually dissolved; preparing a second solution by reacting germanium dioxide with nitric acid until a clear Ge-containing nitrate solution is obtained and filtering the Ge-containing solution through a 0.45 μm PTFE membrane to remove undissolved particulates; combining the first and second solutions and stirring the combined solution at 600-800 rpm until a homogeneous cationic precursor solution is formed; cooling the homogeneous precursor solution to ambient temperature; adding europium nitrate to the cooled precursor solution and stirring until the europium salt is fully dispersed; and thereafter adding the prepared Aloe vera gel extract to the combined nitrate solution while maintaining continuous stirring to give a uniformly mixed precursor gel.

4. The process of claim 1, further comprising warming the Aloe vera gel extract to 40-50° C. to reduce its viscosity prior to incorporation into the precursor solution; calculating and setting a fuel-to-oxidizer stoichiometry based on the total nitrate oxygen content so that the overall mixture is slightly fuel-lean; adding the warmed Aloe vera gel extract to the homogeneous nitrate solution in a controlled, continuous feed so as to avoid local hot spots; maintaining the mixed system under a controlled shear provided by stirring at 400-550 rpm until the mixture attains a viscous gel state indicative of metal-phytochemical chelation; and holding the resultant viscous gel under gentle agitation for a further 20-40 minutes to permit equilibration of metal-ligand complexes within the gel matrix.

5. The process of claim 2, further comprising:
mixing synthesized SMGO:2% Eu³⁺ red-emitting phosphor with blue-emitting BaMgAl₁₀O₁₇:Eu²⁺ phosphor and a green-emitting (Ba,Sr)₂SiO₄:Eu²⁺ phosphor to form a phosphor blend;
combining the phosphor blend with a 398 nm blue LED chip;
mixing the phosphor blend and chip with organic silica gel in a mass ratio of 1:1:2;
stirring the phosphor-silica mixture to ensure even dispersion;
uniformly applying the mixture over the blue LED chip surface; and
curing the composite at 100° C. for 10 hours.

6. The process of claim 2, further comprising:
mixing 10 mL of distilled water with polyvinyl alcohol (PVA) as a binder;
heating the mixture to 85° C. with continuous stirring to form a clear, uniform solution;
incorporating SMGO:2% Eu³⁺ phosphor powder into the solution;
subjecting the mixture to ultrasonic treatment for homogeneous dispersion and to prevent particle agglomeration.

7. The process of claim 1, further comprising transferring the viscous gel into a borosilicate vessel and preheating a muffle furnace to 250-300° C., inserting the vessel into the furnace and maintaining the preheat temperature for a period sufficient to drive off physically adsorbed water, rapidly raising the furnace temperature to 500° C. to initiate self-propagating exothermic combustion across the gel volume, allowing the combustion to proceed to completion such that gaseous products evolve and a porous spongy mass forms, and removing the spongy mass from the furnace after visible cessation of combustion; and breaking the large agglomerates of the porous spongy combustion product to obtain a free-flowing powder; pre-drying the powder at 120-150° C. for 1-2 hours to remove residual moisture and volatile organics; loading the dried powder into a ceramic crucible and placing the crucible into a calcination furnace; increasing the furnace temperature from ambient at a controlled ramp rate of 3-5° C. per minute to 800° C., holding at 800° C. for 4 hours to enable solid-state diffusion and phase formation, and allowing the furnace to cool naturally to room temperature within the closed furnace chamber before unloading the calcined product.

8. The process of claim 1, further comprising: grinding the calcined mass in an agate mortar and pestle using a circular grinding motion for 20-30 minutes to provide a uniformly milled phosphor powder; sieving the milled powder through a non-metallic sieve having nominal pore dimensions between 100 μm and 150 μm to remove oversized agglomerates; placing the sieved powder into a desiccator to equilibrate under low humidity conditions prior to packaging; and storing the equilibrated powder in sealed, inert-lined containers to prevent atmospheric contamination; and preparing separate precursor batches for each desired europium doping concentration in the range 0-6 mol % by weighing Sr(NO₃)₂, Mg(NO₃)₂, Ge precursor and Eu(NO₃)₃ on an analytical balance to the required molar ratios, dissolving and combining the precursors to form an individual homogeneous solution for each doping level, adding Aloe vera gel to each batch to form a respective viscous gel, subjecting each batch independently to the combustion and calcination sequence.

9. The process of claim 1, further comprising converting GeO₂ to a soluble Ge nitrate prior to precursor mixing by adding a stoichiometric excess of nitric acid, heating the GeO₂-acid mixture until complete dissolution of GeO₂ is evidenced by the absence of solids, neutralizing any excess acid to a pH of about 3.0-4.0 to maintain ionic activity suitable for metal complexation, filtering the resultant Ge nitrate solution to remove insoluble residues, and immediately using the filtrate in precursor preparation to avoid hydrolytic precipitation; and adjusting the pH of the viscous precursor gel to a value between 3.0 and 4.0 by controlled addition of nitric acid to stabilize dissolved Ge and Eu species, continuing gentle stirring of the pH-adjusted gel for a period of 20-30 minutes to enable redistribution of cations within the Aloe-based chelating matrix, monitoring the viscosity of the gel using a viscometric sensor until the viscosity range of 2-6 Pa s is attained, and transferring the gel to a borosilicate reaction vessel only after said viscosity range is reached.

10. The process of claim 1, further comprising degassing the homogeneous precursor solution by applying low-pressure evacuation for 3-5 minutes to remove dissolved air pockets that may disrupt combustion, returning the degassed solution to atmospheric pressure, reheating the solution to 40-50° C. to maintain reduced viscosity, and subsequently adding the Aloe vera gel under continuous stirring to form a uniformly aeration-free viscous gel.

11. The process of claim 1, further comprising:
placing the borosilicate vessel containing the viscous gel in a preheated muffle furnace maintained at 250-300° C. for a pre-dehydration phase, holding the gel at this temperature until steam evolution visibly subsides, raising the temperature rapidly to 500° C. to initiate combustion, and retaining the vessel in the furnace until the combustion front propagates throughout the entire gel matrix and visibly forms a lightweight porous mass; and
allowing the combusted porous mass to remain within the furnace chamber for an additional residence period of 5-10 minutes after flame extinction to stabilize intermediate oxide species, removing the vessel from the furnace while maintaining ambient airflow around the vessel, mechanically crushing the mass immediately while still warm to reduce macro-agglomerates, and then transferring the crushed powder into a drying oven.

12. The process of claim 1, further comprising:
drying the crushed porous product at 120-150° C. for 1-2 hours to remove moisture generated during combustion, mixing the dried material thoroughly prior to calcination to redistribute fine and coarse fragments, placing the mixed powder into a high-purity ceramic crucible, and positioning the crucible in the central heating zone of a programmable calcination furnace;
initiating calcination by ramping the furnace temperature at 3-5° C. per minute from ambient temperature to 800° C., maintaining a uniform temperature distribution around the crucible by centering the crucible within the furnace, holding the temperature at 800° C. for 4 hours to enable solid-state diffusion pathways to complete, and subsequently allowing the furnace to cool naturally to room temperature without forced ventilation; and
removing the calcined mass from the furnace only after the temperature reaches below 80° C., transferring the calcined mass to an agate mortar, applying continuous circular grinding force until the powder achieves a visually uniform texture, and performing intermediate mixing during grinding to collapse residual agglomerates.

13. The process of claim 1, further comprising:
sieving the ground phosphor powder through a non-metallic sieve having a nominal pore dimension of 100-150 μm, collecting the fraction of powder that passes through the sieve as the target product, returning the coarse fraction above the sieve to the mortar for additional grinding, and repeating grinding and sieving cycles until no oversized particles remain;
transferring the sieved phosphor powder to a desiccator containing a moisture-adsorbing medium, holding the powder in the desiccator for a conditioning period sufficient to achieve low-humidity equilibrium, and storing the conditioned powder in sealed containers lined with inert polymer coatings for subsequent handling; and
preparing separate precursor mixtures for each europium concentration in the range 0-6 mol %, dissolving metal nitrates for each mixture individually to avoid cross-contamination, adding Aloe vera gel to each solution separately to produce individual viscous gels, and conducting combustion and calcination for each doping level independently so that each concentration yields its own distinct phosphor batch.

14. The process of claim 1, further comprising:
preparing the Ge nitrate precursor by adding nitric acid dropwise to the GeO₂ under continuous stirring, heating the mixture until the GeO₂ visibly dissolves, adjusting the resulting solution to a pH of approximately 3.0-4.0 to stabilize the Ge species, filtering the acidified solution to remove insoluble residues, and immediately incorporating the filtered Ge nitrate into the primary precursor mixture; and
maintaining the homogeneous precursor solution at an elevated temperature between 40-50° C. before Aloe vera gel addition to improve miscibility, stirring the mixture under controlled shear conditions until metal-ligand interactions within the gel matrix are visibly established, and aging the gel for an interval of 10-20 minutes to permit rearrangement of metal ions within the gel structure prior to combustion.

15. The process of claim 1, further comprising:
loading the viscous precursor gel into a muffle furnace that has been pre-stabilized at temperature to avoid transient thermal gradients, allowing the gel to undergo pre-dehydration until visually consistent evaporation occurs, initiating combustion by raising the furnace temperature to 500° C., and maintaining the vessel in the furnace until the internal combustion propagates uniformly across the entire gel structure; forming the final phosphor powder by performing repeated cycles of grinding, drying, calcination, and sieving until the powder reaches a uniform particle distribution suitable for downstream incorporation into devices, and packaging the final powder in moisture-controlled conditions for subsequent use in light-emitting or forensic applications.

16. The process of claim 1, comprising:
pre-conditioning the distilled water prior to precursor dissolution by heating the water to 90-95° C. to expel dissolved atmospheric gases, cooling the degassed water to 50-60° C. before metal salt dissolution, and subsequently introducing the metal nitrates into the pre-conditioned water in a staggered manner so that each nitrate salt dissolves under identical solvent conditions;
introducing a pre-heating holding period during calcination in which the furnace temperature is retained at 400-450° C. for 20-30 minutes prior to ramping to 800° C., allowing early-stage oxide intermediates to stabilize, and thereafter increasing the temperature at a controlled ramp rate until the set calcination temperature is reached and maintained for the intended duration; and
implementing a post-calcination thermal conditioning phase in which the calcined powder is reheated to a temperature between 200-250° C. for a duration of 15-25 minutes after natural furnace cooling, agitating the powder between reheating intervals to break thermally weakened agglomerates, and cooling the conditioned powder to ambient temperature prior to grinding.
